(19) United States
(12) Patent Application Publication
(10) Pub. No.: US 2025/0081453 A1
(43) Pub. Date: Mar. 6, 2025

(54) THREE-DIMENSIONAL MEMORY DEVICE WITH PILLAR SHAPED TRENCH BRIDGE STRUCTURES AND METHODS OF FORMING THE SAME

(71) Applicant: WESTERN DIGITAL TECHNOLOGIES, INC.,, SAN JOSE, CA (US)

(72) Inventors: Yuya SANADA, Yokkaichi (JP); Koichi MATSUNO, Fremont, CA (US); Tomohiro KUBO, Yokkaichi (JP); Johann ALSMEIER, San Jose, CA (US)

(21) Appl. No.: 18/646,016

(22) Filed: Apr. 25, 2024

Related U.S. Application Data
(63) Continuation-in-part of application No. 18/459,938, filed on Sep. 1, 2023.

(51) Int. Cl. H10B 41/27; H01L 21/311; H01L 21/762; H10B 43/27

(52) U.S. Cl. CPC H10B 41/27; H01L 21/31144; H01L 21/76224; H10B 43/27

(57) ABSTRACT

A three-dimensional memory device includes alternating stacks of insulating layers and electrically conductive layers, where each of the alternating stacks laterally extends along a first horizontal direction, and the alternating stacks are laterally spaced apart from each other along a second horizontal direction by lateral isolation trenches, arrays of memory openings, where each array of memory openings vertically extends through a respective one of the alternating stacks, arrays of memory opening fill structures located within the arrays of memory openings, where each of the memory opening fill structures includes a respective vertical stack of memory elements and a vertical semiconductor channel, and composite lateral isolation trench fill structures located between a respective neighboring pair of the alternating stacks. Each of the composite lateral isolation trench fill structures includes a laterally alternating sequence of dielectric pillar structures and isolation opening fill structures arranged along the first horizontal direction.

### RELATED APPLICATIONS

This application is a continuation-in-part (CIP) application of U.S. application Ser. No. 18/459,938 filed on Sep. 1, 2023, the entire contents of which are incorporated herein by reference.

### FIELD

The present disclosure relates generally to the field of semiconductor devices, and particularly to a three-dimensional memory device including pillar shaped trench bridge structures and methods of forming the same.

### BACKGROUND

A three-dimensional memory device including three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an embodiment of the present disclosure, a three-dimensional memory device is provided, which comprises: alternating stacks of insulating layers and electrically conductive layers, wherein each of the alternating stacks laterally extends along a first horizontal direction, and the alternating stacks are laterally spaced apart from each other along a second horizontal direction by lateral isolation trenches; arrays of memory openings, wherein each array of memory openings vertically extends through a respective one of the alternating stacks; arrays of memory opening fill structures located within the arrays of memory openings, wherein each of the memory opening fill structures comprises a respective vertical stack of memory elements and a vertical semiconductor channel; and composite lateral isolation trench fill structures located in the lateral isolation trenches, wherein each of the composite lateral isolation trench fill structures comprises a laterally alternating sequence of dielectric pillar structures and dielectric containing structures (such as insulating spacers or isolation opening fill structures) arranged along the first horizontal direction.

According to another aspect of the present disclosure, a method of forming device structure is provided. The method comprises: forming a vertically alternating sequence of continuous insulating layers comprising a first material and continuous sacrificial material layers comprising a second material; forming dielectric pillar structures arranged in rows through the vertically alternating sequence, wherein each row of dielectric pillar structures comprises a respective subset of the dielectric pillar structures arranged along a first horizontal direction, and the rows of dielectric pillar structures are laterally spaced apart along a second horizontal direction that is perpendicular to the first horizontal direction; forming memory openings through the vertically alternating sequence; forming isolation openings arranged in rows through the vertically alternating sequence, wherein each row of isolation openings comprises a respective subset of the isolation openings arranged along the first horizontal direction, and the rows of isolation openings are laterally spaced apart along the second horizontal direction; replacing the sacrificial material layers with electrically conductive layers employing at least cavities within the isolation openings as a conduit for providing an isotropic etchant that etches the second material selective to the first material, and for providing a precursor material for depositing at least one conductive material of the electrically conductive layers; and forming memory opening fill structures in the memory openings, wherein each of the memory opening fill structures comprises a respective vertical stack of memory elements and a vertical semiconductor channel.

According to an embodiment of the present disclosure, a three-dimensional memory device includes alternating stacks of insulating layers and electrically conductive layers, wherein each of the alternating stacks laterally extends along a first horizontal direction, and the alternating stacks are laterally spaced apart from each other along a second horizontal direction by lateral isolation trenches, arrays of memory openings, wherein each array of memory openings vertically extends through a respective one of the alternating stacks, arrays of memory opening fill structures located within the arrays of memory openings, wherein each of the memory opening fill structures comprises a respective vertical stack of memory elements and a vertical semiconductor channel, and composite lateral isolation trench fill structures located between a respective neighboring pair of the alternating stacks, wherein each of the composite lateral isolation trench fill structures comprises a dielectric pillar structure which vertically extends at least from first horizontal plane including a bottom of the alternating stacks to a second horizontal plane including a top of the alternating stacks.

According to another aspect of the present disclosure, a method of forming a semiconductor structure is provided. The method comprises: forming a vertically alternating sequence of continuous insulating layers and continuous sacrificial material layers; forming elongated dielectric pillar structures laterally extending along a first horizontal direction and laterally spaced apart along a second horizontal direction through the vertically alternating sequence; forming memory openings through the vertically alternating sequence; forming memory opening fill structures in the memory openings, wherein each of the memory opening fill structures comprises a respective vertical stack of memory elements and a vertical semiconductor channel; forming laterally-extending trenches through the vertically alternating sequence, wherein contiguous combinations of the elongated dielectric pillar structures and the laterally extending trenches divide the vertically alternating sequence into alternating stacks of insulating layers and sacrificial material layers; and replacing the sacrificial material layers with electrically conductive layers.

### BRIEF DESCRIPTION OF THE DRAWINGS

FIG. 1 is a plan view of an exemplary semiconductor die according to an embodiment of the present disclosure.

FIG. 2 is a vertical cross-sectional view a first exemplary structure after formation of optional semiconductor devices, optional dielectric material layers embedding optional lower-level metal interconnect structures, a semiconductor material layer, and a vertically alternating sequence of continuous insulating layers and continuous sacrificial material layers according to an embodiment of the present disclosure. The region illustrated in FIG. 2 corresponds to region M1 in FIG. 1.

FIG. 3A is a top-down view of the first exemplary structure after formation of multiple sets of stepped surfaces according to an embodiment of the present disclosure. The region illustrated in FIG. 3A corresponds to region M1 in FIG. 1.

FIG. 3B is a vertical cross-sectional view of the first exemplary structure along the vertical plane B-B′ of FIG. 3A.

FIG. 3C is a vertical cross-sectional view of the first exemplary structure along the vertical plane C-C′ of FIG. 3A.

FIG. 4A is a top-down view of the first exemplary structure after formation of stepped dielectric material portions according to an embodiment of the present disclosure. The region illustrated in FIG. 4A corresponds to region M1 in FIG. 1.

FIG. 4B is a vertical cross-sectional view of the first exemplary structure along the vertical plane B-B′ of FIG. 4A.

FIG. 4C is a vertical cross-sectional view of the first exemplary structure along the vertical plane C-C′ of FIG. 4A.

FIG. 5A is a vertical cross-sectional view of a region R of the first exemplary structure in FIG. 4A according to an embodiment of the present disclosure.

FIG. 5B is a top-down view of the region of the first exemplary structure of FIG. 5A. The vertical plane A-A′ is the cut plane of the vertical cross-sectional view of FIG. 5A.

FIG. 5C is a vertical cross-sectional view of the region of the first exemplary structure along the vertical plane C-C′ of FIG. 5B.

FIG. 6A is a vertical cross-sectional view of a region of the first exemplary structure after formation of elongated pillar cavities, support openings, and stepped-region isolation openings according to an embodiment of the present disclosure.

FIG. 6B is a top-down view of the region of the first exemplary structure of FIG. 6A. The vertical plane A-A′ is the cut plane of the vertical cross-sectional view of FIG. 6A.

FIG. 6C is a vertical cross-sectional view of the region of the first exemplary structure along the vertical plane C-C′ of FIG. 6B.

FIG. 7A is a vertical cross-sectional view of a region of the first exemplary structure after formation of elongated sacrificial pillar structures, sacrificial support opening fill structures, and sacrificial isolation opening fill material portions according to an embodiment of the present disclosure.

FIG. 7B is a top-down view of the region of the first exemplary structure of FIG. 7A. The vertical plane A-A′ is the cut plane of the vertical cross-sectional view of FIG. 7A.

FIG. 7C is a vertical cross-sectional view of the region of the first exemplary structure along the vertical plane C-C′ of FIG. 7B.

FIG. 8A is a vertical cross-sectional view of a region of the first exemplary structure after formation of an etch mask layer according to an embodiment of the present disclosure.

FIG. 8B is a partial see-through top-down view of the region of the first exemplary structure of FIG. 8A. The vertical plane A-A′ is the cut plane of the vertical cross-sectional view of FIG. 8A.

FIG. 8C is a vertical cross-sectional view of the region of the first exemplary structure along the vertical plane C-C′ of FIG. 8B.

FIG. 9A is a vertical cross-sectional view of a region of the first exemplary structure after removal of sacrificial isolation opening fill material portions according to an embodiment of the present disclosure.

FIG. 9B is a partial see-through top-down view of the region of the first exemplary structure of FIG. 9A. The vertical plane A-A′ is the cut plane of the vertical cross-sectional view of FIG. 9A.

FIG. 9C is a vertical cross-sectional view of the region of the first exemplary structure along the vertical plane C-C′ of FIG. 9B.

FIG. 10A is a vertical cross-sectional view of a region of the first exemplary structure after removal of the etch mask layer according to an embodiment of the present disclosure.

FIG. 10B is a top-down view of the region of the first exemplary structure of FIG. 10A. The vertical plane A-A′ is the cut plane of the vertical cross-sectional view of FIG. 10A.

FIG. 10C is a vertical cross-sectional view of the region of the first exemplary structure along the vertical plane C-C′ of FIG. 10B.

FIG. 11A is a vertical cross-sectional view of a region of the first exemplary structure after formation of sacrificial staircase-region isolation opening fill structures and removal of the elongated sacrificial pillar structures and the sacrificial support opening fill structures according to an embodiment of the present disclosure.

FIG. 11B is a top-down view of the region of the first exemplary structure of FIG. 11A. The vertical plane A-A′ is the cut plane of the vertical cross-sectional view of FIG. 11A.

FIG. 11C is a vertical cross-sectional view of the region of the first exemplary structure along the vertical plane C-C′ of FIG. 11B.

FIG. 12A is a vertical cross-sectional view of a region of the first exemplary structure after formation of elongated dielectric pillar structures and dielectric support pillar structures according to an embodiment of the present disclosure.

FIG. 12B is a partial-see-through top-down view of the region of the first exemplary structure of FIG. 12A. The vertical plane A-A′ is the cut plane of the vertical cross-sectional view of FIG. 12A.

FIG. 12C is a vertical cross-sectional view of the region of the first exemplary structure along the vertical plane C-C′ of FIG. 12B.

FIG. 13A is a vertical cross-sectional view of a region of the first exemplary structure after formation of an insulating cap layer, memory openings, rows of through-stack isolation openings, semiconductor pillar structures, and pedestal channel portions according to an embodiment of the present disclosure.

FIG. 13B is a partial-see-through top-down view of the region of the first exemplary structure of FIG. 13A. The vertical plane A-A′ is the cut plane of the vertical cross-sectional view of FIG. 13A.

FIG. 13C is a vertical cross-sectional view of the region of the first exemplary structure along the vertical plane C-C′ of FIG. 13B.

FIG. 14A is a vertical cross-sectional view of a region of the first exemplary structure after formation of sacrificial memory opening fill structures, sacrificial through-stack isolation opening fill structures, and a first hard mask layer according to an embodiment of the present disclosure.

FIG. 14B is a partial-see-through top-down view of the region of the first exemplary structure of FIG. 14A. The vertical plane A-A′ is the cut plane of the vertical cross-sectional view of FIG. 14A.

FIG. 14C is a vertical cross-sectional view of the region of the first exemplary structure along the vertical plane C-C′ of FIG. 14B.

FIG. 15A is a vertical cross-sectional view of a region of the first exemplary structure after patterning the first hard mask layer and removal of the sacrificial memory opening fill structures according to an embodiment of the present disclosure.

FIG. 15B is a top-down view of the region of the first exemplary structure of FIG. 15A. The vertical plane A-A′ is the cut plane of the vertical cross-sectional view of FIG. 15A.

FIG. 15C is a vertical cross-sectional view of the region of the first exemplary structure along the vertical plane C-C′ of FIG. 15B.

FIGS. 16A-16F are sequential vertical cross-sectional views of a memory opening during formation of a memory opening fill structure according to an embodiment of the present disclosure.

FIG. 17A is a vertical cross-sectional view of a region of the first exemplary structure after formation of memory opening fill structures and removal of the first hard mask layer according to an embodiment of the present disclosure.

FIG. 17B is a top-down view of the region of the first exemplary structure of FIG. 17A. The vertical plane A-A′ is the cut plane of the vertical cross-sectional view of FIG. 17A.

FIG. 17C is a vertical cross-sectional view of the region of the first exemplary structure along the vertical plane C-C′ of FIG. 17B.

FIG. 18A is a vertical cross-sectional view of a region of the first exemplary structure after formation of a second hard mask layer according to an embodiment of the present disclosure.

FIG. 18B is a partial-see-through top-down view of the region of the first exemplary structure of FIG. 18A. The vertical plane A-A′ is the cut plane of the vertical cross-sectional view of FIG. 18A.

FIG. 18C is a vertical cross-sectional view of the region of the first exemplary structure along the vertical plane C-C′ of FIG. 18B.

FIG. 19A is a vertical cross-sectional view of a region of the first exemplary structure after removal of the sacrificial through-stack isolation opening fill structures according to an embodiment of the present disclosure.

FIG. 19B is a partial-see-through top-down view of the region of the first exemplary structure of FIG. 19A. The vertical plane A-A′ is the cut plane of the vertical cross-sectional view of FIG. 19A.

FIG. 19C is a vertical cross-sectional view of the region of the first exemplary structure along the vertical plane C-C′ of FIG. 19B.

FIG. 20A is a vertical cross-sectional view of a region of the first exemplary structure after formation of first laterally-extending trenches and division of the vertically alternating sequence into alternating stacks according to an embodiment of the present disclosure.

FIG. 20B is a partial-see-through top-down view of the region of the first exemplary structure of FIG. 20A. The vertical plane A-A′ is the cut plane of the vertical cross-sectional view of FIG. 20A.

FIG. 20C is a vertical cross-sectional view of the region of the first exemplary structure along the vertical plane C-C′ of FIG. 20B.

FIG. 21A is a vertical cross-sectional view of a region of the first exemplary structure after formation of a third hard mask layer, patterning of the third hard mask layer and the second hard mask layer, and removal of the sacrificial staircase-region isolation opening fill structures according to an embodiment of the present disclosure.

FIG. 21B is a partial-see-through top-down view of the region of the first exemplary structure of FIG. 21A. The vertical plane A-A′ is the cut plane of the vertical cross-sectional view of FIG. 21A.

FIG. 21C is a vertical cross-sectional view of the region of the first exemplary structure along the vertical plane C-C′ of FIG. 21B.

FIG. 22A is a vertical cross-sectional view of a region of the first exemplary structure after formation of second laterally-extending trenches according to an embodiment of the present disclosure.

FIG. 22B is a partial-see-through top-down view of the region of the first exemplary structure of FIG. 22A. The vertical plane A-A′ is the cut plane of the vertical cross-sectional view of FIG. 22A.

FIG. 22C is a vertical cross-sectional view of the region of the first exemplary structure along the vertical plane C-C′ of FIG. 22B.

FIG. 23A is a vertical cross-sectional view of a region of the first exemplary structure after removal of the second and third hard mask layers according to an embodiment of the present disclosure.

FIG. 23B is a partial-see-through top-down view of the region of the first exemplary structure of FIG. 23A. The vertical plane A-A′ is the cut plane of the vertical cross-sectional view of FIG. 23A.

FIG. 23C is a vertical cross-sectional view of the region of the first exemplary structure along the vertical plane C-C′ of FIG. 23B.

FIG. 24A is a vertical cross-sectional view of a region of the first exemplary structure after replacement of sacrificial material layers with electrically conductive layers according to an embodiment of the present disclosure.

FIG. 24B is a partial-see-through top-down view of the region of the first exemplary structure of FIG. 24A. The vertical plane A-A′ is the cut plane of the vertical cross-sectional view of FIG. 24A.

FIG. 24C is a vertical cross-sectional view of the region of the first exemplary structure along the vertical plane C-C′ of FIG. 24B.

FIG. 25A is a vertical cross-sectional view of a region of the first exemplary structure after formation of composite lateral isolation trench fill structures according to an embodiment of the present disclosure.

FIG. 25B is a partial-see-through top-down view of the region of the first exemplary structure of FIG. 25A. The vertical plane A-A′ is the cut plane of the vertical cross-sectional view of FIG. 25A.

FIG. 25C is a vertical cross-sectional view of the region of the first exemplary structure along the vertical plane C-C′ of FIG. 25B.

FIG. 26A is a vertical cross-sectional view of a region of the first exemplary structure after formation of layer contact via structures according to an embodiment of the present disclosure.

FIG. 26B is a partial-see-through top-down view of the region of the first exemplary structure of FIG. 26A. The vertical plane A-A′ is the cut plane of the vertical cross-sectional view of FIG. 26A.

FIG. 26C is a vertical cross-sectional view of the region of the first exemplary structure along the vertical plane C-C′ of FIG. 26B.

FIGS. 27A-50D are various views of a second exemplary structure. Figures within FIGS. 27A-50D are labeled with a respective combination of a figure numeral and an alphabetical suffix selected from A, B, C, and D. Figures with the same figure numeral correspond to a same processing step within a sequence of processing steps. Figures with the alphabetical suffix D are top-down views. Each figure within the alphabetical suffix A is a vertical cross-sectional view along the vertical plane A-A′ of the second exemplary structure with the same figure numeral and the alphabetical suffix D. Each figure within the alphabetical suffix B is a vertical cross-sectional view along the vertical plane B-B′ of the second exemplary structure with the same figure numeral and the alphabetical suffix D. Each figure within the alphabetical suffix C is a vertical cross-sectional view along the vertical plane C-C′ of the second exemplary structure with the same figure numeral and the alphabetical suffix D.

FIGS. 27A-27D are various views of the second exemplary structure after formation of a first-tier vertically alternating sequence of first insulating layers and first sacrificial material layers according to an embodiment of the present disclosure.

FIGS. 28A-28D are various views of the second exemplary structure after formation of first-tier support openings and first-tier pillar openings according an embodiment of the present disclosure.

FIGS. 29A-29D are various views of the second exemplary structure after formation of first-tier support pillars and first-tier dielectric pillars according an embodiment of the present disclosure.

FIGS. 30A-30D are various views of the second exemplary structure after formation of first-tier memory openings and first-tier isolation openings according an embodiment of the present disclosure.

FIGS. 31A-31D are various views of the second exemplary structure after formation of first-tier sacrificial memory opening fill material portions and first-tier sacrificial isolation opening fill material portions according an embodiment of the present disclosure.

FIGS. 32A-32D are various views of the second exemplary structure after formation of a second-tier vertically alternating sequence of second insulating layers and second sacrificial material layers according to an embodiment of the present disclosure.

FIGS. 33A-33D are various views of the second exemplary structure after formation of second-tier support openings and second-tier pillar openings according an embodiment of the present disclosure.

FIGS. 34A-34D are various views of the second exemplary structure after formation of second-tier support pillars and second-tier dielectric pillars according an embodiment of the present disclosure.

FIGS. 35A-35D are various views of the second exemplary structure after formation of second-tier memory openings and second-tier isolation openings according an embodiment of the present disclosure.

FIGS. 36A-36D are various views of the second exemplary structure after formation of second-tier sacrificial memory opening fill material portions and second-tier sacrificial isolation opening fill material portions according an embodiment of the present disclosure.

FIGS. 37A-37D are various views of the second exemplary structure after formation of a third-tier vertically alternating sequence of third insulating layers and third sacrificial material layers according to an embodiment of the present disclosure.

FIGS. 38A-38D are various views of the second exemplary structure after formation of third-tier support openings and third-tier pillar openings according an embodiment of the present disclosure.

FIGS. 39A-39D are various views of the second exemplary structure after formation of third-tier support pillars and third-tier dielectric pillars according an embodiment of the present disclosure.

FIGS. 40A-40D are various views of the second exemplary structure after formation of third-tier memory openings and third-tier isolation openings according an embodiment of the present disclosure.

FIGS. 41A-41D are various views of the second exemplary structure after formation of third-tier sacrificial memory opening fill material portions and third-tier sacrificial isolation opening fill material portions according an embodiment of the present disclosure.

FIGS. 42A-42D are various views of the second exemplary structure after formation of an etch mask layer according to an embodiment of the present disclosure.

FIGS. 43A-43D are various views of the second exemplary structure after patterning the etch mask layer according to an embodiment of the present disclosure.

FIGS. 44A-44D are various views of the second exemplary structure after formation of voids in the isolation openings according to an embodiment of the present disclosure.

FIGS. 45A-45D are various views of the second exemplary structure after removal of the etch mask layer according to an embodiment of the present disclosure.

FIGS. 46A-46D are various views of the second exemplary structure after laterally expanding the isolation openings to form merged isolation openings according to an embodiment of the present disclosure.

FIGS. 47A-47D are various views of the second exemplary structure after replacement of the sacrificial material layers with electrically conductive layers according to an embodiment of the present disclosure.

FIGS. 48A-48D are various views of the second exemplary structure after formation of isolation opening fill structures according to an embodiment of the present disclosure.

FIGS. 49A-49D are various views of the second exemplary structure after formation of voids in memory openings according to an embodiment of the present disclosure.

FIGS. 50A-50D are various views of the second exemplary structure after formation of memory opening fill structures according to an embodiment of the present disclosure.

FIGS. 51A-74D are various views of a third exemplary structure. Figures within FIGS. 51A-74D are labeled with a respective combination of a figure numeral and an alphabetical suffix selected from A, B, C, and D. Figures with the same figure numeral correspond to a same processing step within a sequence of processing steps. Figures with the alphabetical suffix D are top-down views. Each figure within the alphabetical suffix A is a vertical cross-sectional view along the vertical plane A-A′ of the third exemplary structure with the same figure numeral and the alphabetical suffix D. Each figure within the alphabetical suffix B is a vertical cross-sectional view along the vertical plane B-B′ of the third exemplary structure with the same figure numeral and the alphabetical suffix D. Each figure within the alphabetical suffix C is a vertical cross-sectional view along the vertical plane C-C′ of the third exemplary structure with the same figure numeral and the alphabetical suffix D.

FIGS. 51A-51D are various views of the third exemplary structure after formation of a first-tier vertically alternating sequence of first insulating layers and first sacrificial material layers according to an embodiment of the present disclosure.

FIGS. 52A-52D are various views of the third exemplary structure after formation of first-tier support openings and first-tier pillar openings according to an embodiment of the present disclosure.

FIGS. 53A-53D are various views of the third exemplary structure after formation of first-tier support pillars and first-tier dielectric pillars according to an embodiment of the present disclosure.

FIGS. 54A-54D are various views of the third exemplary structure after formation of first-tier memory openings and first-tier isolation openings according to an embodiment of the present disclosure.

FIGS. 55A-55D are various views of the third exemplary structure after formation of first-tier sacrificial memory opening fill material portions and first-tier sacrificial isolation opening fill material portions according to an embodiment of the present disclosure.

FIGS. 56A-56D are various views of the third exemplary structure after formation of a second-tier vertically alternating sequence of second insulating layers and second sacrificial material layers according to an embodiment of the present disclosure.

FIGS. 57A-57D are various views of the third exemplary structure after formation of second-tier support openings and second-tier pillar openings according to an embodiment of the present disclosure.

FIGS. 58A-58D are various views of the third exemplary structure after formation of second-tier support pillars and second-tier dielectric pillars according to an embodiment of the present disclosure.

FIGS. 59A-59D are various views of the third exemplary structure after formation of second-tier memory openings and second-tier isolation openings according to an embodiment of the present disclosure.

FIGS. 60A-60D are various views of the third exemplary structure after formation of second-tier sacrificial memory opening fill material portions and second-tier sacrificial isolation opening fill material portions according to an embodiment of the present disclosure.

FIGS. 61A-61D are various views of the third exemplary structure after formation of a third-tier vertically alternating sequence of third insulating layers and third sacrificial material layers according to an embodiment of the present disclosure.

FIGS. 62A-62D are various views of the third exemplary structure after formation of third-tier support openings and third-tier pillar openings according to an embodiment of the present disclosure.

FIGS. 63A-63D are various views of the third exemplary structure after formation of third-tier support pillars and third-tier dielectric pillars according to an embodiment of the present disclosure.

FIGS. 64A-64D are various views of the third exemplary structure after formation of third-tier memory openings and third-tier isolation openings according to an embodiment of the present disclosure.

FIGS. 65A-65D are various views of the third exemplary structure after formation of third-tier sacrificial memory opening fill material portions and third-tier sacrificial isolation opening fill material portions according to an embodiment of the present disclosure.

FIGS. 66A-66D are various views of the third exemplary structure after formation of an etch mask layer according to an embodiment of the present disclosure.

FIGS. 67A-67D are various views of the third exemplary structure after patterning the etch mask layer according to an embodiment of the present disclosure.

FIGS. 68A-68D are various views of the third exemplary structure after formation of voids in the isolation openings according to an embodiment of the present disclosure.

FIGS. 69A-69D are various views of the third exemplary structure after removal of the etch mask layer according to an embodiment of the present disclosure.

FIGS. 70A-70D are various views of the third exemplary structure after laterally expanding the isolation openings according to an embodiment of the present disclosure.

FIGS. 71A-71D are various views of the third exemplary structure after replacement of the sacrificial material layers with electrically conductive layers according to an embodiment of the present disclosure.

FIGS. 72A-72D are various views of the third exemplary structure after formation of isolation opening fill structures according to an embodiment of the present disclosure.

FIGS. 73A-73D are various views of the third exemplary structure after formation of voids in memory openings according to an embodiment of the present disclosure.

FIGS. 74A-74D are various views of the third exemplary structure after formation of memory opening fill structures according to an embodiment of the present disclosure.

### DETAILED DESCRIPTION

As discussed above, the embodiments of the present disclosure are directed to a three-dimensional memory device including pillar shaped trench bridge structures which reduce or prevent inclination of word line layer stacks and methods of forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁻⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

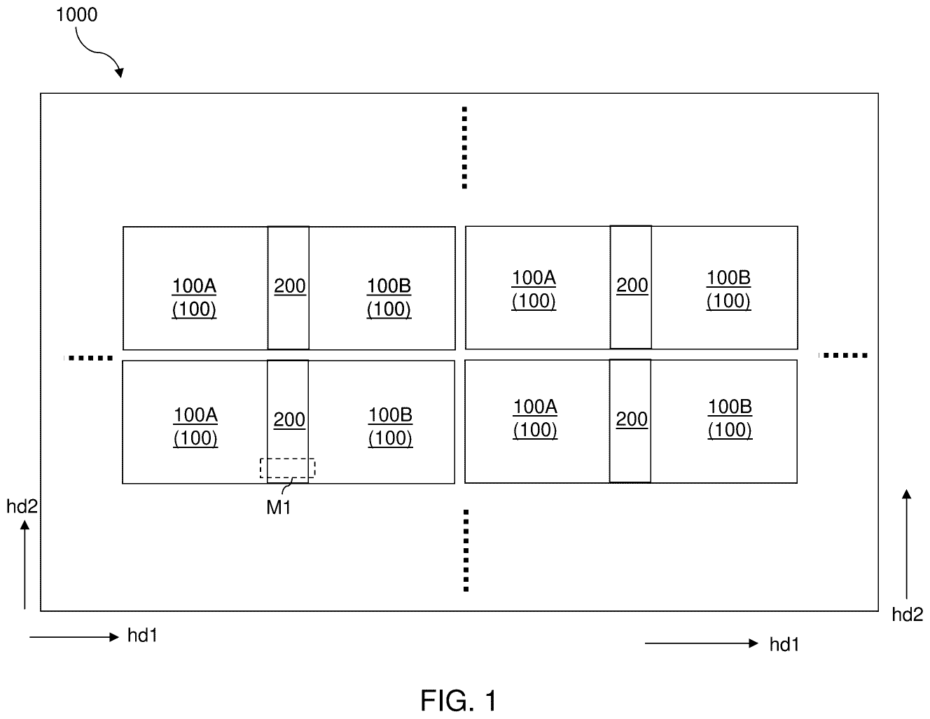

Referring to FIG. 1, a semiconductor die 1000 including multiple three-dimensional memory array regions and inter-array region is illustrated in various views. The semiconductor die 1000 can include multiple planes, each of which includes two memory array regions 100, such as a first memory array region 100A and a second memory array region 100B that are laterally spaced apart by a respective inter-array region 200. Generally, a semiconductor die 1000 may include a single plane or multiple planes. The total number of planes in the semiconductor die 1000 may be selected based on performance requirements on the semiconductor die 1000. A pair of memory array regions 100 in a plane may be laterally spaced apart along a first horizontal direction hd1 (which may be the word line direction). A second horizontal direction hd2 (which may be the bit line direction) can be perpendicular to the first horizontal direction hd1.

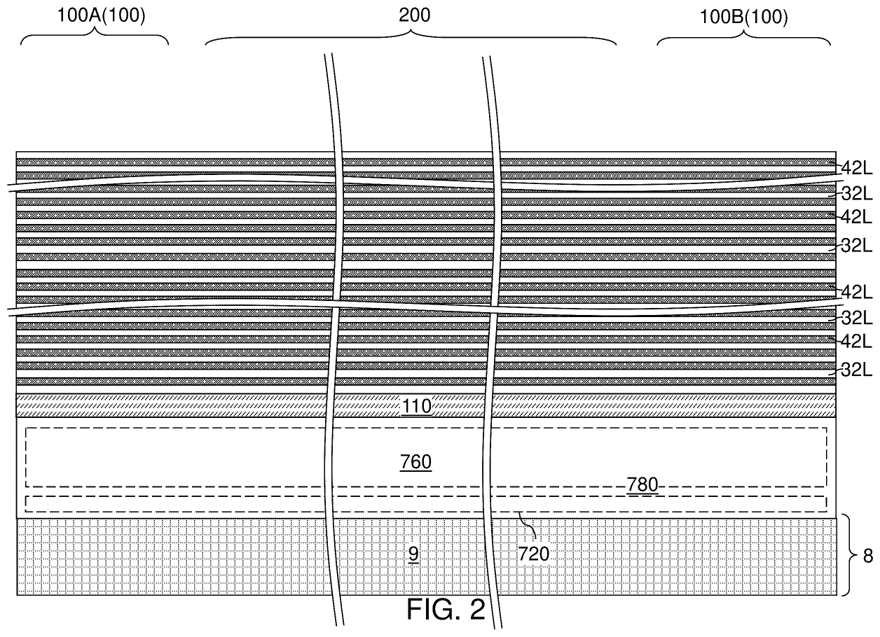

Referring to FIG. 2, a first exemplary structure according to a first embodiment of the present disclosure is illustrated. The region illustrated in FIG. 2 corresponds to region M1 in FIG. 1. The first exemplary structure comprises a substrate 8 including a substrate material layer 9. The substrate material layer 9 may comprise a semiconductor material layer, a dielectric material layer, or a combination thereof. In one embodiment, the substrate 8 may comprise a commercially available semiconductor substrate, such as a single crystalline silicon wafer, and the substrate material layer 9 may comprise a doped well in the top surface of the silicon wafer or an epitaxial silicon layer on the silicon wafer. Thus, in one embodiment, the substrate material layer 9 comprises a single crystalline silicon layer. In this case, semiconductor devices 720, such as complementary metal oxide semiconductor (CMOS) devices (e.g., peripheral or driver circuit devices for the overlying memory devices), may be formed in or over the substrate material layer 9. Alternatively, the peripheral or driver circuit devices may be formed on a separate substrate and then bonded to the memory device formed over the substrate 8.

Metal interconnect structures embedded in dielectric material layers can be formed over the substrate material layer 9. The metal interconnect structures are herein referred to as lower-level metal interconnect structures 780, and the dielectric material layers are herein referred to as lower-level dielectric material layers 760. The lower-level metal interconnect structures 780 can be electrically connected to a respective one of the semiconductor devices 720 on the substrate material layer 9.

At least one semiconductor material layer 110 may be formed over the lower-level dielectric material layers 760. The at least one semiconductor material layer 110 may function as a horizontal semiconductor channel in which, or on which, source regions can be subsequently formed. Alternatively, the at least one semiconductor material layer 110 may comprise a source semiconductor layer that functions as a common source region for vertical semiconductor channels to be subsequently formed. Additionally or alternatively, the at least one semiconductor material layer 110 may comprise a source-level continuous sacrificial material layer that is subsequently replaced with a source contact layer that contacts bottom ends of vertical semiconductor channels to be subsequently formed, and functions as a portion of a common source region for the vertical semiconductor channels.

A vertically alternating sequence of continuous insulating layers 32L and continuous sacrificial material layers 42L can be formed over the at least one semiconductor material layer 110. As used herein, a “vertically alternating sequence” or an “alternating stack” refers to a sequence of multiple instances of a first element and multiple instances of a second element that is arranged such that an instance of a second element is located between each vertically neighboring pair of instances of the first element, and an instance of a first element is located between each vertically neighboring pair of instances of the second element.

The continuous insulating layers 32L can be composed of a first material, and the continuous sacrificial material layers 42L can be composed of a second material, which is different from the first material. The first material of the continuous insulating layers 32L may be at least one insulating material. Insulating materials that may be used for the continuous insulating layers 32L include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the continuous insulating layers 32L may be silicon oxide.

The second material of the continuous sacrificial material layers 42L is a sacrificial material that may be removed selective to the first material of the continuous insulating layers 32L. As used herein, a removal of a material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material.

The continuous sacrificial material layers 42L may comprise an insulating material, a semiconductor material, or a conductive material. The second material of the continuous sacrificial material layers 42L may be subsequently replaced with electrically conductive electrodes which may function, for example, as control gate electrodes of a vertical NAND device. In one embodiment, the continuous sacrificial material layers 42L may be material layers that comprise silicon nitride.

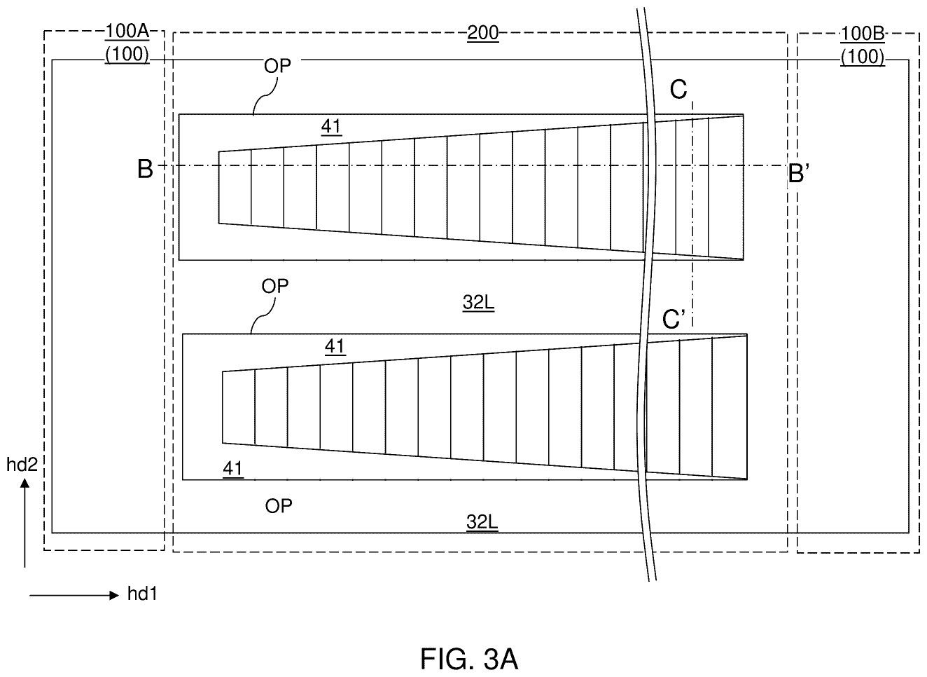

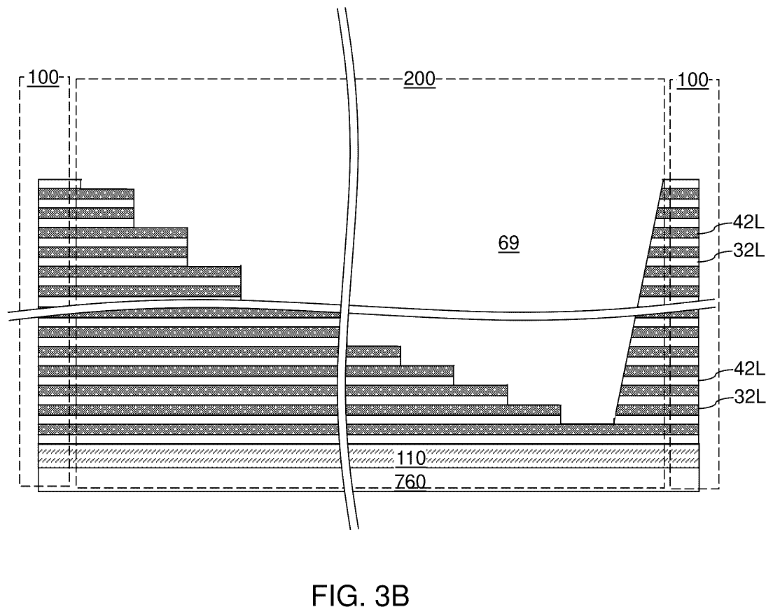

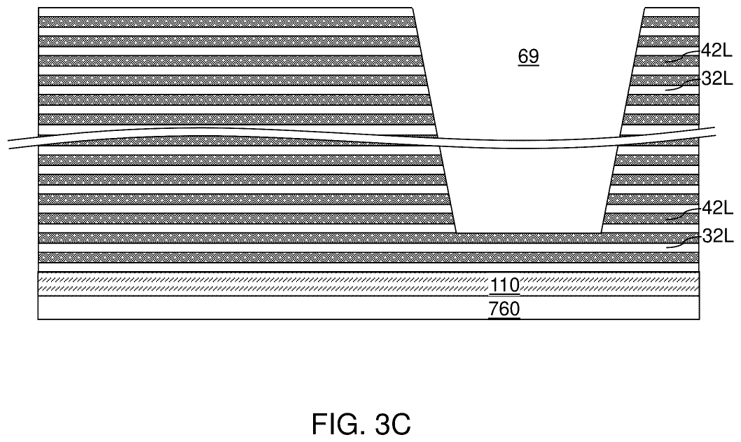

Referring to FIGS. 3A-3C, staircases can be formed through the vertically alternating sequence of continuous insulating layers 32L and continuous sacrificial material layers 42L. Stepped surfaces can be formed within the areas of the staircases. A hard mask layer (not shown) such as a metallic or dielectric mask material layer can be formed over the vertically alternating sequence, and can be patterned to form multiple rectangular openings. The areas of the openings within the hard mask layer correspond to stairwells (i.e., areas in which staircases including stepped surfaces are to be subsequently formed). The peripheries of the opening OP (i.e., stairwell) may or may not be rectangular. Each opening through the hard mask layer may be rectangular, and may have a pair of sides that are parallel to the horizontal direction hd1 and a pair of sides that are parallel to the second horizontal direction hd2.

Regions of the vertically alternating sequence (32L, 42L) located within the peripheries of the openings OP in the hard mask layer can be etched by performing multiple iterations of a combination of a respective lithographic patterning process and a respective anisotropic etch process. A stepped cavity 69 having a stepped bottom surface is formed within each area enclosed by a respective periphery of an opening OP in the topmost continuous insulating layer 32L in the inter-array region 200. The inter-array region 200 is located between the first memory array region 100A and a second memory array region 100B that are laterally spaced from each other along the first horizontal direction hd1.

Generally, the stairwell sidewalls 41 of the vertically alternating sequence (32L, 42L) can be physically exposed to the staircases. The sidewalls 41 of the vertically alternating sequence (32L, 42L) can be formed with a taper angle such that portions of each stepped cavity 69 in the stairwells having a greater depth has a lesser lateral extent. While FIG. 3B illustrates an embodiment in which the depth of each stepped cavity 69 in the staircases increases or decreases monotonically as a function of a lateral distance along the first horizontal direction hd1 for simplicity of illustration, the depth of each stepped cavity 69 in a respective stairwell containing the respective staircase can generally increase or decrease along the first horizontal direction hd1 with localized regions in which the depth changes in an opposite way. In other words, a stepped cavity 69 in a stairwell may have a depth that generally increases along the first horizontal direction hd1 except in localized regions in which the depth generally decreases along the first horizontal direction hd1. Alternatively, a stepped cavity 69 in a stairwell may have a depth that generally decreases along the first horizontal direction hd1 except in localized regions in which the depth generally increases along the first horizontal direction hd1. Such variations in the vertical cross-sectional profiles of staircases along the first horizontal direction hd1 are expressly contemplated herein.

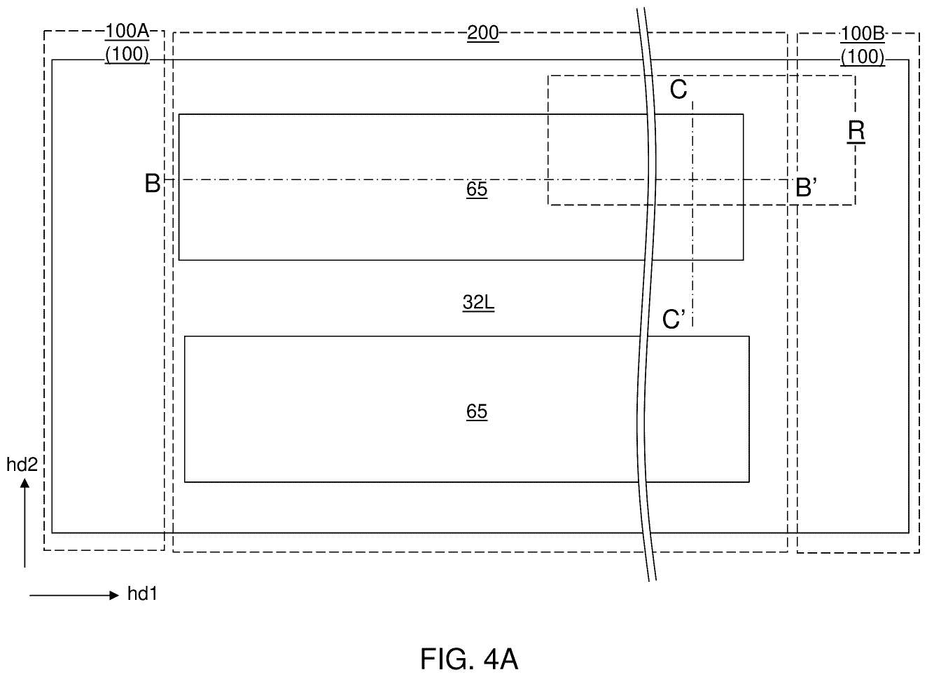

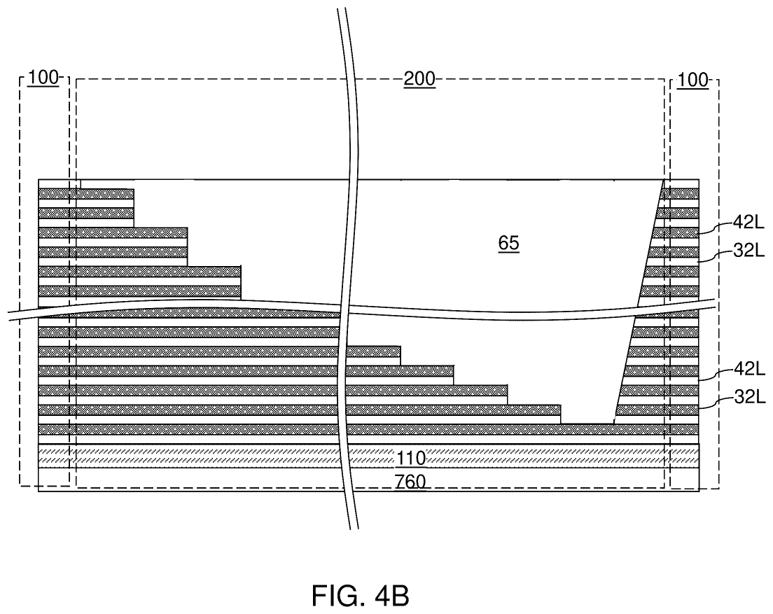

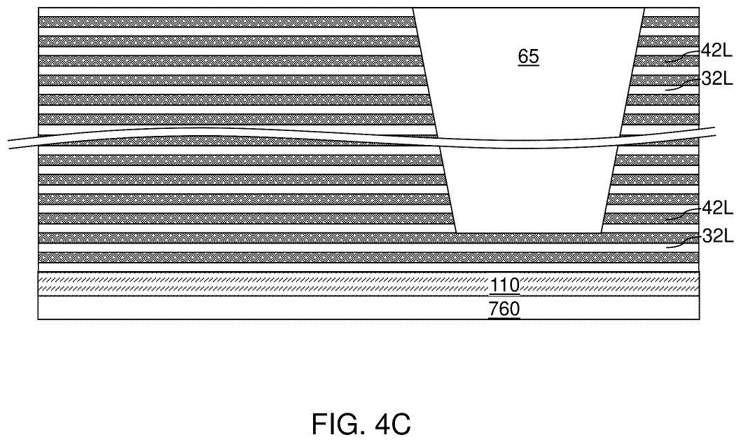

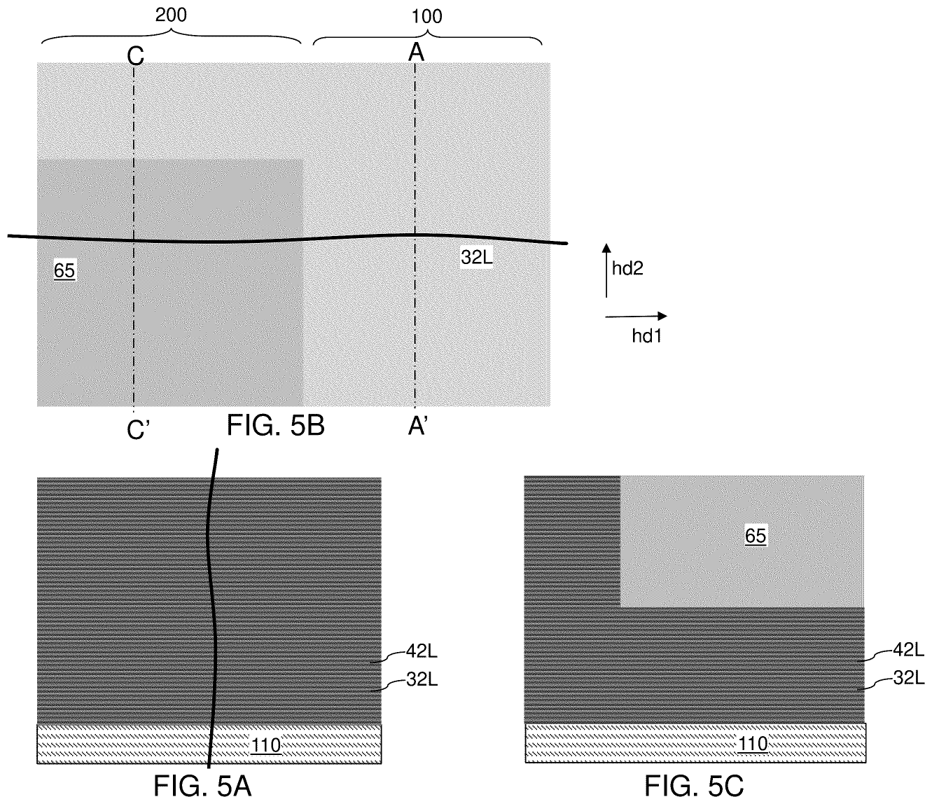

Referring to FIGS. 4A-4C and 5A-5C, a dielectric fill material, such as silicon oxide, can be deposited in the stepped cavities 69. FIG. 5A is a vertical cross-sectional view of a region R of the first exemplary structure in FIG. 4A. Excess portions of the dielectric fill material may be removed from above the horizontal plane including a topmost surface of the topmost continuous insulating layer 32L. Each remaining portion of the dielectric fill material that fills a respective one of the stepped cavities 69 constitutes a stepped dielectric material portion 65. In summary, multiple sets of stepped surfaces can be formed by patterning the vertically alternating sequence (32L, 42L) and the stepped dielectric material portions 65 can be formed over the multiple sets of stepped surfaces.

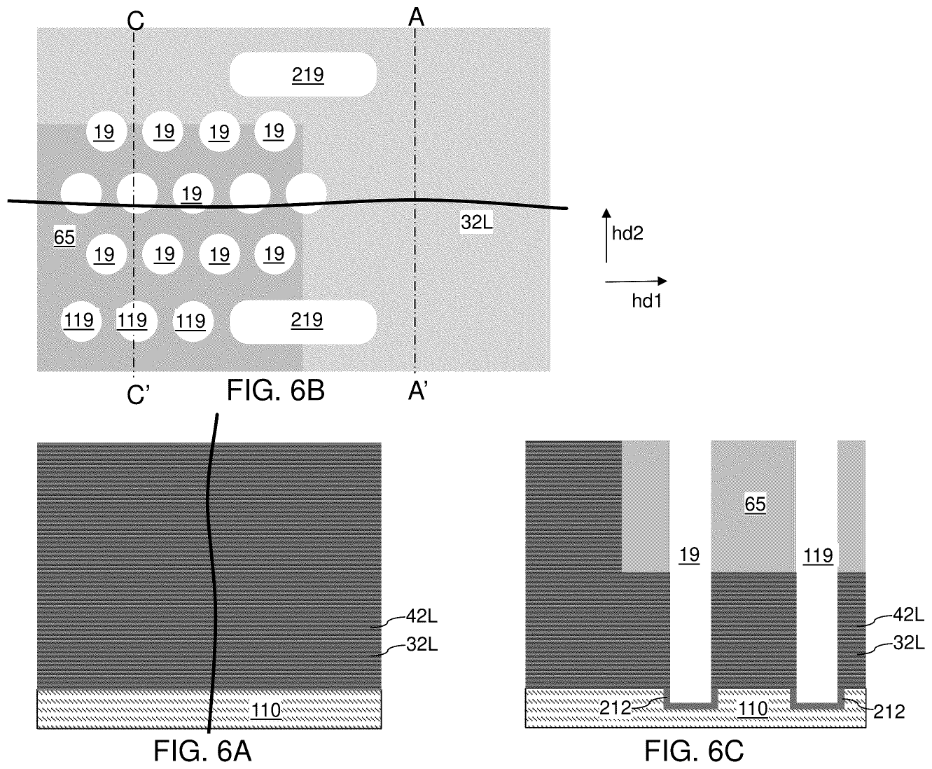

Referring to FIGS. 6A-6C, a photoresist layer (not shown) can be applied over the first exemplary structure, and can be lithographically patterned to form openings. An anisotropic etch process can be performed to transfer the pattern of the openings through the vertically alternating sequence (32L, 42L) and the stepped dielectric material portions 65. Cavities vertically extending from a horizontal plane including the top surfaces of the stepped dielectric material portions 65 to the top surface of the semiconductor material layer 110 (or another layer underlying the vertically alternating sequence (32L, 42L)) can be formed. The cavities may include elongated pillar cavities 219, support openings 19, and stepped-region isolation openings 119.

The elongated pillar cavities 219 laterally extend along the first horizontal direction (e.g., word line direction) hd1. Each elongated pillar cavity 219 comprises a center portion having a uniform width along the second horizontal direction (e.g., bit line direction) hd2. In one embodiment, a first subset of the elongated pillar cavities 219 may be laterally offset from the stepped dielectric material portions 65, and a second subset of the elongated pillar cavities 219 may vertically extend through a portion of a respective one of the stepped dielectric material portions 65. In some embodiments, a two-dimensional array of elongated pillar cavities 219 may be formed. In this case, multiple rows of elongated pillar cavities 219 may be laterally spaced from each other along the second horizontal direction hd2. Each row of elongated pillar cavities 219 may comprise a plurality of elongated pillar cavities 219 that are arranged along the first horizontal direction hd1. The width of each elongated pillar cavity 219 may be in a range from 40 nm to 300 nm, such as from 60 nm to 200 nm, although lesser and greater widths may also be employed. The length-to-width ratio of each elongated pillar cavity 219 may be in a range from 2 to 30, such as from 3 to 20, and/or from 4 to 15, although lesser and greater length-to-width ratios may also be employed.

The support openings 19 can be formed through the stepped dielectric material portions 65 and underlying stepped surfaces of the vertically alternating sequence (32L, 42L). The support openings 19 can be laterally spaced apart from each other, and may have a respective circular or oval-shaped horizontal cross-sectional shape. The lateral dimension (such as a diameter) of each support opening 19 may be in a range from 30 nm to 200 nm, such as from 50 nm to 120 nm, although lesser and greater lateral dimensions may also be employed.

The stepped-region isolation openings 119 are formed through a respective set of stepped surfaces of the vertically alternating sequence (32L, 42L) and through a respective stepped dielectric material portion 65. The stepped-region isolation openings 119 can be formed as rows of stepped-region isolation openings 119 that are arranged along the first horizontal direction hd1 and aligned to a respective one of the elongated pillar cavities 219 along the first horizontal direction hd1. In one embodiment, a combination of an elongated pillar cavity 219 and a row of stepped-region isolation openings 119 may be arranged along the first horizontal direction hd1 midway through a stepped dielectric material portion 65 (i.e., through a staircase region) along the second horizontal direction hd2.

In one embodiment, a thermal conversion process, such as a thermal oxidation process and/or a thermal nitridation process, may be performed to convert physically exposed surface portions of the semiconductor material layer 110 (or of the semiconductor substrate 8 if layer 110 is omitted) into dielectric liners 212 including a dielectric oxide or a dielectric nitride of a semiconductor material of the semiconductor material layer 110 (or of the semiconductor substrate 8 if layer 110 is omitted). If the semiconductor material is silicon, then the dielectric liners 212 comprise silicon oxide, silicon nitride or silicon oxynitride.

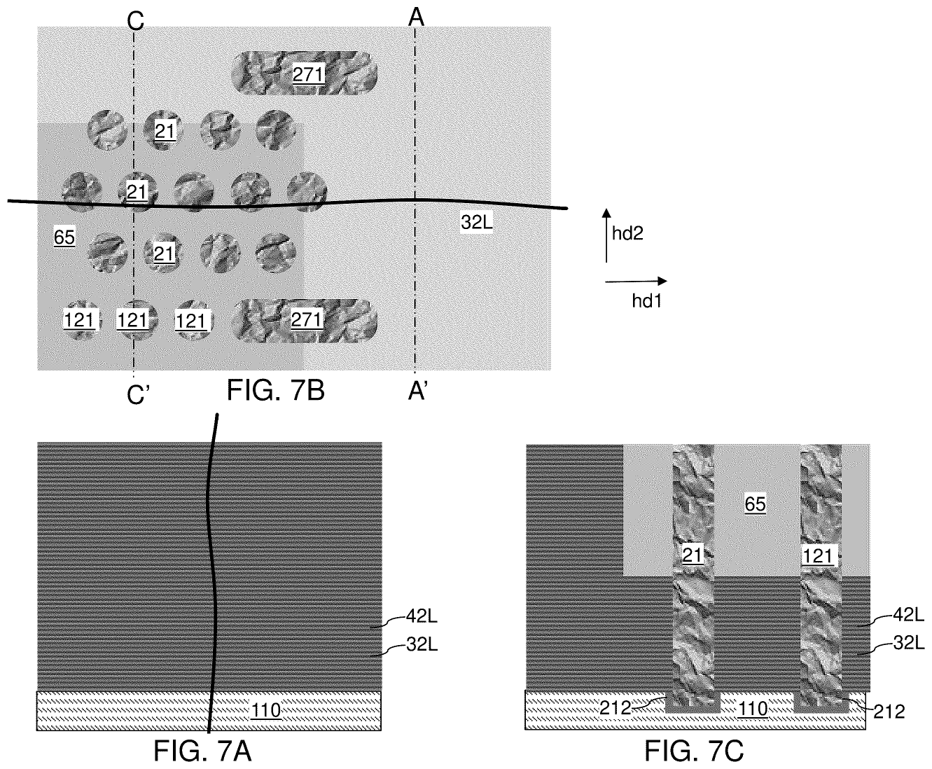

Referring to FIGS. 7A-7C, a first sacrificial fill material can be deposited in the elongated pillar cavities 219, the support openings 19, and the stepped-region isolation openings 119. The first sacrificial fill material comprises a material that can be subsequently removed selective to the materials of the vertically alternating sequence (32L, 42L), the dielectric liners 212 and the stepped dielectric material portions 65. For example, the first sacrificial fill material may comprise a carbon-based material (such as amorphous carbon or diamond-like carbon), or may comprise a silicon-based material (such as amorphous silicon, polysilicon, or silicon-germanium). Excess portions of the first sacrificial fill material can be removed from above the vertically alternating sequence by a planarization process, which may comprise a chemical mechanical polishing (CMP) process or a recess etch process. Each remaining portion of the first sacrificial fill material that fills an elongated pillar cavity 219 constitutes an elongated sacrificial pillar structure 271. Each remaining portion of the first sacrificial fill material that fills a support opening 19 constitutes a sacrificial support opening fill structure 21. Each remaining portion of the first sacrificial fill material that fills a stepped-region isolation opening 119 constitutes a sacrificial isolation opening fill material portion 121.

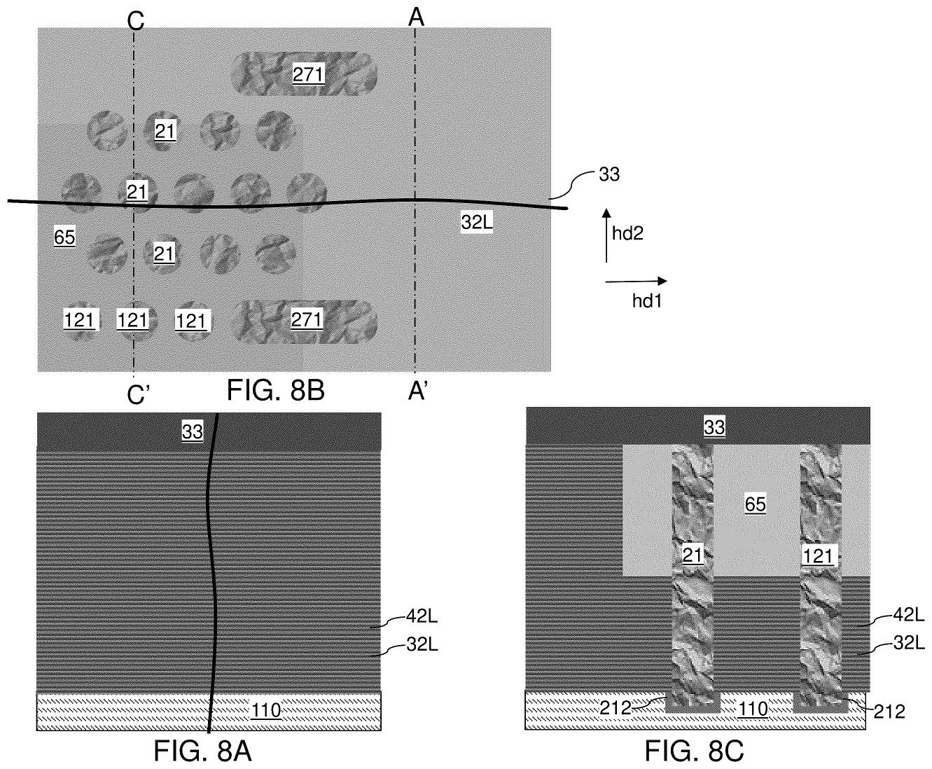

Referring to FIGS. 8A-8C, an etch mask layer 33 can be formed over the vertically alternating sequence (32L, 42L) and the stepped dielectric material portions 65. The etch mask layer 33 comprises a hard mask material that may be subsequently removed selective to the topmost layer 32L of the vertically alternating sequence (32L, 42L), or may comprise a patterned photoresist layer. In one embodiment, the etch mask layer 33 comprises silicon nitride.

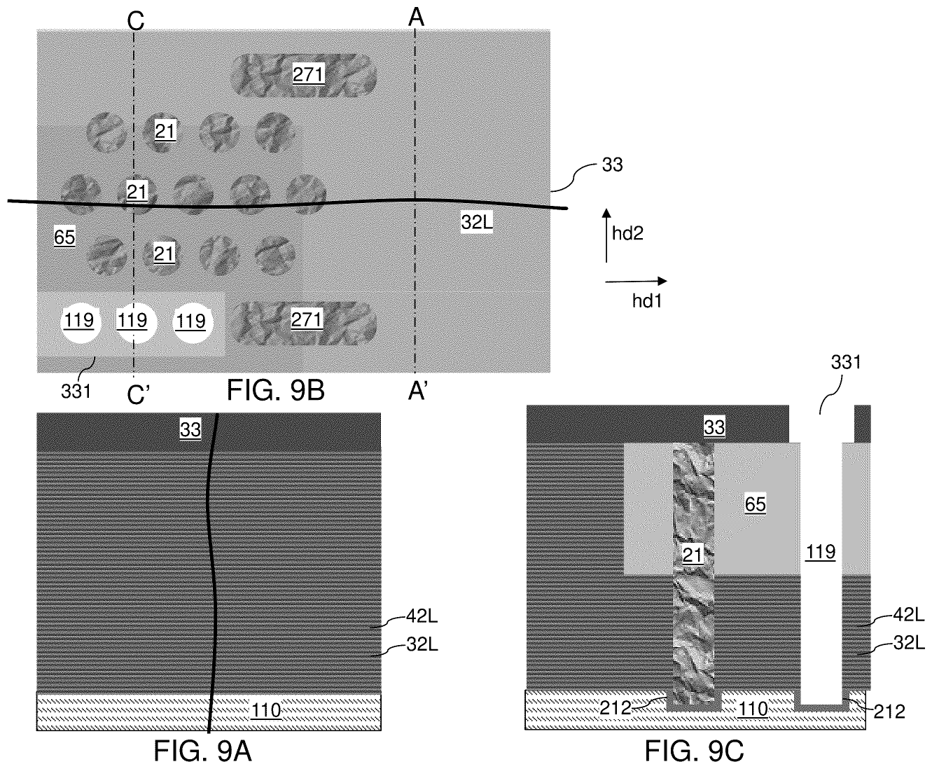

Referring to FIGS. 9A-9C, the etch mask layer 33 can be patterned to form an opening above each row of sacrificial isolation opening fill material portions 121. For example, an elongated opening 331 which extends along the first horizontal direction hd1 may be formed through the etch mask layer 33 above each row of sacrificial isolation opening fill material portions 121. A selective material removal process (such as an ashing process or a wet etch process) may be performed to remove the first sacrificial fill material of the sacrificial isolation opening fill material portions 121 from the stepped-region isolation openings 119 and to reopen the stepped-region isolation openings 119.

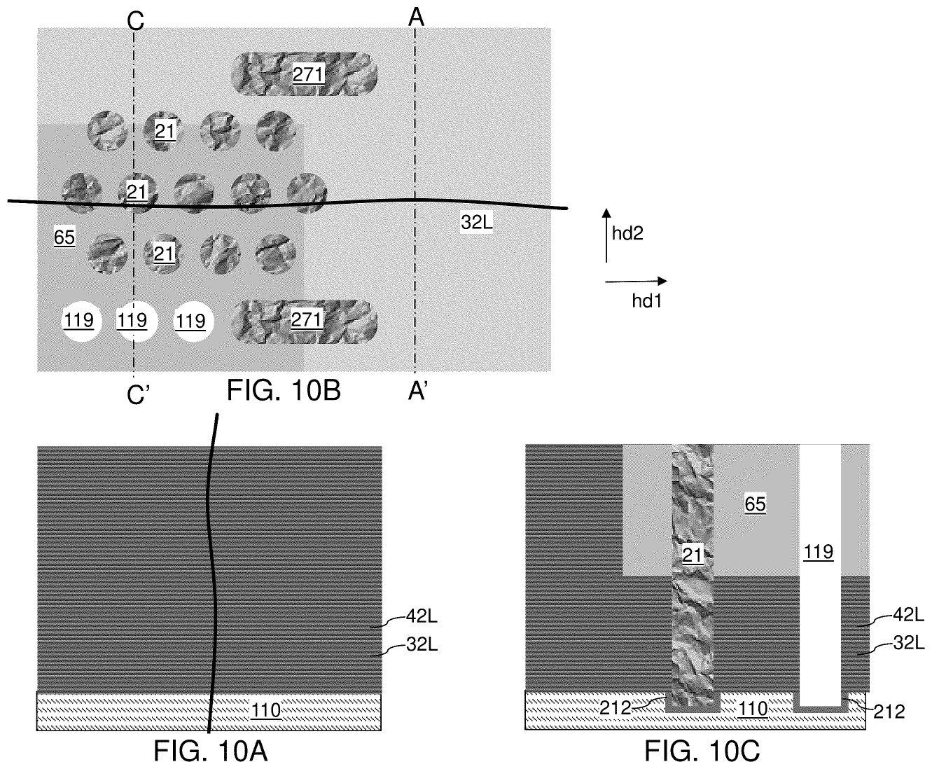

Referring to FIGS. 10A-10C, the etch mask layer 33 may be removed by performing a selective anisotropic etch process, which etches the etch mask layer 33 selective to the materials of the top insulating layers 32L of the vertically alternating sequence (32L, 42L), the stepped dielectric material portions 65, the elongated sacrificial pillar structures 271, the sacrificial support opening fill structures 21, and the dielectric liners 212.

Referring to FIGS. 11A-11C, a second sacrificial fill material that is different from the first sacrificial fill material may be deposited in the volumes of the stepped-region isolation openings 119. For example, the second sacrificial fill material may comprise a semiconductor material (such as amorphous silicon, polysilicon, or silicon-germanium), a carbon-based material (such as amorphous carbon or diamond-like carbon), a polymer material, or a high-etch-rate silicate glass material such as organosilicate glass or borosilicate glass, etc. In an illustrative example, the first sacrificial fill material may comprise a carbon-based material, and the second sacrificial fill material may comprise a semiconductor material, such as amorphous silicon. Excess portions of the second sacrificial fill material may be removed from above the vertically alternating sequence (32L, 42L) by a planarization process such as a chemical mechanical polishing process or a recess etch process. Each remaining portion of the second sacrificial fill material that fills the volumes of the stepped-region isolation openings 119 constitutes a sacrificial staircase-region isolation opening fill structure 115, which is a sacrificial isolation opening fill structure that is located in a staircase region (i.e., a region in which a set of stepped surfaces is present).

Subsequently, a selective removal process may be performed to selectively remove the first sacrificial fill material selective to the second sacrificial fill material and the materials of the vertically alternating sequence (32L, 42L) and the stepped dielectric material portions 65. The elongated sacrificial pillar structures 271 are thus removed from the elongated pillar cavities 219 and the sacrificial support opening fill structures 21 are removed from the support openings 19 to reopen the elongated pillar cavities 219 and the support openings 19. For example, if the first sacrificial fill material comprises a carbon material, then an ashing process may be used to selectively remove the first sacrificial fill material.

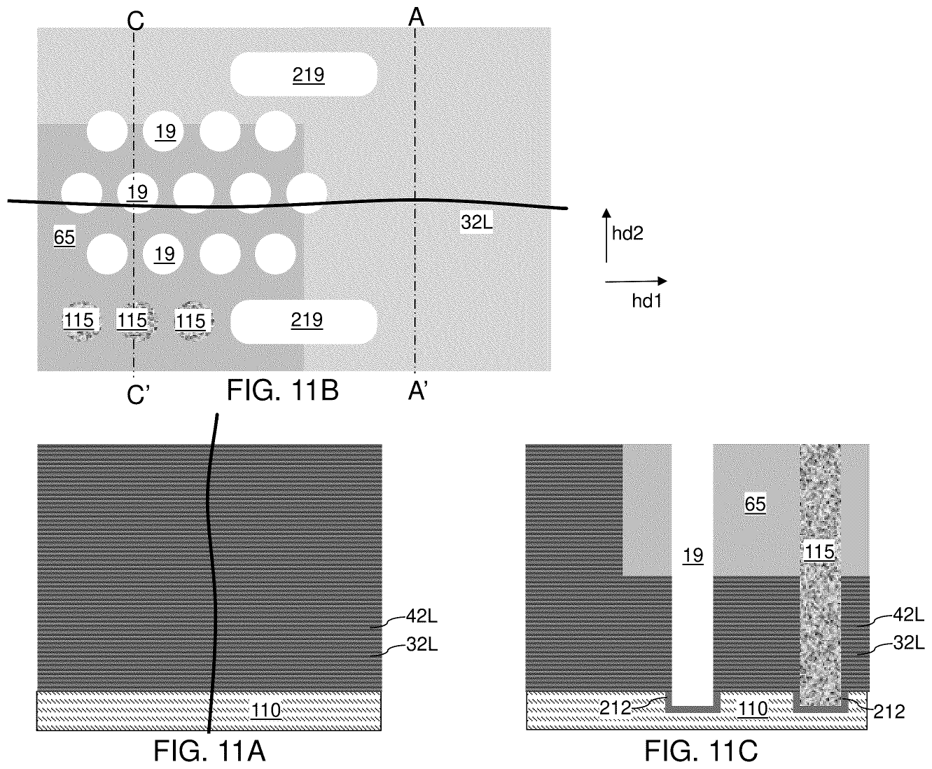

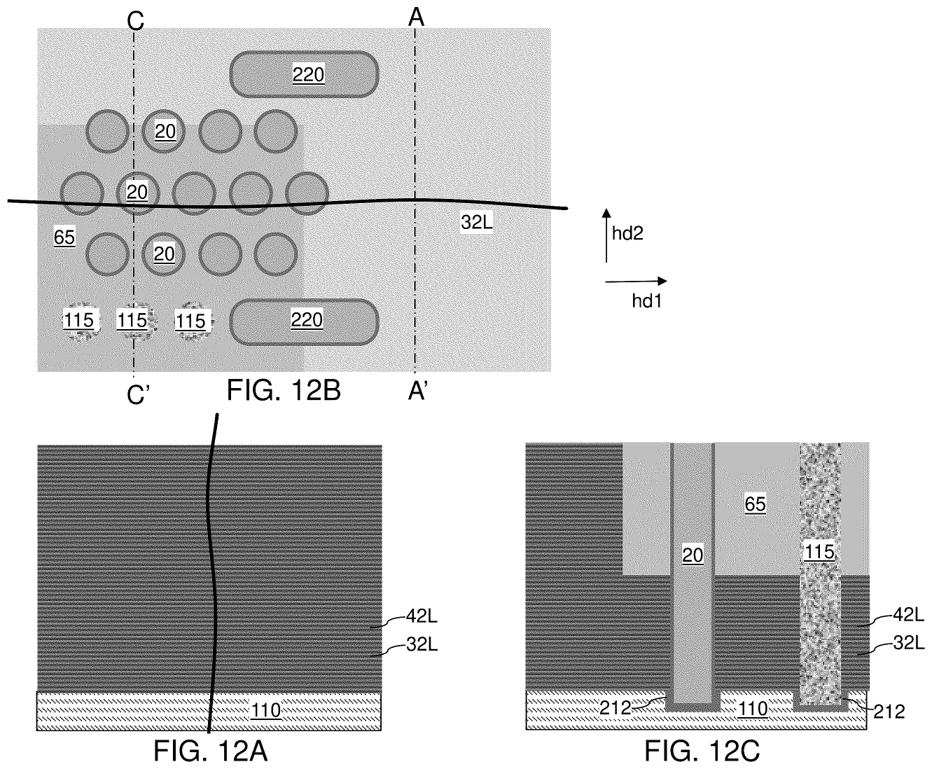

Referring to FIGS. 12A-12C, a dielectric fill material, such as undoped silicate glass (i.e., silicon oxide) or a doped silicate glass, can be conformally deposited in the volumes of the elongated pillar cavities 219 and the support openings 19 and over the vertically alternating sequence (32L, 42L). Excess portions of the dielectric fill material may be removed from above the vertically alternating sequence (32L, 42L) by performing a planarization process, which may comprise a recess etch process and/or a chemical mechanical polishing process. Each remaining portion of the dielectric fill material that fill an elongated pillar cavity 219 constitutes an elongated dielectric pillar structure 220. Each remaining portion of the dielectric fill material that fills a support opening 19 constitutes a dielectric support pillar structure 20. Each of the elongated dielectric pillar structures 220 and the dielectric support pillar structures 20 may vertically extend from a horizontal plane including a topmost surface of the vertically alternating sequence (32L, 42L) at least to a horizontal plane including a bottommost surface of the vertically alternating sequence (32L, 42L).

The elongated dielectric pillar structures 220 are formed through the vertically alternating sequence (32L, 42L), and are laterally extend along the first horizontal direction hd1, and may be laterally spaced apart along the second horizontal direction hd2. In one embodiment, a first subset of the elongated dielectric pillar structures 220 is formed through a respective one of the stepped dielectric material portions 65, and a second subset of the elongated dielectric pillar structures 220 is laterally spaced from the stepped dielectric material portions 65 along the second horizontal direction hd2. The first subset of the elongated dielectric pillar structures 220 may be in direct contact with the vertically alternating sequence (32L, 42L) and a respective stepped dielectric material portion 65. In one embodiment, the dielectric support pillar structures 20 may vertically extend through a respective one of the stepped dielectric material portions 65 and the staircase region of the vertically alternating sequence (32L, 42L). The dielectric support pillar structures 20 and the elongated dielectric pillar structures 220 may comprise a same dielectric fill material, such as undoped silicate glass or a doped silicate glass.

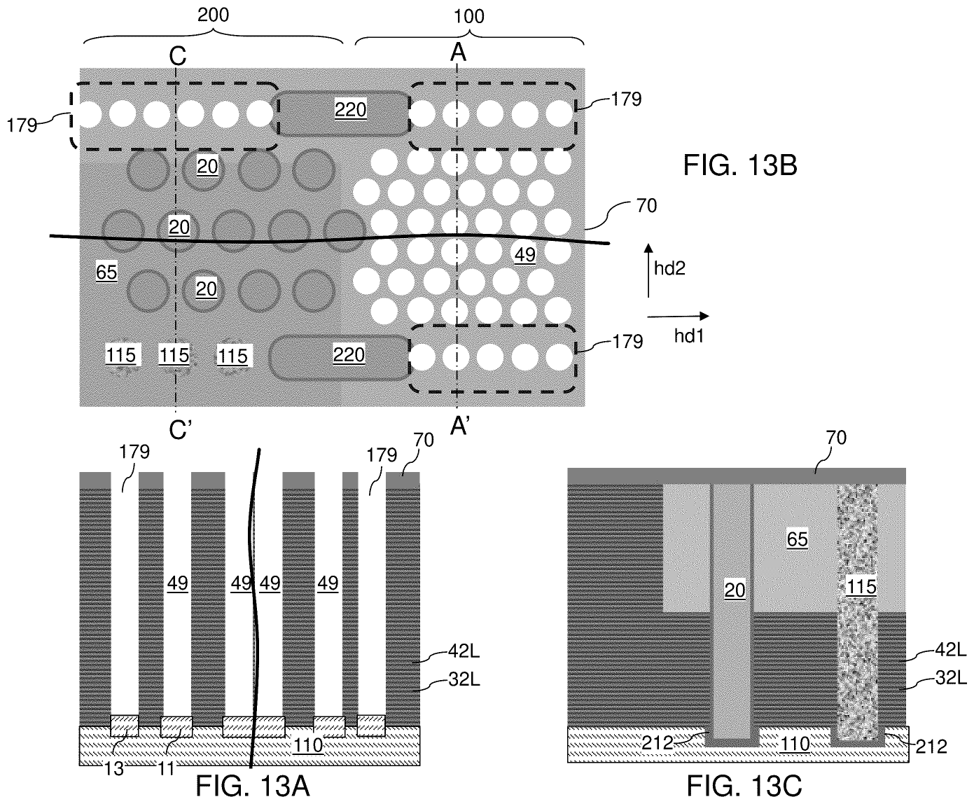

Referring to FIGS. 13A-13C, an insulating cap layer 70 may be formed over the vertically alternating sequence (32L, 42L) and the stepped dielectric material portions 65. The insulating cap layer 70 comprises an insulating material, such as undoped silicate glass or a doped silicate glass, and may have a thickness in a range from 30 nm to 300 nm, such as from 60 nm to 150 nm, although lesser and greater thicknesses may also be employed.

A photoresist layer (not shown) can be applied over the insulating cap layer 70, and can be lithographically patterned to form openings therein. An anisotropic etch process can be performed to transfer the pattern of the openings through the insulating cap layer 70, the vertically alternating sequence (32L, 42L), and the stepped dielectric material portions 65. An array of memory openings 49 is formed within each memory array region (such as the memory array regions 100 illustrated in FIG. 1) in which each layer within the vertically alternating sequence (32L, 42L) is present. Rows of through-stack isolation openings 179 can be formed through the vertically alternating sequence (32L, 42L) between each neighboring pairs of arrays of memory openings 49 (e.g., between adjacent memory blocks) that are spaced apart along the second horizontal direction hd2, and between each neighboring pair of stepped dielectric material portions 65 that are laterally spaced apart along the second horizontal direction hd2. Each of the memory openings 49 and the through-stack isolation openings 179 may be formed through each layer within the vertically alternating sequence (32L, 42L).

In one embodiment, a subset of the through-stack isolation openings 179 may be formed by etching a peripheral portion of a respective one of the elongated dielectric pillar structures 220. In one embodiment, each of the elongated dielectric pillar structures 220 may comprise at least one peripheral portion that is removed during formation of a respective through-stack isolation opening 179. In one embodiment, a subset of the elongated dielectric pillar structures 220 may comprise a respective pair of peripheral portions that are removed during formation of a respective pair of through-stack isolation openings 179. The photoresist layer may be subsequently removed for example, by ashing.

A selective semiconductor deposition process, such as a selective semiconductor epitaxy process, may be performed to grow semiconductor material portions from physically exposed surfaces of the semiconductor material layer 110. In this case, a pedestal channel portion 11 may be formed at the bottom of each memory opening 49. A semiconductor pedestal 13 may be formed at the bottom of each through-stack isolation opening 179. The semiconductor pedestals 13 and the pedestal channel portion 11 may comprise a same semiconductor material, such as silicon.

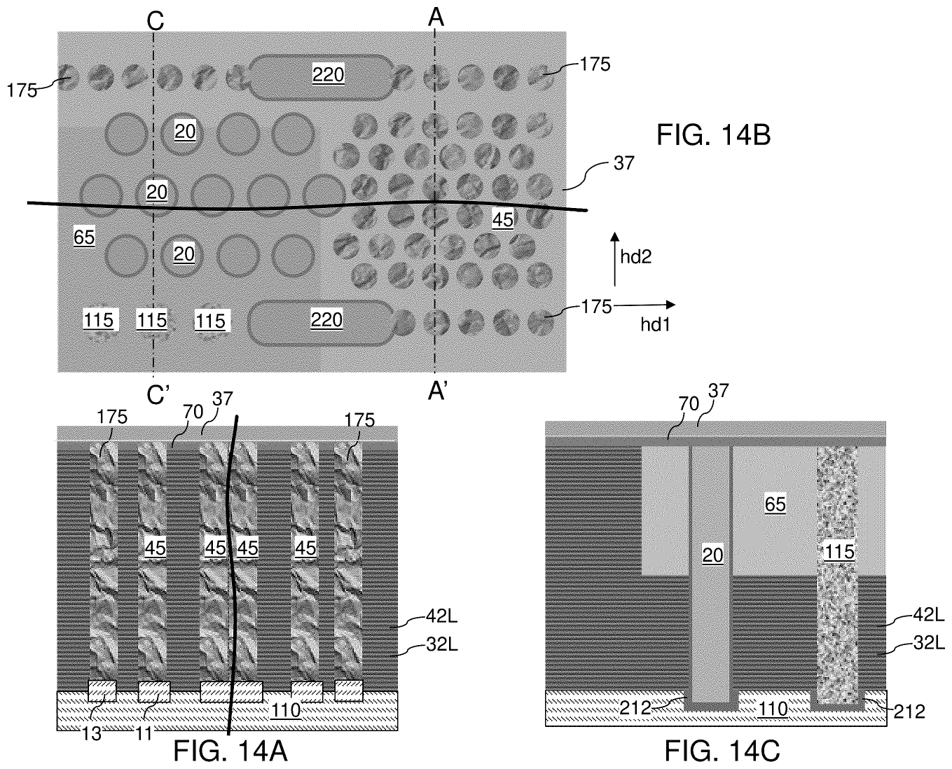

Referring to FIGS. 14A-14C, a third sacrificial fill material can be deposited in the memory openings 49 and the through-stack isolation openings 179. The third sacrificial fill material can comprise any material that may be employed for the first sacrificial fill material. Excess portions of the third sacrificial fill material may be removed from above the horizontal plane including a top surface of the insulating cap layer 70 by performing a planarization process, which may comprise a recess etch process or a chemical mechanical polishing process. Each remaining portion of the third sacrificial fill material that filles a memory opening 49 constitutes a sacrificial memory opening fill structure 45. Each remaining portion of the third sacrificial fill material that fills a through-stack isolation opening 179 constitutes a sacrificial through-stack isolation opening fill structure 175.

A first hard mask layer 37 can be formed above the insulating cap layer 70, the sacrificial memory opening fill structures 45, and the sacrificial through-stack isolation opening fill structures 175. The first hard mask layer 37 comprises a first hard mask material, which may be, for example, silicon oxide. The thickness of the first hard mask layer 37 may be in a range from 30 nm to 300 nm, such as from 60 nm to 150 nm, although lesser and greater thicknesses may also be employed.

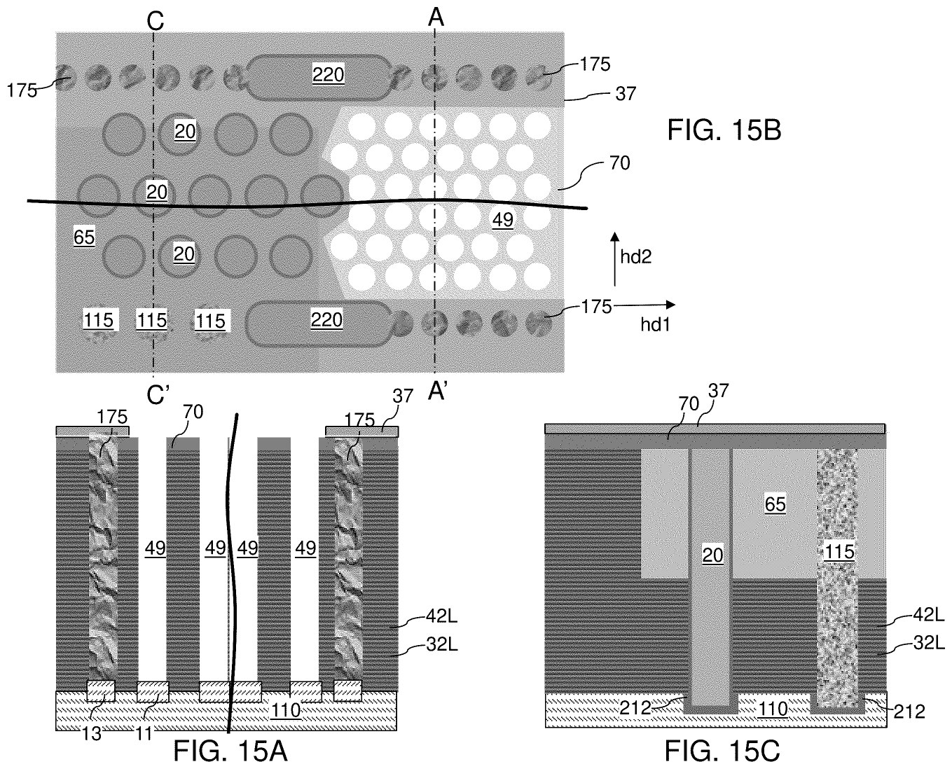

Referring to FIGS. 15A-15C, the first hard mask layer 37 may be patterned to form an opening over each array of sacrificial memory opening fill structures 45. For example, a photoresist layer (not shown) can be applied over the first hard mask layer 37, and can be lithographically patterned to form openings in areas that overlie the sacrificial memory opening fill structures 45. An etch process can be performed to remove unmasked portions of the first hard mask layer 37. The photoresist layer can be subsequently removed, for example, by ashing.

Subsequently, the sacrificial memory opening fill structures 45 can be removed from the memory openings 49 selective to the materials of the vertically alternating sequence (32L, 42L), the first hard mask layer 37, and the pedestal channel portions 11. The memory openings 49 are reopened while the through-stack isolation openings 179 remain filled with the sacrificial through-stack isolation opening fill structures 175.

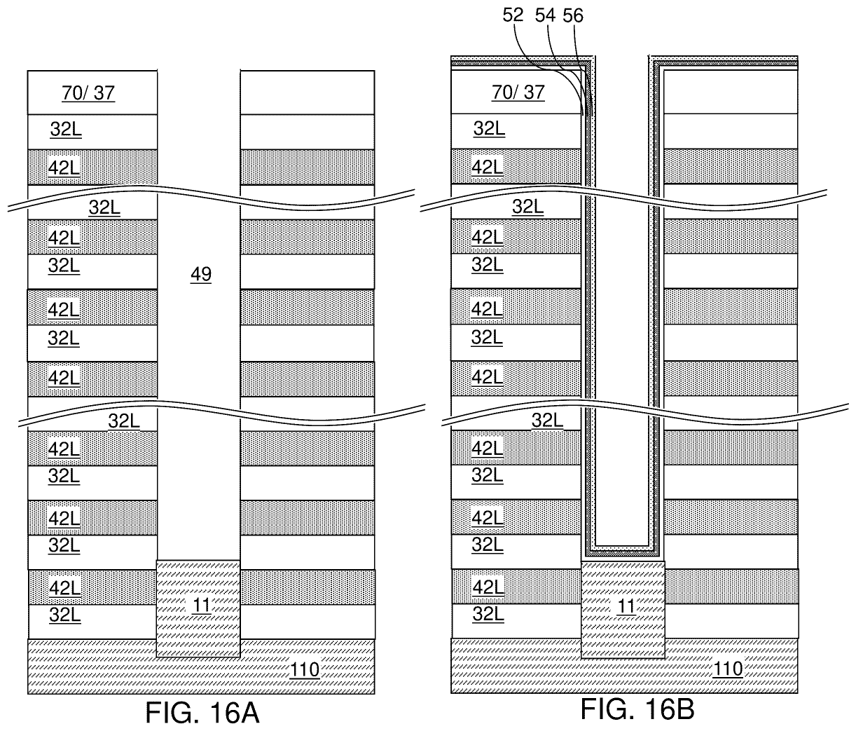

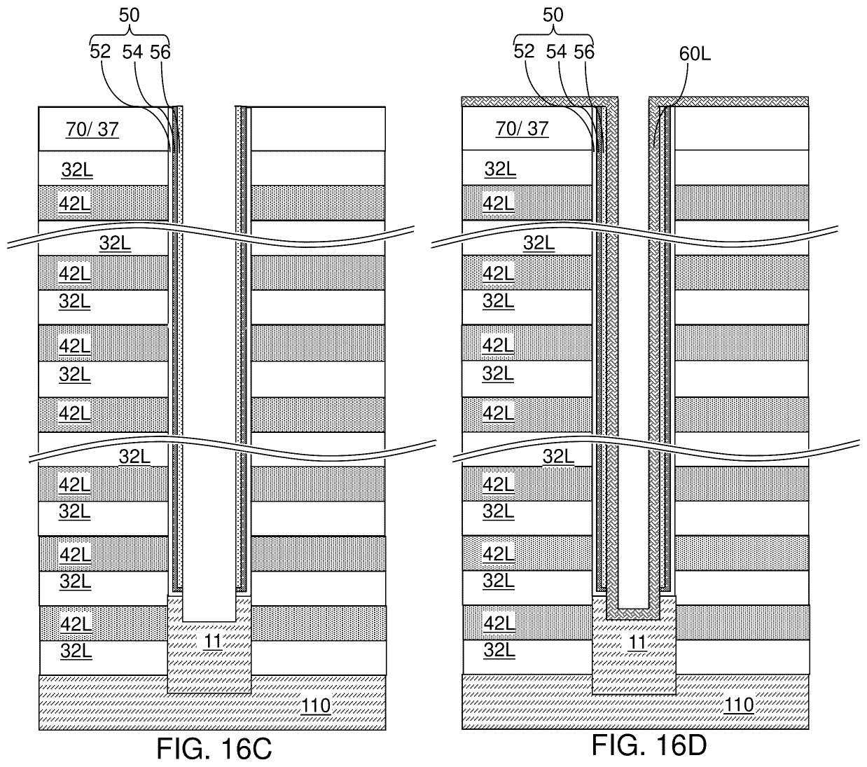

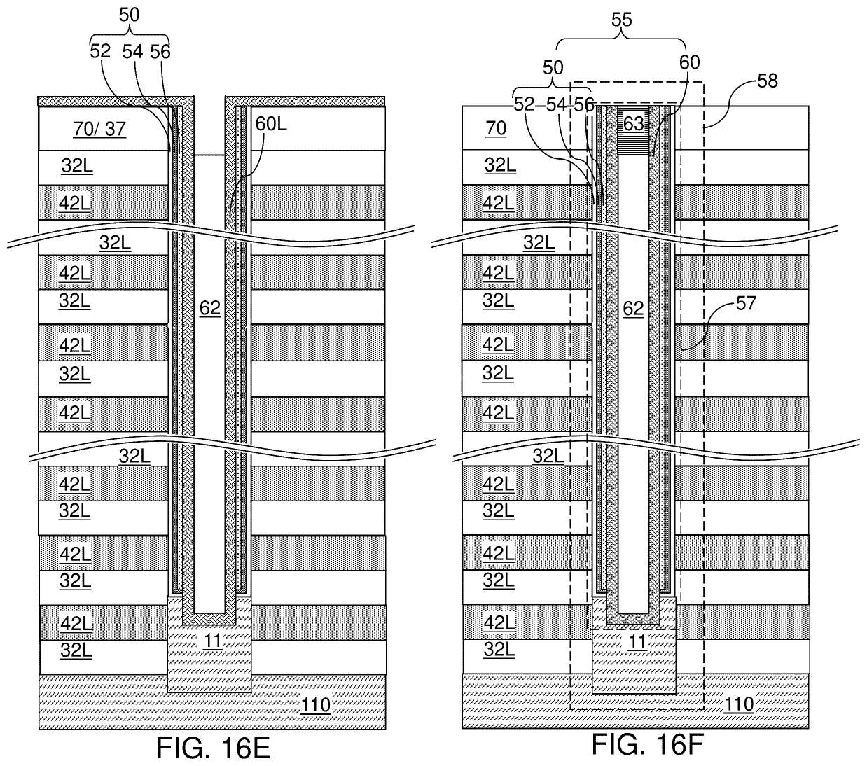

FIGS. 16A-16F are sequential vertical cross-sectional views of a memory opening 49 during formation of a memory opening fill structure according to an embodiment of the present disclosure.

Referring to FIG. 16A, a region around a memory opening 49 is illustrated after removal of a sacrificial memory opening fill structure 45, i.e., after the processing steps described with reference to FIGS. 15A-15C.

Referring to FIG. 16B, a stack of layers including a blocking dielectric layer 52, a memory material layer 54, and a dielectric material liner 56 may be sequentially deposited in the memory openings 49. The blocking dielectric layer 52 may include a single dielectric material layer or a stack of a plurality of dielectric material layers. In one embodiment, the blocking dielectric layer may include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 may include a dielectric metal oxide having a dielectric constant greater than 7.9, i.e., having a dielectric constant greater than the dielectric constant of silicon nitride. The thickness of the dielectric metal oxide layer may be in a range from 1 nm to 20 nm, although lesser and greater thicknesses may also be used. The dielectric metal oxide layer may subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 may include a dielectric semiconductor compound such as silicon oxide, silicon oxynitride, silicon nitride, or a combination thereof.

Subsequently, the memory material layer 54 can be formed. Generally, the memory material layer may comprise any memory material such as a charge storage material, a ferroelectric material, a phase change material, or any material that can store data bits in the form of presence or absence of electrical charges, a direction of ferroelectric polarization, electrical resistivity, or another measurable physical parameter. In one embodiment, the memory material layer 54 can be a continuous layer or patterned discrete portions of a charge trapping material including a dielectric charge trapping material, which can be, for example, silicon nitride. Alternatively, the memory material layer 54 can include a continuous layer or patterned discrete portions of a conductive material such as doped polysilicon or a metallic material that is patterned into multiple electrically isolated portions (e.g., floating gates), for example, by being formed within lateral recesses into continuous sacrificial material layers 42L. In one embodiment, the memory material layer 54 includes a silicon nitride layer. In one embodiment, the continuous sacrificial material layers 42L and the continuous insulating layers 32L can have vertically coincident sidewalls, and the memory material layer 54 can be formed as a single continuous layer.

In another embodiment, the continuous sacrificial material layers 42L can be laterally recessed with respect to the sidewalls of the continuous insulating layers 32L, and a combination of a deposition process and an anisotropic etch process can be employed to form the memory material layer 54 as a plurality of memory material portions that are vertically spaced apart. While the present disclosure is described employing an embodiment in which the memory material layer 54 is a single continuous layer, embodiments are expressly contemplated herein in which the memory material layer 54 is replaced with a plurality of memory material portions (which can be charge trapping material portions or electrically isolated conductive material portions) that are vertically spaced apart. The memory material layer 54 can be formed, for example, by chemical vapor deposition (CVD), atomic layer deposition (ALD), physical vapor deposition (PVD), or any suitable deposition technique for storing electrical charges therein. The thickness of the memory material layer 54 can be in a range from 2 nm to 20 nm, although lesser and greater thicknesses can also be employed.

The dielectric material liner 56 is an optional material layer that may, or may not, be employed. In case the memory material layer 54 comprises a charge storage layer, the dielectric material liner 56 may comprise a tunneling dielectric layer including a dielectric material through which charge tunneling may be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric material liner 56 may include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric material liner 56 may include a stack of a silicon oxide layer, a silicon oxynitride layer, and a second silicon oxide layer, which is commonly known as an ONO stack. In one embodiment, the dielectric material liner 56 may include a silicon oxide layer that is substantially free of carbon or a silicon oxynitride layer that is substantially free of carbon. The thickness of the dielectric material liner 56 may be in a range from 2 nm to 20 nm, although lesser and greater thicknesses may also be used.

Referring to FIG. 16C, an anisotropic etch process can be performed to remove horizontally-extending portions of the dielectric material liner 56, the memory material layer 54, and the blocking dielectric layer 52 from above the vertically alternating sequence (32, 42) and from the bottom portion of each of the memory openings 49. Optionally, a sacrificial material layer (not shown) may be deposited over the memory film 50 prior to the anisotropic etch process, and may be removed after the anisotropic etch process to protect vertically-extending portions of the memory film 50. A top surface of the pedestal channel portion 11 may be physically exposed at the bottom of each memory opening 49. Each contiguous combination of a remaining portion of the blocking dielectric layer 52, a remaining portion of the memory material layer 54, and a remaining portion of the dielectric material liner 56 located in a memory opening 49 constitutes a memory film 50.

Referring to FIG. 16D, a semiconductor channel material layer 60L can be conformally deposited in the memory openings 49. The semiconductor channel material layer 60L may include an undoped semiconductor material, or a doped semiconductor material. The semiconductor channel material layer 60L comprises at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L may have a uniform doping. In one embodiment, the semiconductor channel material layer 60L include dopants of a first conductivity type at an atomic concentration in a range from 1.0×10¹²/cm³ to 1.0×10¹⁸/cm³, such as from 1.0×10¹⁴/cm³ to 1.0×10¹⁷/cm³. The thickness of the semiconductor channel material layer 60L may be in a range from 2 nm to 10 nm, although lesser and greater thicknesses may also be used. A cavity 49′ is formed in the volume of each memory opening 49 that is not filled with the deposited material layers (52, 54, 56, 60L).

Referring to FIG. 16E, in case the memory openings 49 are not completely filled by the semiconductor channel material layer 60L, a dielectric core layer may be deposited in unfilled volumes of the memory openings 49. The dielectric core layer includes a dielectric material such as silicon oxide or organosilicate glass. The dielectric core layer may be deposited by a conformal deposition method such as low pressure chemical vapor deposition (LPCVD), or by a self-planarizing deposition process such as spin coating. The horizontal portion of the dielectric core layer overlying the topmost surface of the vertically-alternating sequence (32, 42) may be removed, for example, by a recess etch. The recess etch continues until top surfaces of the remaining portions of the dielectric core layer are recessed to a height between the top and bottom surfaces of the topmost continuous insulating layer 32L. Each remaining portion of the dielectric core layer constitutes a dielectric core 62.

Referring to FIG. 16F, a doped semiconductor material having a doping of a second conductivity type may be deposited in cavities overlying the dielectric cores 62. The second conductivity type is the opposite of the conductivity type. For example, if the conductivity type is p-type, the second conductivity type is n-type, and vice versa. Portions of the deposited doped semiconductor material, the semiconductor channel material layer 60L, the dielectric material liner 56, the memory material layer 54, and the blocking dielectric layer 52 that overlie the horizontal plane including the top surface of the insulating cap layer 70 and the first hard mask layer 37 may be removed by a planarization process such as a chemical mechanical planarization (CMP) process.

Each remaining portion of the doped semiconductor material of the second conductivity type constitutes a drain region 63. The dopant concentration in the drain regions 63 may be in a range from 5.0×10¹⁸/cm³ to 2.0×10²¹/cm³, although lesser and greater dopant concentrations may also be used. The doped semiconductor material may be, for example, doped polysilicon.

Each remaining portion of the semiconductor channel material layer 60L constitutes a vertical semiconductor channel 60 through which electrical current may flow when a vertical NAND device including the vertical semiconductor channel 60 is turned on. A dielectric material liner 56 is surrounded by a memory material layer 54, and laterally surrounds a vertical semiconductor channel 60. Each adjoining set of a blocking dielectric layer 52, a memory material layer 54, and a dielectric material liner 56 collectively constitute a memory film 50, which may store electrical charges with a macroscopic retention time. In some embodiments, a blocking dielectric layer 52 may not be present in the memory film 50 at this step, and a blocking dielectric layer may be subsequently formed after formation of isolation opening recesses. As used herein, a macroscopic retention time refers to a retention time suitable for operation of a memory device as a permanent memory device such as a retention time in excess of 24 hours.

Each combination of a memory film 50 and a vertical semiconductor channel 60 within a memory opening 49 constitutes a memory stack structure 55. The memory stack structure 55 is a combination of a vertical semiconductor channel 60, a dielectric material liner 56, a vertical stack of memory elements comprising portions of the memory material layer 54, and an optional blocking dielectric layer 52. In one embodiment, a vertical stack of memory elements may comprise portions of a respective memory material layer 54 that are located at levels of the continuous sacrificial material layers 42L. The memory stack structures 55 can be formed through memory array regions 100 of the and second vertically alternating sequences in which all layers of the and second vertically alternating sequences are present. Each combination of a memory stack structure 55, a dielectric core 62, and a drain region 63 within the memory opening 49 constitutes a memory opening fill structure 58. Generally, memory opening fill structures 58 are formed within the memory openings 49. Each of the memory opening fill structures 58 comprises a respective memory film 50 and a respective vertical semiconductor channel 60. A pedestal channel portion 11 may comprise a lower portion of a memory opening fill structure 58. A combination of a memory film 50, a vertical semiconductor channel 60, an optional dielectric core 62, and a drain region 63 constitutes an upper memory opening fill material portion 57 of a memory opening fill structure 58.

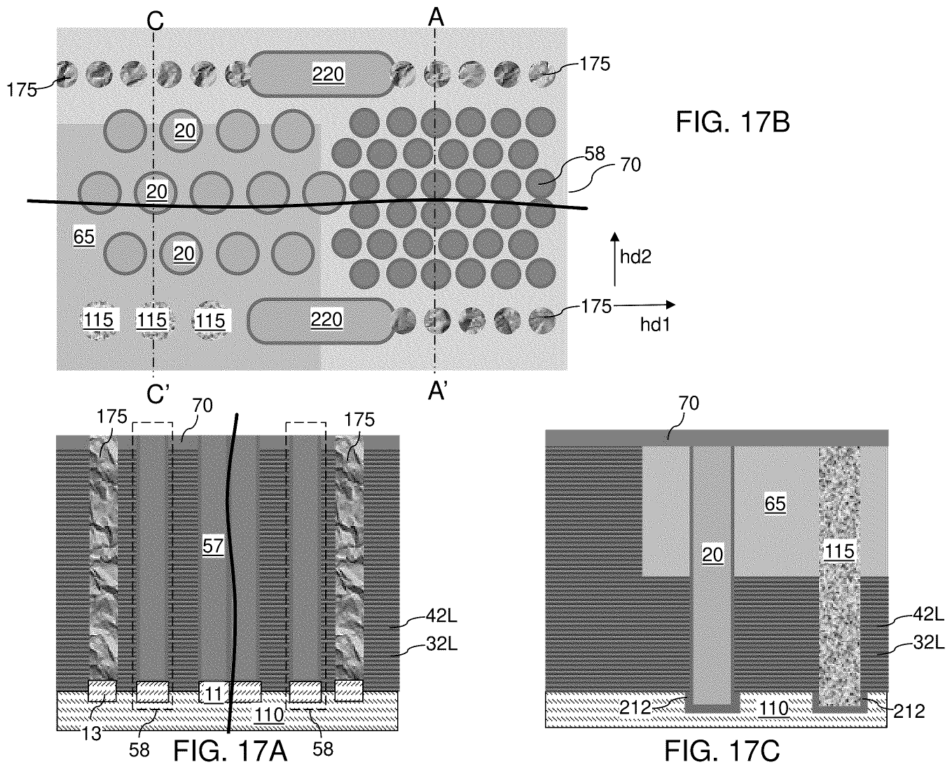

Referring to FIGS. 17A-17C, the first exemplary structure is illustrated after formation of the memory opening fill structure 58. In one embodiment, each of the memory opening fill structures 58 comprises a respective pedestal channel portion 11 having a same material composition as the semiconductor pedestals 13.

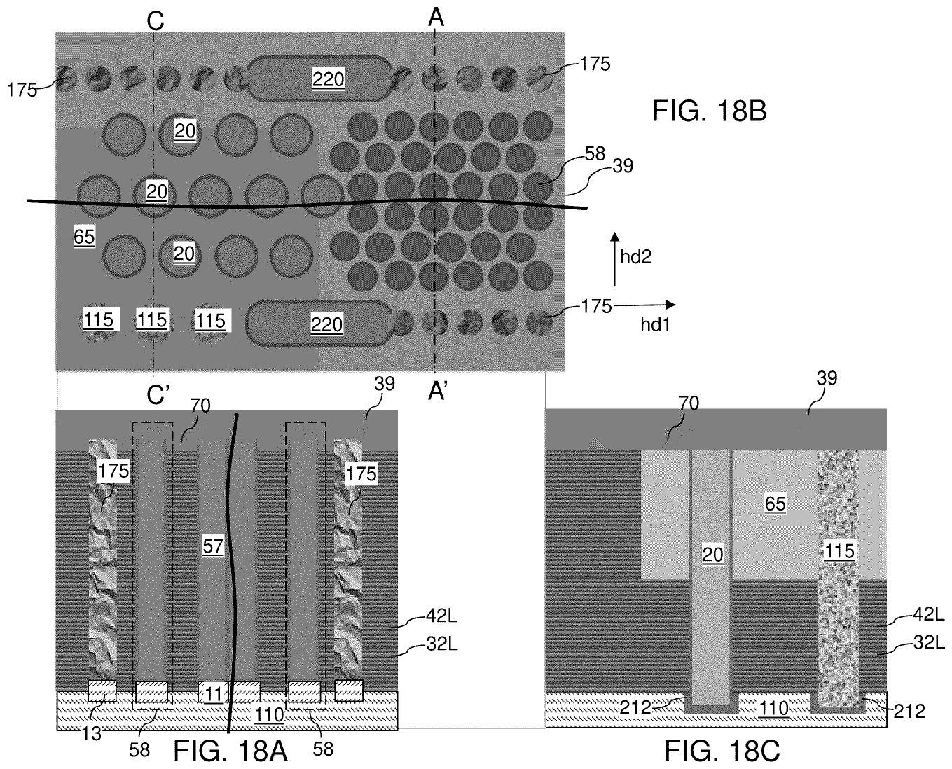

Referring to FIGS. 18A-18C, a second hard mask layer 39 can be deposited over the insulating cap layer 70. The second hard mask layer 39 comprises a second hard mask material, which may be, for example, boron doped amorphous silicon. The thickness of the second hard mask layer 39 may be in a range from 30 nm to 300 nm, such as from 60 nm to 150 nm, although lesser and greater thicknesses may also be employed.

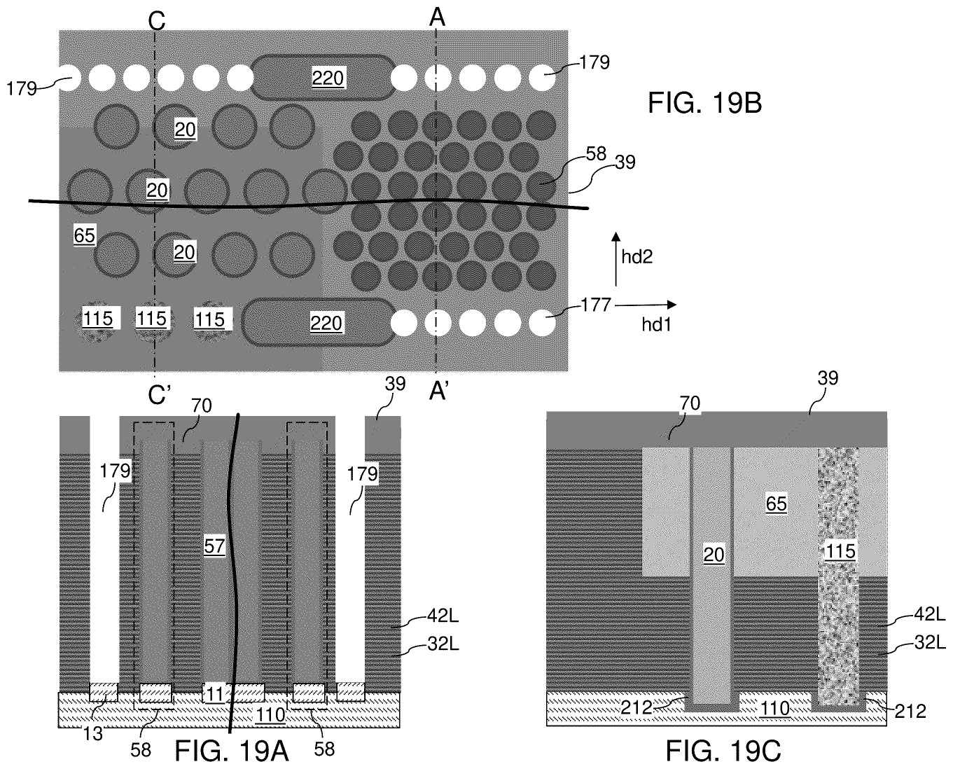

Referring to FIGS. 19A-19C, the second hard mask layer 39 can be patterned to form openings in areas that overlie the sacrificial through-stack isolation opening fill structures 175. For example, a photoresist layer (not shown) can be applied over the second hard mask layer 39, and can be lithographically patterned with openings having the same pattern as the sacrificial through-stack isolation opening fill structures 175. An anisotropic etch process can be performed to transfer the pattern of the openings in the photoresist layer through the second hard mask layer 39.

A selective removal process (such as an ashing process or an isotropic etch process) may be performed to remove the third sacrificial fill material of the sacrificial through-stack isolation opening fill structures 175 from the through-stack isolation openings 179 selective to the materials of the vertically alternating sequence (32L, 42L), the stepped dielectric material portions 65, the insulating cap layer 70, the second hard mask layer 39, and the semiconductor pedestals 13. The through-stack isolation openings 179 are reopened.

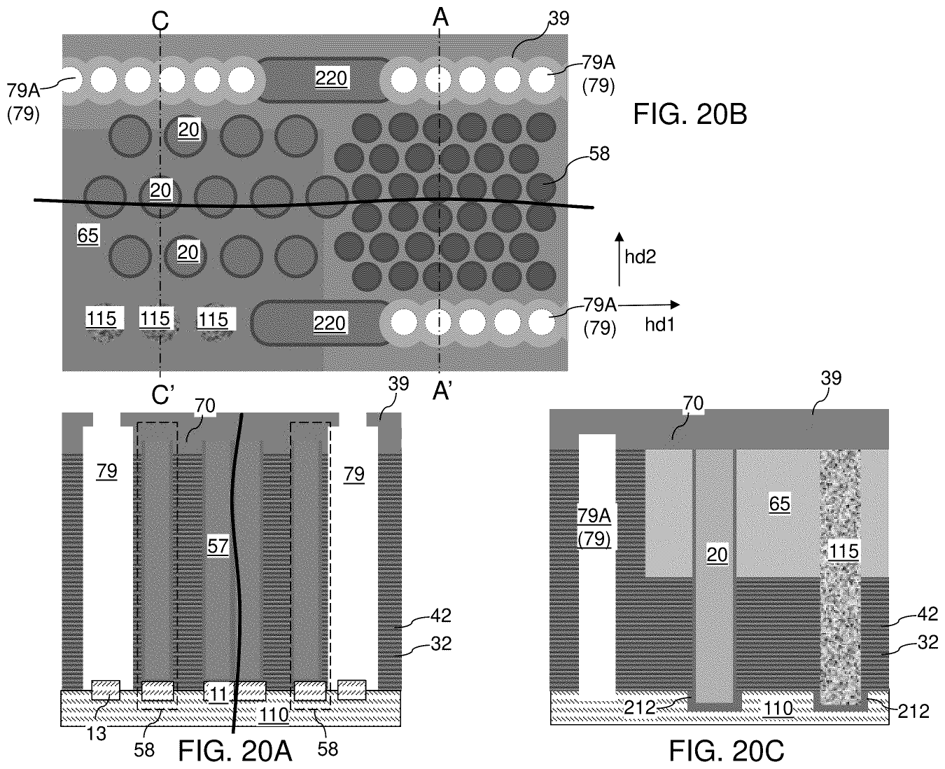

Referring to FIGS. 20A-20C, a first isotropic etch process can be performed to isotropically laterally recess physically exposed sidewalls of the vertically alternating sequence (32L, 42L) around each of the through-stack isolation openings 179. First laterally-extending trenches 79A can be formed in continuous voids that are formed by merging of the adjacent through-stack isolation openings 179. The first isotropic etch process may comprise an isotropic etch step that isotropically etches the material of the continuous insulating layers 32L and another isotropic etch step that isotropically etches the material of the continuous sacrificial material layers 42L. In one embodiment, the first isotropic etch process may include sequentially etching the silicon nitride continuous sacrificial material layers 42L using hot phosphoric acid and separately etching the silicon oxide continuous insulating layers 32L using hydrofluoric acid before or after etching the silicon nitride continuous sacrificial material layers 42L. The duration of the isotropic etch steps can be selected to merge a respective row of through-stack isolation openings 179 into respective first laterally-extending trenches 79A.

In summary, rows of isolation openings (such as rows of through-stack isolation openings 179) can be formed through the vertically alternating sequence (32L, 42L), and volumes of the isolation openings can be laterally expanded by isotropically laterally recessing portions of the vertically alternating sequence (32L, 42L) around the rows of isolation openings to form the first laterally-extending trenches 79A. The first laterally-extending trenches 79A are a first subset of laterally-extending trenches 79 that will be present after completion of the first exemplary structure. Each of the first laterally-extending trenches 79A generally extends along the first horizontal direction hd1 and has a lateral width undulation along the second horizontal direction hd2 as a function of a lateral distance along the first horizontal direction hd1.

Each continuous volume including volumes of at least one elongated dielectric pillar structure 220 and at least two first laterally-extending trenches 79A constitutes a lateral isolation trench. The lateral isolation trenches (79A, 220) divide the vertically alternating sequence (32L, 42L) into multiple alternating stacks of respective insulating layers 32 and respective sacrificial material layers 42. Each insulating layer 32 is a patterned portion of a continuous insulating layer 32L. Each sacrificial material layer 42 is a patterned portion of a continuous sacrificial material layer 42L. Thus, contiguous combinations of the elongated dielectric pillar structures 220 and the first laterally-extending trenches 79A divide the vertically alternating sequence (32L, 42L) into alternating stacks (32, 46) of insulating layers 32 and sacrificial material layers 42. The elongated dielectric pillar structures 220 function as bridge structures which prevent or reduce tilting or collapse of the alternating stacks (32, 46) into the first laterally-extending trenches 79A.

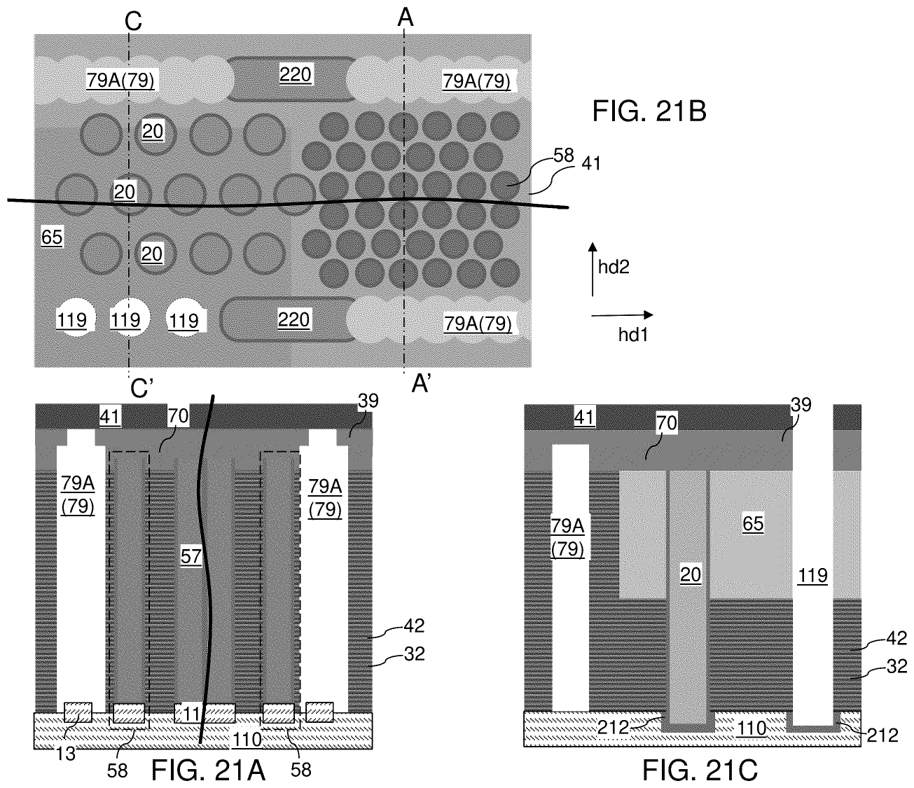

Referring to FIGS. 21A-21C, a third hard mask layer 41 can be formed over the second hard mask layer 39 by performing an anisotropic deposition process. For example, a non-conformal chemical vapor deposition process, such as a plasma-enhanced chemical deposition process or a physical vapor deposition process, may be employed to deposit the third hard mask layer 41. The third hard mask layer 41 may comprise a dielectric material that is different from the material of the second hard mask layer 39. In one embodiment, the second hard mask layer 39 comprises amorphous silicon, and the third hard mask layer 41 comprises silicon nitride. The thickness of the third hard mask layer 41 can be selected such that the third hard mask layer 41 covers openings in the second hard mask layer 39. For example, the thickness of the third hard mask layer 41 over a horizontally-extending portion of the second hard mask layer 39 may be in a range from 100 nm to 400 nm, although lesser and greater thicknesses may also be employed.

The third hard mask layer 41 can be patterned to form openings in areas of the sacrificial staircase-region isolation opening fill structures 115. For example, a photoresist layer (not shown) can be applied over the third hard mask layer 41, and can be lithographically patterned to form openings having a same pattern as the sacrificial staircase-region isolation opening fill structures 115. An anisotropic etch process can be performed to remove unmasked portions of the third hard mask layer 41. Subsequently, the second sacrificial fill material of the sacrificial staircase-region isolation opening fill structures 115 can be removed from the stepped-region isolation openings 119 selective to the materials of the alternating stacks (32, 42), the stepped dielectric material portions 65, the insulating cap layer 70, the second hard mask layer 39, and the third hard mask layer 41 to reopen the stepped-region isolation openings 119. The photoresist layer may be removed prior to, during, or after, removal of the sacrificial staircase-region isolation opening fill structures 115.

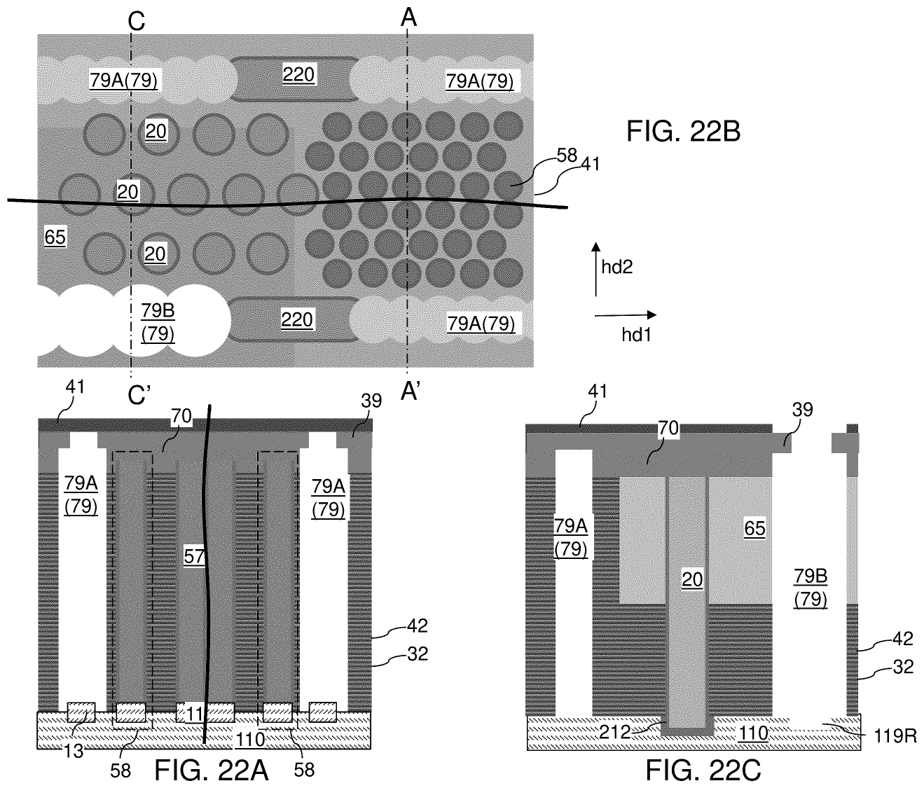

Referring to FIGS. 22A-22C, a second isotropic etch process can be performed to isotropically laterally recess portions of the alternating stacks (32, 42), the stepped dielectric material portions 65, and the elongated dielectric pillar structures 220 around each of the stepped-region isolation openings 119. Second laterally-extending trenches 79B can be formed in continuous voids that are formed by merging of the adjacent stepped-region isolation openings 119. The second isotropic etch process may comprise an isotropic etch step that isotropically etches the material of the insulating layers 32 and another isotropic etch step that isotropically etches the material of the sacrificial material layers 42. In one embodiment, the first isotropic etch process may include sequentially etching the silicon nitride sacrificial material layers 42 using hot phosphoric acid and separately etching the silicon oxide insulating layers 32 using hydrofluoric acid before or after etching the silicon nitride sacrificial material layers 42. The duration of the isotropic etch steps can be selected to from a respective row of stepped-region isolation openings 119. The second laterally-extending trenches 79B can be a subset of the laterally-extending trenches 79. Furthermore, the dielectric liners 212 may be removed from the stepped-region isolation openings 119 to form recesses 119R in the layer (e.g., the semiconductor material layer 110 or the substrate 8) underlying the stepped-region isolation openings 119.

In summary, rows of isolation openings (such as rows of stepped-region isolation openings 119) can be formed through the vertically alternating sequence (32L, 42L), and volumes of the isolation openings can be laterally expanded by isotropically laterally recessing portions of the alternating stacks (32, 42 around the rows of isolation openings to form laterally-extending trenches (such as the second laterally-extending trenches 79B). Each of the laterally-extending trenches 79 generally extends along the first horizontal direction hd1 and has a lateral width undulation along the second horizontal direction hd2 as a function of a lateral distance along the first horizontal direction hd1.

In one embodiment, a subset of the laterally-extending trenches 79 (such as the second laterally-extending trenches 79B) may be formed through a respective one of the stepped dielectric material portions 65 and the staircase region, and may divide the respective one of the stepped dielectric material portions 65 into a respective pair of patterned stepped dielectric material portions 65 and pair of staircase regions. Upon formation of the second laterally-extending trenches 79B, each of the alternating stacks (32, 42) may have a respective stepped surface in the staircase region that underlies and contacts a respective stepped dielectric material portion 65. Each of the alternating stacks (32, 42) of insulating layers 32 and sacrificial material layers 42 may laterally extend along the first horizontal direction hd1. The alternating stacks (32, 42) may be laterally spaced apart from each other along a second horizontal direction hd2 by lateral isolation trenches (219, 79). Generally, each lateral isolation trench (219, 79) may comprise a volume of at least one elongated pillar cavity 219 and at least two laterally-extending trenches 79.

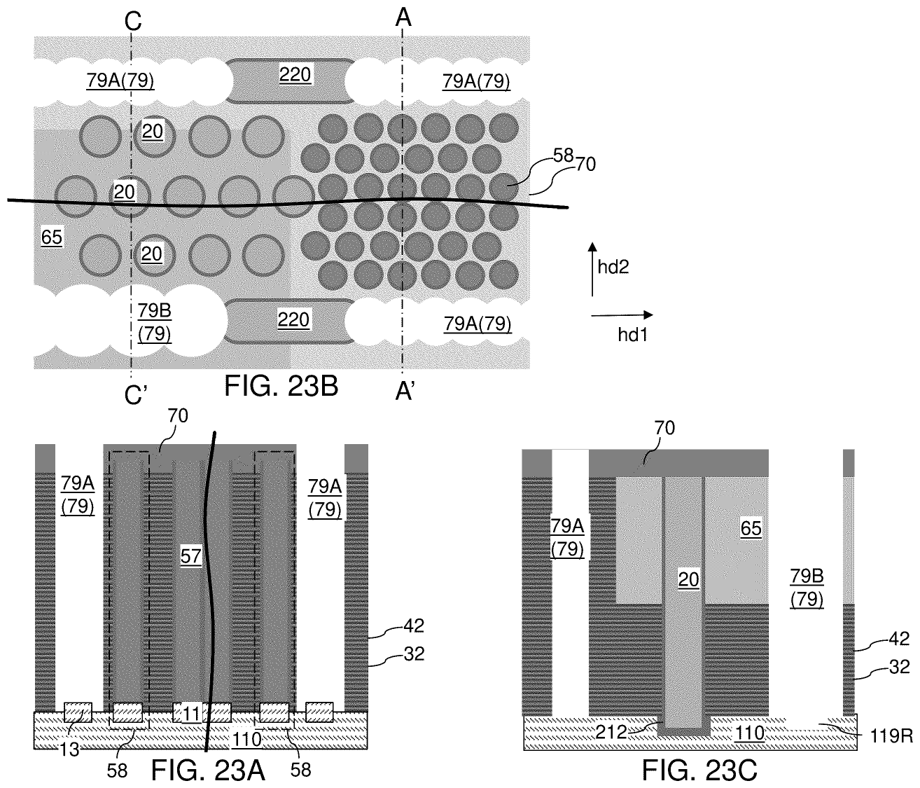

Referring to FIGS. 23A-23C, anisotropic etch processes may be performed to remove the third hard mask layer 41 and the second hard mask layer 39.

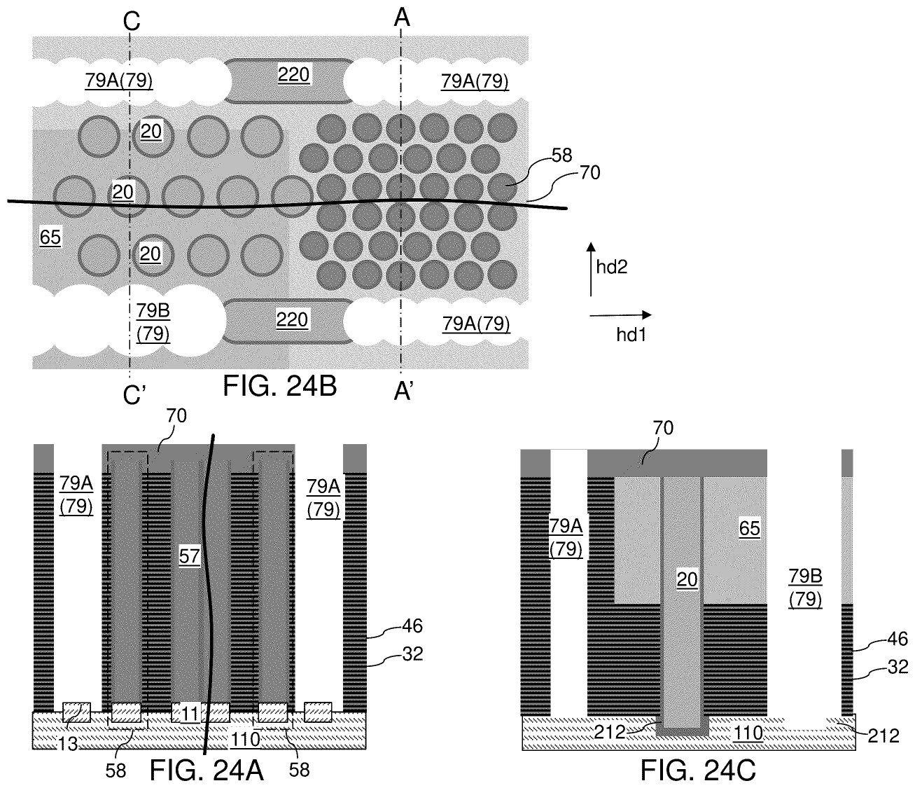

Referring to FIGS. 24A-24C, the sacrificial material layers 42 can be removed selective to the insulating layers 32, the stepped dielectric material portions 65, the insulating cap layer 70, outermost layers of the memory films 50, and the semiconductor pedestals 13. For example, an etchant that selectively etches the materials of the sacrificial material layers 42 with respect to the materials of the insulating layers 32, the stepped dielectric material portions 65, the insulating cap layer 70, outermost layers of the memory films 50, and the semiconductor pedestals 13 may be introduced into the laterally-extending trenches 79, for example, using an isotropic etch process.

The isotropic etch process may be a wet etch process using a wet etch solution, or may be a gas phase (dry) etch process in which the etchant is introduced in a vapor phase into the laterally-extending trench 79. For example, if the sacrificial material layers 42 include silicon nitride, the etch process may be a wet etch process in which the first exemplary structure is immersed within a wet etch tank including phosphoric acid, which etches silicon nitride selective to silicon oxide, silicon, and various other materials used in the art.

Isolation opening recesses are formed in volumes from which the sacrificial material layers 42 are removed. Each of the isolation opening recesses may be a laterally extending cavity having a lateral dimension that is greater than the vertical extent of the cavity. In other words, the lateral dimension of each of the isolation opening recesses may be greater than the height of the respective isolation opening recess. Each of the isolation opening recesses may extend substantially parallel to the top surface of the substrate 8. A isolation opening recess may be vertically bounded by a top surface of an underlying insulating layer 32 and a bottom surface of an overlying insulating layer 32. In one embodiment, each of the isolation opening recesses may have a uniform height throughout.

An optional isolation opening blocking dielectric layer (not shown) may be optionally deposited in the isolation opening recesses and the laterally-extending trenches 79 and over the insulating cap layer 70. The isolation opening blocking dielectric layer includes a dielectric material such as a dielectric metal oxide (e.g., aluminum oxide), silicon oxide, or a combination thereof.

At least one conductive material may be deposited in the plurality of isolation opening recesses, on the sidewalls of the laterally-extending trenches 79, and over the insulating cap layer 70. The at least one conductive material may be deposited by a conformal deposition method, which may be, for example, chemical vapor deposition (CVD), atomic layer deposition (ALD), electroless plating, electroplating, or a combination thereof. The at least one conductive material may include an elemental metal, an intermetallic alloy of at least two elemental metals, a conductive nitride of at least one elemental metal, a conductive metal oxide, a conductive doped semiconductor material, a conductive metal-semiconductor alloy, such as a metal silicide, alloys thereof, and combinations or stacks thereof.

In one embodiment, the at least one conductive material may include at least one metallic material, i.e., an electrically conductive material that includes at least one metal element. Non-limiting exemplary metallic materials that may be deposited in the isolation opening recesses include tungsten, tungsten nitride, titanium, titanium nitride, tantalum, tantalum nitride, cobalt, and/or ruthenium. For example, the at least one conductive material may include a conductive metallic nitride liner that includes a conductive metallic nitride material such as TiN, TaN, MON, WN, or a combination thereof, and a conductive fill material such as W, Co, Ru, Mo, Cu, or combinations thereof. In one embodiment, the at least one conductive material for filling the isolation opening recesses may be a combination of titanium nitride layer and a tungsten fill material.

Electrically conductive layers 46 may be formed in the isolation opening recesses by deposition of the at least one conductive material. A continuous metallic material layer (not shown) may be formed on the sidewalls of each laterally-extending trench 79 and over the insulating cap layer 70. Each of the electrically conductive layers may include a respective conductive metallic nitride liner and a respective conductive fill material. Thus, the sacrificial material layers 42 may be replaced with the electrically conductive layers 46. Specifically, each sacrificial material layer 42 may be replaced with an optional portion of the isolation opening blocking dielectric layer and an electrically conductive layer 46. A isolation opening cavity is present in the portion of each laterally-extending trench 79 that is not filled with the continuous metallic material layer.

The continuous metallic material layer may be removed from inside the laterally-extending trenches 79. Specifically, the continuous metallic material layer may be etched back from the sidewalls of each laterally-extending trench 79 and from above the insulating cap layer 70, for example, by an anisotropic or isotropic etch. Each remaining portion of the deposited metallic material in the isolation opening recesses constitutes an electrically conductive layer 46. Sidewalls of the electrically conductive layers 46 may be physically exposed to a respective laterally-extending trench 79.

Each electrically conductive layer 46 may be a conductive sheet including openings therein. A subset of the openings through each electrically conductive layer 46 may be filled with memory opening fill structures 58. A second subset of the openings through each electrically conductive layer 46 may be filled with the dielectric support pillar structures 20. A subset of the electrically conductive layers 46 may comprise word lines for the memory elements.

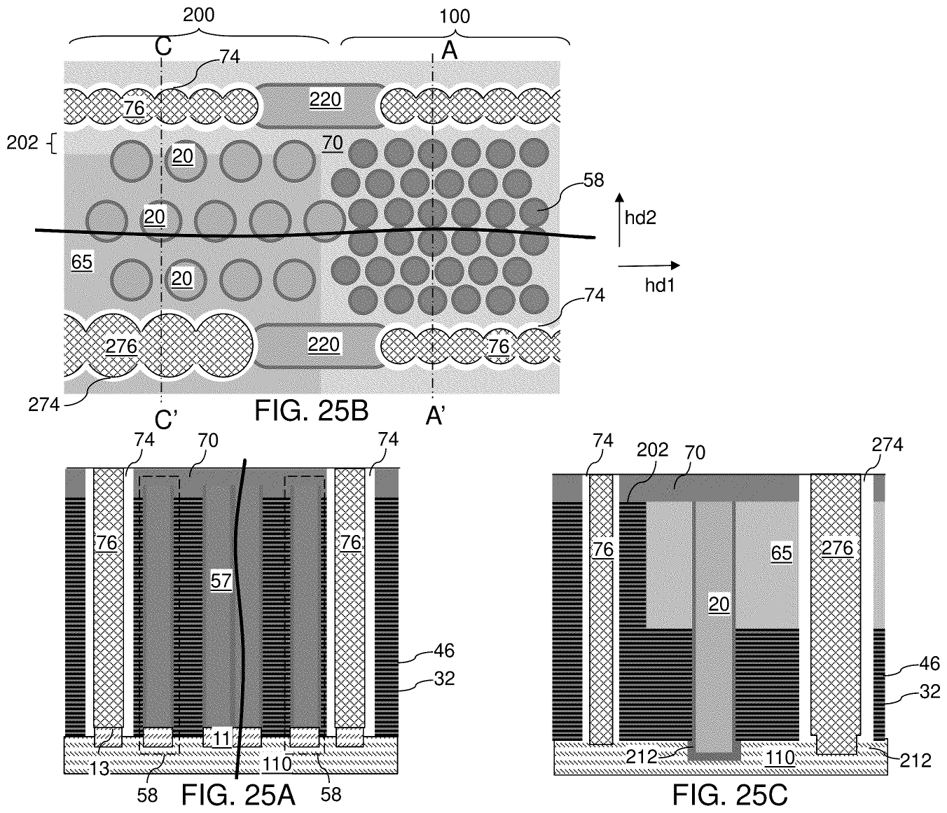

Referring to FIGS. 25A-25C, a laterally-extending trench fill structure {(74, 76) or (274, 276)} can be formed in each laterally-extending trench 79. In one embodiment, a laterally-elongated tubular insulating spacer (74, 274) can be formed at a periphery of each laterally-extending trench 79 by conformally depositing an insulating material layer and anisotropically etching the insulating material layer. The laterally-elongated tubular insulating spacers (74, 274) may comprise first laterally-elongated tubular insulating spacers 74 that are formed in the first laterally-extending trenches 79A and second laterally-elongated tubular insulating spacers 274 that are formed in the second laterally-extending trenches 79B. At least one conductive material may optionally be deposited in remaining unfilled volumes of the laterally-extending trenches 79, and excess portions of the at least one conductive fill material may be removed from above the horizontal plane including the top surface of the insulating cap layer 70. Each remaining portion of the at least one conductive material constitutes a source contact via structure (76, 276). The source contact via structures (76, 276) may comprise first source contact via structures 76 that are formed in the first laterally-extending trenches 79A and second source contact via structure 276 that are formed in the second laterally-extending trenches 79B. In this case, each contiguous combination of a source contact via structure (76, 276) and a laterally-elongated tubular insulating spacer (74, 274) constitutes a laterally-extending trench fill structure {(74, 76) or (274, 276)}. In one embodiment, the source contact via structures (76, 276) can be formed within the laterally-extending trenches 79, and can be electrically connected to the semiconductor material layer 110 or the semiconductor substrate 8 that underlies the alternating stacks (32, 46).

Each contiguous combination of material portions that fills a respective by lateral isolation trench (219, 79) constitutes a composite lateral isolation trench fill structure (220, 74, 76, 274, 276). Thus, each composite lateral isolation trench fill structure (220, 74, 76, 274, 276) comprises at least one elongated dielectric pillar structure 220 and at least two laterally-extending trench fill structure {(74, 76) and/or (274, 276)}. The width of the first type laterally-extending trench fill structures {(74, 76)} located in the first laterally-extending trenches 79A may be narrower along the second horizontal direction hd2 than the width of the second type laterally-extending trench fill structures {(274, 276)} located in the second laterally-extending trenches 79B.

Each alternating stack (32, 46) with memory opening fill structures 58 vertically extending therethrough comprises a memory block. In an embodiment in which the inter-array region 200 is located between two memory array regions (100A, 100B) in the same memory block as shown in FIG. 1, then the electrically conductive layers 46 may continuously extend from the first memory array region 100A to the second memory array region 100B through a connection portion 202 in the inter-array region 200. The connection portion 202 is located in a region between the stepped dielectric material portion 65 overlying the staircase region and the laterally-extending trench fill structure {(74, 76)}.

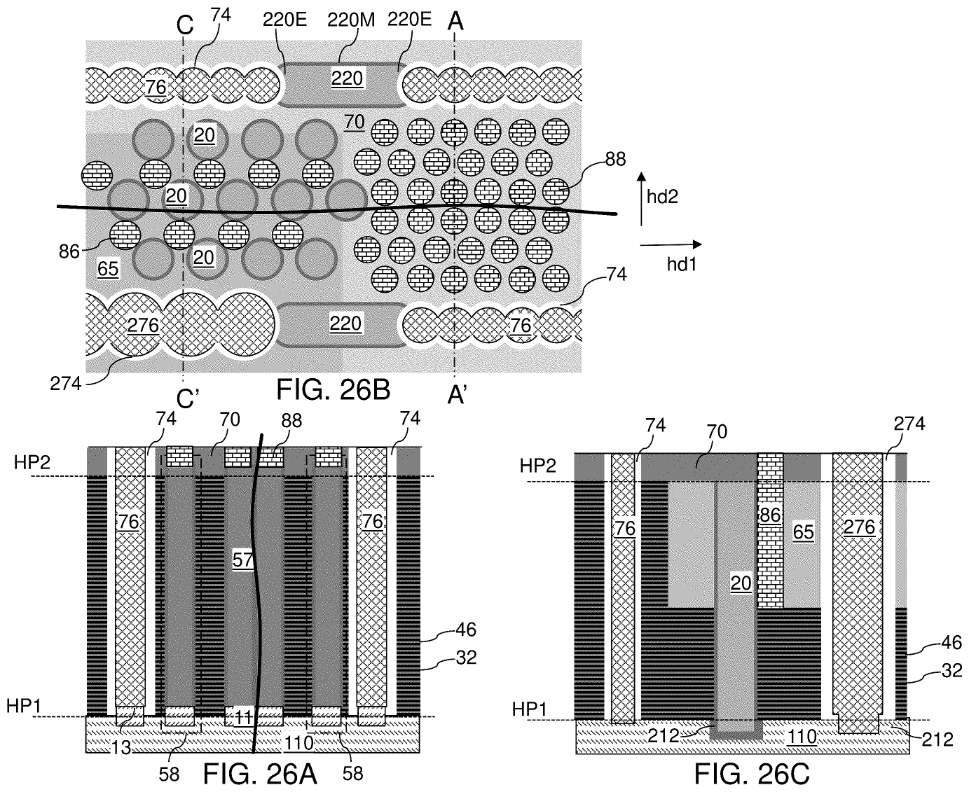

Referring to FIGS. 26A-26C, contact via cavities can be formed through the insulating cap layer 70 and the stepped dielectric material portions 65 to a top surface of a respective electrically conductive layer 46. At least one conductive material, such as at least one metallic material can be deposited in the contact via cavities to form layer contact via structures 86. Further, drain contact via structures 88 can be formed through the insulating cap layer 70 on a top surface of a respective one of the drain regions 63.

Referring to all drawings and according to various embodiments of the present disclosure, a three-dimensional memory device comprises: alternating stacks (32, 46) of insulating layers 32 and electrically conductive layers 46, wherein each of the alternating stacks (32, 46) laterally extends along a first horizontal direction hd1 and the alternating stacks (32, 46) are laterally spaced apart from each other along a second horizontal direction hd2 by lateral isolation trenches (219, 79); arrays of memory openings 49, wherein each array of memory openings 49 vertically extends through a respective one of the alternating stacks (32, 46); arrays of memory opening fill structures 58 located within the arrays of memory openings 49, wherein each of the memory opening fill structures 58 comprises a respective vertical stack of memory elements (e.g., portions of the memory film 50) and a vertical semiconductor channel 60; and composite lateral isolation trench fill structures (220, 74, 76, 274, 276) located between a respective neighboring pair of the alternating stacks (32, 46). Each of the composite lateral isolation trench fill structure (220, 74, 76, 274, 276) comprises a dielectric pillar structure 220 which vertically extends at least from first horizontal plane HP1 including a bottom of the alternating stacks (32, 46) to a second horizontal plane HP2 including a top of the alternating stacks (32, 46), as shown in FIGS. 26A and 26C.

In one embodiment shown in FIG. 26B, the dielectric pillar structure 220 comprises an elongated dielectric pillar structure 220 that comprises a middle portion 220M laterally extending along the first horizontal direction hd1 with a uniform width along the second horizontal direction hd2 and further comprises a pair of end portions 220E having a respective vertically-straight and laterally-concave sidewall.

In one embodiment, each of the composite lateral isolation trench fill structures (220, 74, 76, 274, 276) comprises at least one source contact via structure (76, 276) having a pair of lengthwise sidewalls that generally extend along the first horizontal direction hd1 and having a laterally-undulating width along the second horizontal direction hd2 that undulates along the first horizontal direction hd1. In one embodiment, each of the at least one source contact via structure (76, 276) is laterally surrounded by a laterally-elongated tubular insulating spacer (74, 274) having an undulating lateral extent along the second horizontal direction hd2 as a function of a lateral distance along the first horizontal direction hd1.

In one embodiment, each of the at least one source contact via structure (76, 276) comprises a respective bottom surface contacting a respective row of semiconductor pedestals 13 (which may overly a semiconductor material layer 110 or a semiconductor substrate 8). In one embodiment, each of the memory opening fill structures 58 comprises a respective pedestal channel portion 11 having a same material composition as the semiconductor pedestals 13.

In one embodiment, each of the elongated dielectric pillar structures 220 is in contact with a respective pair of laterally-elongated tubular insulating spacers (74, 274) each having an undulating lateral extent along the second horizontal direction hd2 as a function of a lateral distance along the first horizontal direction hd1.

In one embodiment, each of the alternating stacks (32, 46) has a respective stepped surface that underlies, and contacts, a respective stepped dielectric material portion 65. In one embodiment, the composite lateral isolation trench fill structures (220, 74, 76, 274, 276) comprise: first composite lateral isolation trench fill structures (220, 74, 76) that are not in direct contact with any of the stepped dielectric material portions 65; and second composite lateral isolation trench fill structures (220, 74, 76, 274, 276) that contact a respective one of the stepped dielectric material portions 65. In one embodiment, each of the first composite lateral isolation trench fill structures (220, 74, 76) comprises a respective pair of first source contact via structure 76 having a first maximum lateral width along the second horizontal direction hd2; and each of the second composite lateral isolation trench fill structures (220, 74, 76, 274, 276) comprises a respective additional first source contact via structure 76 having the first maximum lateral width along the second horizontal direction hd2 and a second source contact via structure 276 having a second maximum lateral width along the second horizontal direction hd2 that is greater than the first maximum lateral width.

In one embodiment, a contiguous set of the stepped surfaces continuously extends at least from a bottommost electrically conductive layer 46 within a respective one of the alternating stacks (32, 46) to a topmost electrically conductive layer 46 within the respective one of the alternating stacks (32, 46).

In one embodiment, the three-dimensional memory device comprises layer contact via structures 86 vertically extending through a respective one of the stepped dielectric material portions 65 and contacting a respective electrically conductive layer 46 within the alternating stacks (32, 46).

In one embodiment, the three-dimensional memory device comprises dielectric support pillar structures 20 vertically extending through a respective one of the stepped dielectric material portions 65, wherein the dielectric support pillar structures 20 and the dielectric pillar structures 220 comprise a same dielectric fill material.

In one embodiment, a subset of the dielectric pillar structures 220 is in direct contact with a respective pair of alternating stacks (32, 46) among the alternating stacks (32, 46) and a respective pair of stepped dielectric material portions 65 among the dielectric material portions.

The various embodiments of the present disclosure can be employed to prevent pattern collapse (i.e., collapse of the insulating layers 32 into the isolation opening recesses) during replacement of the sacrificial material layers 42 with electrically conductive layers 46. This reduces or eliminates vertical deflection of the electrically conductive layers 46 which reduces or eliminates short circuits between vertically adjacent electrically conductive layers 46. The elongated dielectric pillar structure 220 fills a respective elongated pillar cavity 219 of the lateral isolation trenches (219, 79) upon formation of the laterally-extending trenches 79, during formation of the isolation opening recesses, during formation of the electrically conductive layers 46, and during formation of the laterally-extending trench fill structures {(74, 76), (274, 276)}. Thus, the elongated dielectric pillar structure 220 also functions as a trench bridge structure which reduces or prevents alternating stack inclination into the laterally-extending trenches 79 prior to formation of the laterally-extending trench fill structures {(74, 76), (274, 276)}.

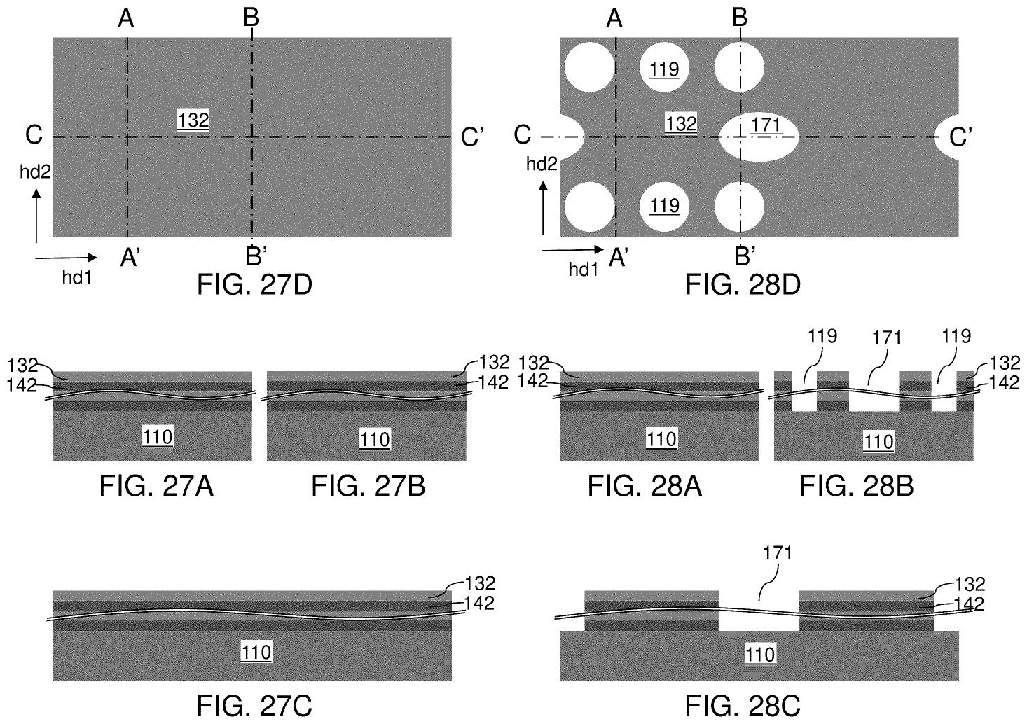

Referring to FIGS. 27A-27D, a second exemplary structure according to a second embodiment of the present disclosure is illustrated. The second exemplary structure includes a first-tier vertically alternating sequence of first insulating layers 132 and first sacrificial material layers 142. In the second exemplary structure, composite structures are built up from bottom to top, and each composite structure is referred to, from bottom to top, as a first tier structure, a second tier structure, and a third tier structure. A first-tier element refers to an element within a first tier structure, a second-tier element refers to an element within a second tier structure, and a third-tier element refers to an element within a third tier structure.

The first insulating layers 132 may be the same as the continuous insulating layers 32L described with reference to FIG. 2. The first sacrificial material layers 142 may be the same as the continuous sacrificial material layers 42L described with reference to FIG. 2. Thus, the first-tier vertically alternating sequence of the first insulating layers 132 and the first sacrificial material layers 142 may be the same as the vertically alternating sequence (32L, 42L) of the continuous insulating layers 32L and the continuous sacrificial material layers 42L described with reference to FIG. 2. Generally, the first insulating layers 132 comprise a first material such as silicon oxide, and the first sacrificial material layers 142 comprise a second material such as silicon nitride. In one embodiment, the second exemplary structure illustrated in FIGS. 27A-27D may be the same as the first exemplary structure illustrated in FIG. 2, which comprises a substrate 8 including a substrate material layer 9, optional semiconductor devices 720 formed on the substrate material layer 9, optional lower-level metal interconnect structures 780 embedded within optional lower-level dielectric material layers 760, and optionally at least one semiconductor material layer (e.g., source layer) 110. In this case, the first insulating layers 132 may be an alternative name for the continuous insulating layers 32L, and the first sacrificial material layers 142 may be an alternative name for the continuous sacrificial material layers 42L.

Alternatively, the semiconductor devices 720, lower-level metal interconnect structures 780 and lower-level dielectric material layers 760 can be formed on a separate substrate and then bonded to the memory device containing the memory opening fill structures and electrically conductive layers. Furthermore, the source layer may be formed in contact with the vertical semiconductor channels 60 after removing the substrate 8.

The processing steps described with reference to FIGS. 3A-3C, 4A-4C, and 5A-5C can be subsequently performed to form a stepped dielectric material portion (not illustrated), which is herein referred to as a first-tier stepped dielectric material portion.

Referring to FIGS. 28A-28D, the processing steps described with reference to FIGS. 6A-6C may be performed, with optional changes in the shapes of the openings in the patterned etch mask layer, to form first-tier support openings 119 and first-tier pillar openings 171. The first-tier support openings 119 may have the same pattern as the pattern of the support openings 19 illustrated in FIGS. 6A-6C. The first-tier pillar openings 171 may be arranged in rows of first-tier pillar openings 171. Each row of first-tier pillar openings 171 may comprise a respective set of first-tier pillar openings 171 arranged along the first horizontal direction hd1. The rows of first-tier pillar openings 171 may be laterally spaced apart from each other along the second horizontal direction hd2.

Each first-tier pillar opening 171 may have a respective horizontal cross-sectional shape of a circle or an oval that is laterally elongated along the first horizontal direction hd1. Each row of first-tier pillar openings 171 may be formed within an area in which a respective lateral isolation trench that divides the first-tier vertically alternating sequence is to be subsequently formed. Each of the first-tier support openings 119 and the first-tier pillar openings 171 may have bottom surfaces located below the horizontal plane including the bottommost surface of the first-tier vertically alternating sequence (132, 142).

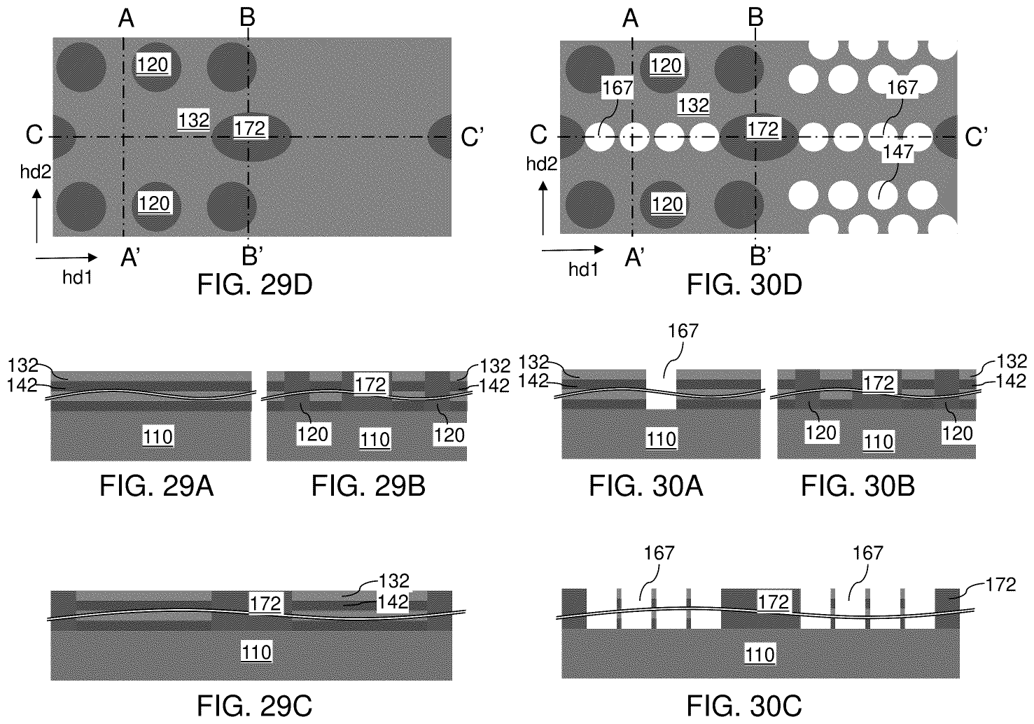

Referring to FIGS. 29A-29D, a first dielectric fill material may be deposited in the first-tier support openings 119 and in the first-tier pillar openings 171. The first dielectric fill material may comprise undoped silicate glass (i.e., silicon oxide) or a doped silicate glass. Excess portions of the first dielectric fill material may be removed from above the horizontal plane including the first-tier vertically alternating sequence (132, 142) by a planarization process, which may comprise a recess etch process and/or a chemical mechanical polishing process. Each remaining portion of the first dielectric fill material filling a first-tier support opening 119 comprises a first-tier support pillar 120. Each remaining portion of the first dielectric fill material filling a first-tier pillar opening 171 comprises a first-tier dielectric pillar 172. The first-tier dielectric pillars 172 may be arranged as rows of first-tier dielectric pillars 172. Each row of first-tier dielectric pillars 172 comprises a respective set of first-tier dielectric pillars 172 arranged along the first horizontal direction hd1. The rows of first-tier dielectric pillars 172 are laterally spaced apart along the second horizontal direction hd2.

Referring to FIGS. 30A-30D, the processing steps described with respect to FIGS. 13A-13C can be performed to form memory openings 49 and through-stack isolation openings 179 through the first-tier vertically alternating sequence (132, 142). The memory openings 49 that are formed through the first-tier vertically alternating sequence (132, 142) in the second exemplary structure are herein referred to as first-tier memory openings 147. The through-stack isolation openings 179 that are formed through the first-tier vertically alternating sequence (132, 142) in the second exemplary structure are herein referred to as first-tier isolation openings 167. The first-tier memory openings 147 may be formed with the same pattern as the pattern of the memory openings 49 in the first exemplary structure.

The first-tier isolation openings 167 are formed in rows of first-tier isolation openings 167. The rows of first-tier isolation openings 167 can be laterally spaced from each other along the second horizontal direction hd2. Each row of first-tier isolation openings 167 can be aligned to a respective row of first-tier dielectric pillars 172, and can be interlaced along the first horizontal direction with the respective row of first-tier dielectric pillars 172. At least one first-tier isolation opening 167 can be provided between each neighboring pair of first-tier dielectric pillars 172. In one embodiment, the row of first-tier isolation openings 167 can be aligned to the row of first-tier dielectric pillars 172 within each laterally interlaced combination of a row of first-tier isolation openings 167 and a row of first-tier dielectric pillars 172 such that any lateral gap along the first horizontal direction within the laterally interlaced combination is less than a predetermined lateral dimension, which may be in a range from 20 nm to 200 nm, such as from 40 nm to 120 nm, although lesser and greater dimensions may also be employed.

In one embodiment, at least one, such as each of the first-tier isolation openings 167 may have a horizontal cross-sectional shape of a circle or an oval that is elongated along the first horizontal direction hd1. In one embodiment, multiple first-tier isolation openings 167 can be provided between each neighboring pair of first-tier dielectric pillars 172 within each laterally interlaced combination of a row of first-tier isolation openings 167 and a row of first-tier dielectric pillars 172. The number of first-tier isolation openings 167 between each neighboring pair of first-tier dielectric pillars 172 may be in a range from 2 to 24, such as from 3 to 12. In the illustrated example of FIGS. 30A-30D, the number of first-tier isolation openings 167 between each neighboring pair of first-tier dielectric pillars 172 is four.

In one embodiment, each of the first-tier dielectric pillars 172 may have a first lateral extent along the second horizontal direction hd2, and each of the first-tier isolation openings 167 may have a second lateral extent along the second horizontal direction hd2. The second lateral extent may be different from the first lateral extent, or may be the same as the first lateral extent. The first lateral extent may be in a range from 200 nm to 1,000 nm, such as from 300 nm to 600 nm, although lesser and greater first lateral extents may also be employed. In one embodiment, the second lateral extent may be in a range from 150 nm to 800 nm, such as from 200 nm to 500 nm, although lesser and greater second lateral extents may also be employed.

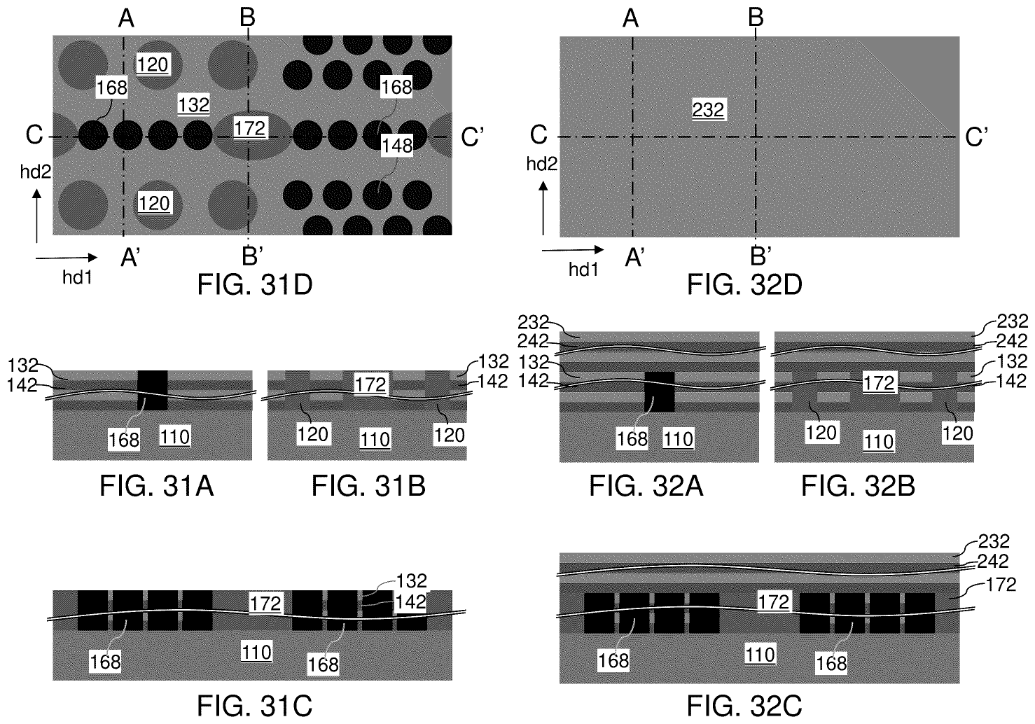

Referring to FIGS. 31A-31D, a first sacrificial fill material can be deposited in the first-tier memory openings 147 and first-tier isolation openings 167. The first sacrificial fill material comprises a material that may be subsequently removed selective to the materials of the first-tier vertically alternating sequence (132, 142), the first-tier dielectric pillars 172 and the at least one semiconductor material layer 110. For example, the first sacrificial fill material may comprise a carbon-based material (such as amorphous carbon or diamond-like carbon) or may comprise a polymer material. Excess portions of the first sacrificial fill material may be removed from above the horizontal plane including the top surface of the first-tier vertically alternating sequence (132, 142) by a planarization process, such as a recess etch process or a chemical mechanical polishing process. Each remaining portion of the first sacrificial fill material that fills a respective one of the first-tier memory openings 147 constitutes a first-tier sacrificial memory opening fill material portion 148. Each remaining portion of the first sacrificial fill material that fills a respective one of the first-tier isolation openings 167 constitutes a first-tier sacrificial isolation opening fill material portion 168.

Referring to FIGS. 32A-32D, a second-tier vertically alternating sequence of second insulating layers 232 and second sacrificial material layers 242 can be formed. The second insulating layers 232 may have the same material composition and the same thickness as the first insulating layers 132 employed in the first-tier vertically alternating sequence. The second sacrificial material layers 242 may have the same material composition and the same thickness as the first sacrificial material layers 142 employed in the first-tier vertically alternating sequence. Thus, the second-tier vertically alternating sequence of the second insulating layers 232 and the second sacrificial material layers 242 may be the same as the first-tier vertically alternating sequence (132, 142) of the first insulating layers 132 and the first sacrificial material layers 142 described with reference to FIGS. 27A-27D.

The processing steps described with reference to FIGS. 3A-3C, 4A-4C, and 5A-5C can be subsequently performed with suitable modification in the pattern of the stepped surfaces to form a stepped dielectric material portion (not illustrated), which is herein referred to as a second-tier stepped dielectric material portion.

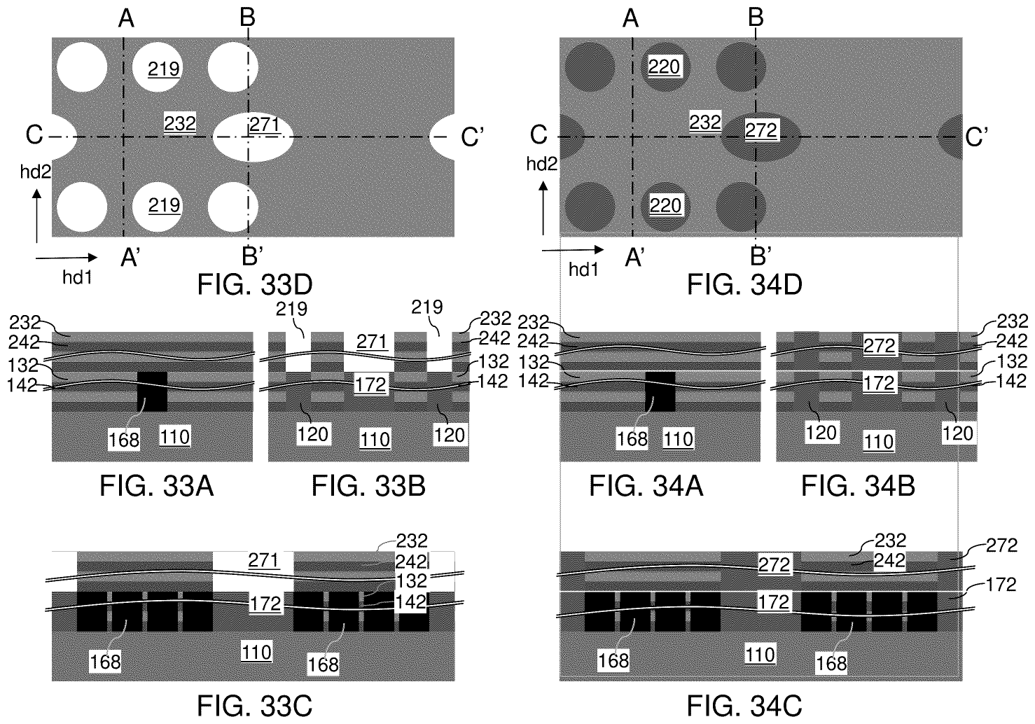

Referring to FIGS. 33A-33D, the processing steps described with reference to FIGS. 6A-6C may be performed, with optional changes in the shapes of the openings in the patterned etch mask layer, to form second-tier support openings 219 and second-tier pillar openings 271. The second-tier support openings 219 may have the same pattern as the pattern of the first-tier support openings 119, which is the same as the pattern of the first-tier support pillars 120. The second-tier pillar openings 271 may have the same pattern as the pattern of the first-tier pillar openings 171, which is the same as the pattern of the first-tier dielectric pillars 172.

Referring to FIGS. 34A-34D, a dielectric fill material may be deposited in the second-tier support openings 219 and in the second-tier pillar openings 271. The dielectric fill material may comprise undoped silicate glass or a doped silicate glass. The dielectric fill material may be the same as the first dielectric fill material of the first-tier support pillars 120 and the first-tier dielectric pillars 172. Excess portions of the dielectric fill material may be removed from above the horizontal plane including the second-tier vertically alternating sequence (232, 242) by a planarization process, which may comprise a recess etch process and/or a chemical mechanical polishing process. Each remaining portion of the dielectric fill material filling a second-tier support opening 219 comprises a second-tier support pillar 220. Each remaining portion of the second dielectric fill material filling a second-tier pillar opening 271 comprises a second-tier dielectric pillar 272. The second-tier dielectric pillars 272 may be arranged as rows of second-tier dielectric pillars 272. Each row of second-tier dielectric pillars 272 comprises a respective set of second-tier dielectric pillars 272 arranged along the first horizontal direction hd1. The rows of second-tier dielectric pillars 272 are laterally spaced apart along the second horizontal direction hd2. The second-tier support pillars 220 may have the same pattern as the pattern of the first-tier support pillars 120. The second-tier dielectric pillars 272 may have the same pattern as the pattern of the first-tier dielectric pillars 172.

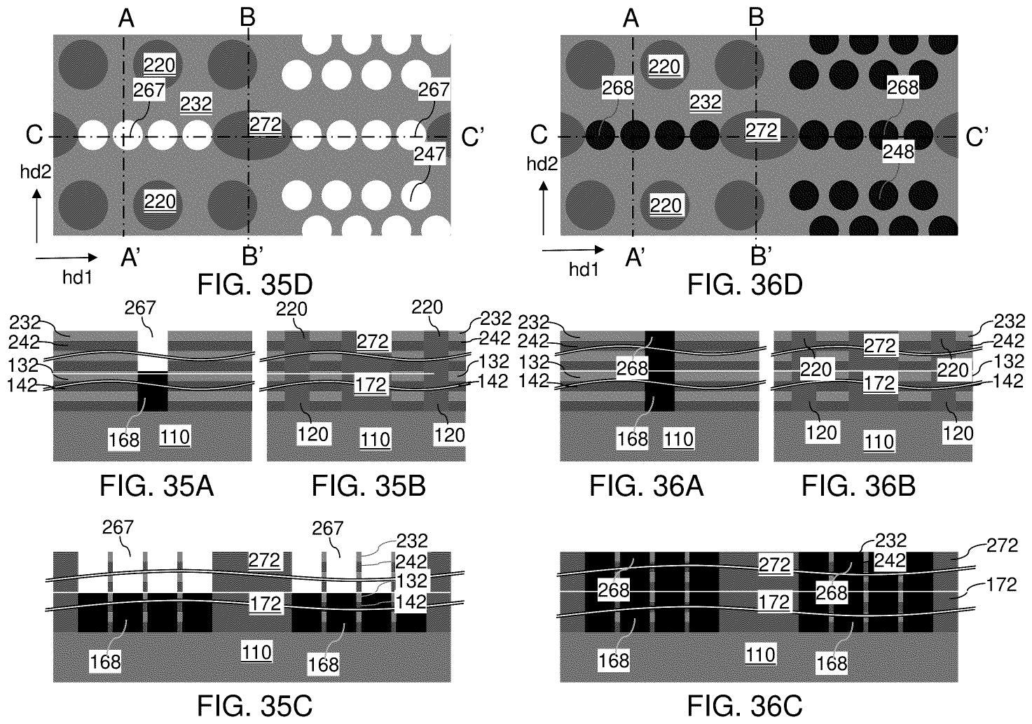

Referring to FIGS. 35A-35D, the processing steps described with respect to FIGS. 13A-13C can be performed with suitable modifications to form second-tier memory openings 247 and second-tier isolation openings 267 through the second-tier vertically alternating sequence (232, 242). The second-tier memory openings 247 may have the same pattern as the pattern of the first-tier memory openings 147, which is the same as the pattern of the first-tier sacrificial memory opening fill material portions 148. The second-tier isolation openings 267 may have the same pattern as the pattern of the first-tier isolation openings 167, which is the same as the pattern of the first-tier sacrificial isolation opening fill material portions 168.

Referring to FIGS. 36A-36D, a second sacrificial fill material can be deposited in the second-tier memory openings 247 and second-tier isolation openings 267. The second sacrificial fill material comprises a material that may be subsequently removed selective to the materials of the second-tier vertically alternating sequence (232, 242). For example, the second sacrificial fill material may comprise a carbon-based material (such as amorphous carbon or diamond-like carbon) or may comprise a polymer material. The second sacrificial fill material may be the same as the first sacrificial fill material of the first-tier sacrificial memory opening fill material portions 148 and the first-tier sacrificial isolation opening fill material portions 168. Excess portions of the second sacrificial fill material may be removed from above the horizontal plane including the top surface of the second-tier vertically alternating sequence (232, 242) by a planarization process, such as a recess etch process or a chemical mechanical polishing process. Each remaining portion of the second sacrificial fill material that fills a respective one of the second-tier memory openings 247 constitutes a second-tier sacrificial memory opening fill material portion 248. Each remaining portion of the second sacrificial fill material that fills a respective one of the second-tier isolation openings 267 constitutes a second-tier sacrificial isolation opening fill material portion 268.

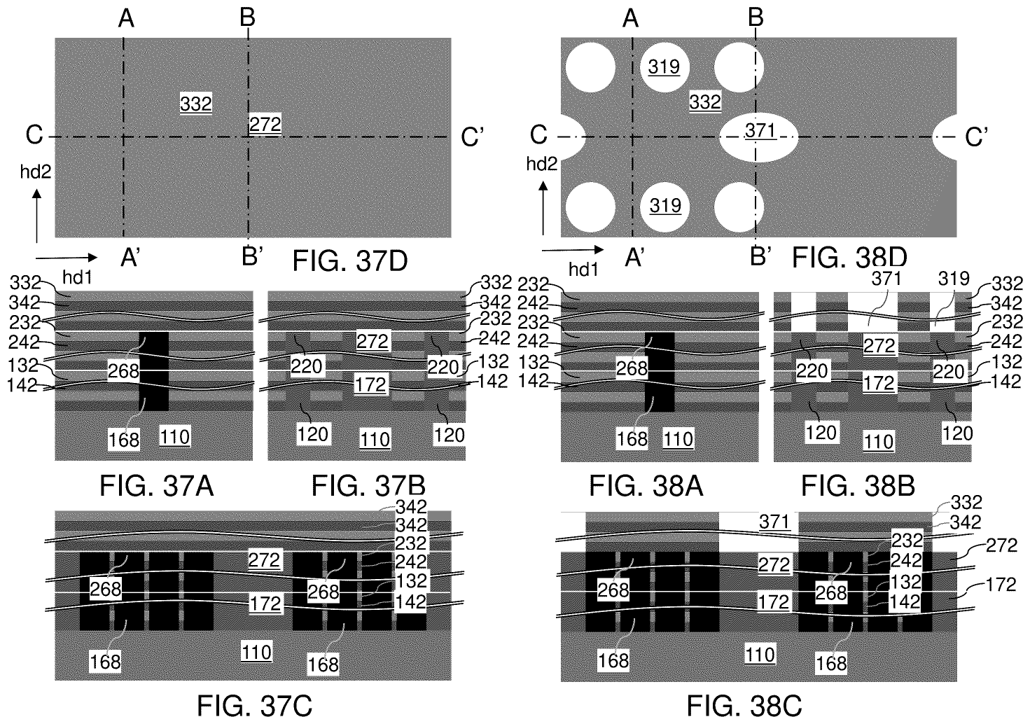

Referring to FIGS. 37A-37D, a third-tier vertically alternating sequence of third insulating layers 332 and third sacrificial material layers 342 can be formed. The third insulating layers 332 may have the same material composition and the same thickness as the first insulating layers 132 employed in the first-tier vertically alternating sequence. The third sacrificial material layers 342 may have the same material composition and the same thickness as the first sacrificial material layers 142 employed in the first-tier vertically alternating sequence. Thus, the third-tier vertically alternating sequence of the third insulating layers 332 and the third sacrificial material layers 342 may be the same as the first-tier vertically alternating sequence (132, 142) of the first insulating layers 132 and the first sacrificial material layers 142 described with reference to FIGS. 27A-27D.

The processing steps described with reference to FIGS. 3A-3C, 4A-4C, and 5A-5C can be subsequently performed with suitable modification in the pattern of the stepped surfaces to form a stepped dielectric material portion (not illustrated), which is herein referred to as a third-tier stepped dielectric material portion.

Referring to FIGS. 38A-38D, the processing steps described with reference to FIGS. 6A-6C may be performed, with optional changes in the shapes of the openings in the patterned etch mask layer, to form third-tier support openings 319 and third-tier pillar openings 371. The third-tier support openings 319 may have the same pattern as the pattern of the first-tier support openings 119, which is the same as the pattern of the first-tier support pillars 120. The third-tier pillar openings 371 may have the same pattern as the pattern of the first-tier pillar openings 171, which is the same as the pattern of the first-tier dielectric pillars 172.

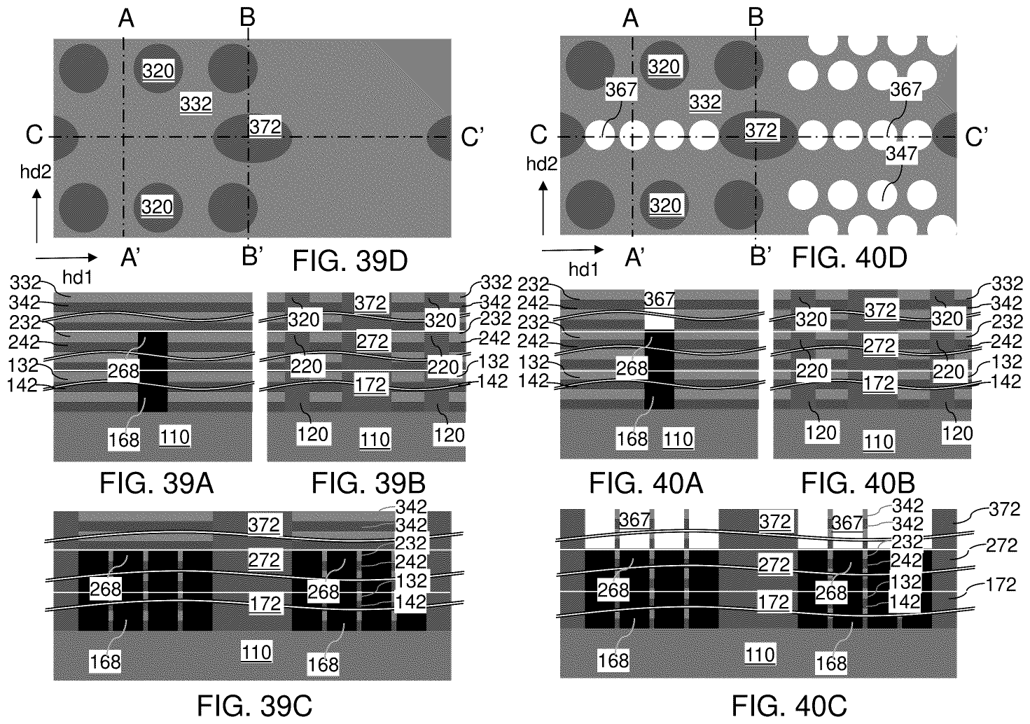

Referring to FIGS. 39A-39D, a dielectric fill material may be deposited in the third-tier support openings 319 and in the third-tier pillar openings 371. The dielectric fill material may comprise undoped silicate glass or a doped silicate glass. The dielectric fill material may be the same as the first dielectric fill material of the first-tier support pillars 120 and the first-tier dielectric pillars 172. Excess portions of the dielectric fill material may be removed from above the horizontal plane including the third-tier vertically alternating sequence (332, 342) by a planarization process, which may comprise a recess etch process and/or a chemical mechanical polishing process. Each remaining portion of the dielectric fill material filling a third-tier support opening 319 comprises a third-tier support pillar 320. Each remaining portion of the third dielectric fill material filling a third-tier pillar opening 371 comprises a third-tier dielectric pillar 372. The third-tier dielectric pillars 372 may be arranged as rows of third-tier dielectric pillars 372. Each row of third-tier dielectric pillars 372 comprises a respective set of third-tier dielectric pillars 372 arranged along the first horizontal direction hd1. The rows of third-tier dielectric pillars 372 are laterally spaced apart along the second horizontal direction hd2. The third-tier support pillars 320 may have the same pattern as the pattern of the first-tier support pillars 120. The third-tier dielectric pillars 372 may have the same pattern as the pattern of the first-tier dielectric pillars 172.

Each vertical stack of a first-tier dielectric pillar 172, a second-tier dielectric pillar 272, and a third-tier dielectric pillar 372 constitutes a dielectric pillar structure (172, 272, 372). Each vertical stack of a first-tier support pillar 120, a second-tier support pillar 220, and a third-tier support pillar 320 constitutes a support pillar structure (120, 220, 320). The dielectric pillar structures (172, 272, 372) and the support pillar structures (120, 220, 320) vertically extend from the at least one semiconductor material layer 110 to a horizontal plane including the topmost surface of the third-tier vertically alternating sequence (332, 342).

Referring to FIGS. 40A-40D, the processing steps described with respect to FIGS. 13A-13C can be performed with suitable modifications to form third-tier memory openings 347 and third-tier isolation openings 367 through the third-tier vertically alternating sequence (332, 342). The third-tier memory openings 347 may have the same pattern as the pattern of the first-tier memory openings 147, which is the same as the pattern of the first-tier sacrificial memory opening fill material portions 148. The third-tier isolation openings 367 may have the same pattern as the pattern of the first-tier isolation openings 167, which is the same as the pattern of the first-tier sacrificial isolation opening fill material portions 168.

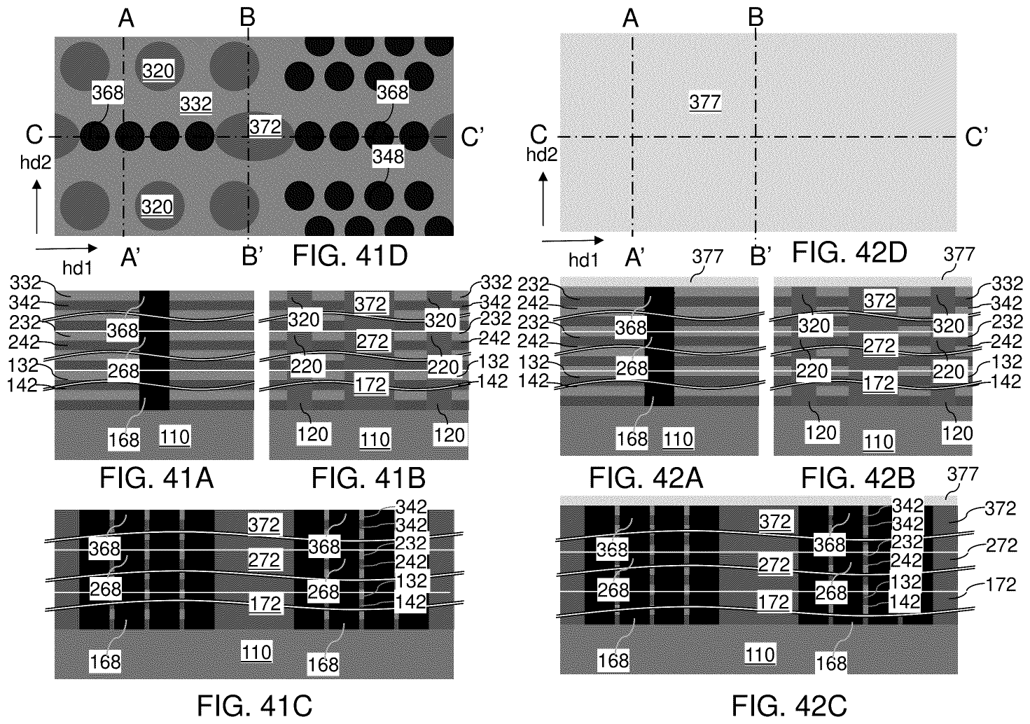

Referring to FIGS. 41A-41D, a third sacrificial fill material can be deposited in the third-tier memory openings 347 and third-tier isolation openings 367. The third sacrificial fill material comprises a material that may be subsequently removed selective to the materials of the third-tier vertically alternating sequence (332, 342). For example, the third sacrificial fill material may comprise a carbon-based material (such as amorphous carbon or diamond-like carbon) or may comprise a polymer material. The third sacrificial fill material may be the same as the first sacrificial fill material of the first-tier sacrificial memory opening fill material portions 148 and the first-tier sacrificial isolation opening fill material portions 168. Excess portions of the third sacrificial fill material may be removed from above the horizontal plane including the top surface of the third-tier vertically alternating sequence (332, 342) by a planarization process, such as a recess etch process or a chemical mechanical polishing process. Each remaining portion of the third sacrificial fill material that fills a respective one of the third-tier memory openings 347 constitutes a third-tier sacrificial memory opening fill material portion 348. Each remaining portion of the third sacrificial fill material that fills a respective one of the third-tier isolation openings 367 constitutes a third-tier sacrificial isolation opening fill material portion 368.

Referring to FIGS. 42A-42D, an etch mask layer 377 can be formed over the third-tier vertically alternating sequence (332, 342). The etch mask layer 377 comprises a hard mask material that can function as an etch stop structure during subsequent removal of the various sacrificial isolation opening fill material portions (168, 268, 368). In one embodiment, the etch mask layer 377 comprises a metallic material (such as TiN) or a semiconductor material (such as polysilicon or amorphous silicon). The thickness of the etch mask layer 377 may be in a range from 50 nm to 200 nm, although lesser and greater thicknesses may also be employed.

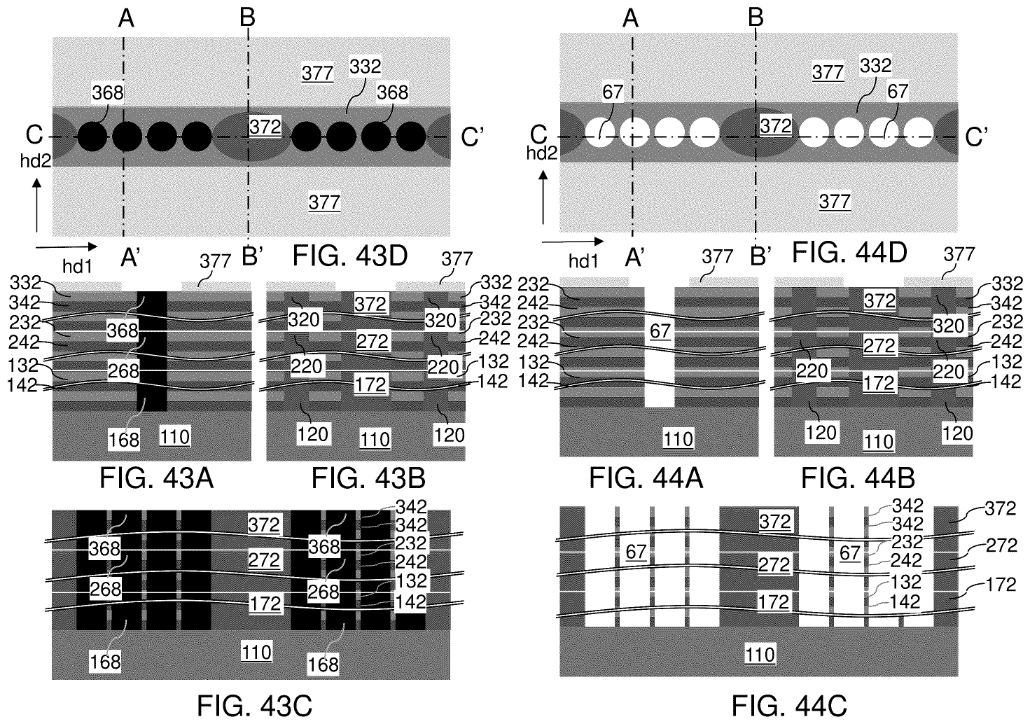

Referring to FIGS. 43A-43D, a photoresist layer (not shown) can be applied over the etch mask layer 377, and can be lithographically patterned to form elongated openings that overlie the dielectric pillar structures (172, 272, 372) and the various sacrificial isolation opening fill material portions (168, 268, 368). The various sacrificial memory opening fill material portions (148, 248, 348) and the support pillar structures (120, 220, 320) can be masked by the etch mask layer 377.

Referring to FIGS. 44A-44D, the sacrificial isolation opening fill material portions (168, 268, 368) can be removed selective to the materials of the vertically alternating sequences {(132, 142), (232, 242), (332, 342)}, the dielectric pillar structures (172, 272, 372), and the etch mask layer 377. For example, if the sacrificial isolation opening fill material portions (168, 268, 368) comprise a carbon-based material such as amorphous carbon, an ashing process can be performed to remove the sacrificial isolation opening fill material portions (168, 268, 368). Cavities are formed in the volumes from which the sacrificial isolation opening fill material portions (168, 268, 368) are removed. These cavities are herein referred to as isolation openings 67, which may be arranged as rows of isolation openings 67. Each row of isolation openings 67 may be interlaced with a respective row of dielectric pillar structures (172, 272, 372).

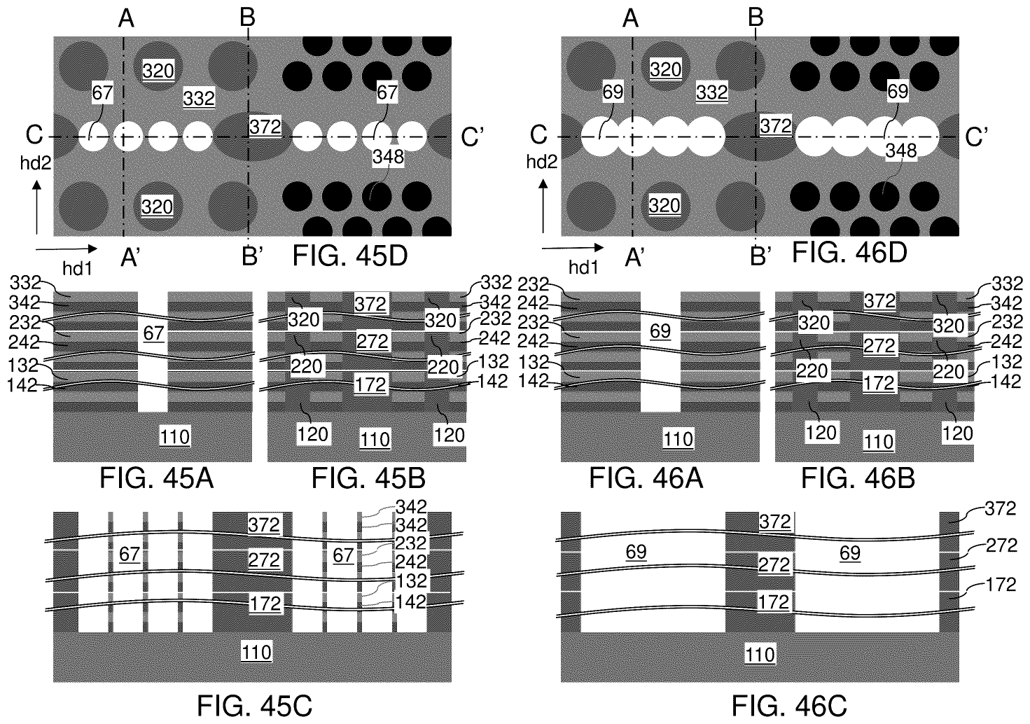

Referring to FIGS. 45A-45D, the etch mask layer 377 may be removed (e.g., by selective etching) selective to the materials of the vertically alternating sequences {(132, 142), (232, 242), (332, 342)}, the dielectric pillar structures (172, 272, 372), and the at least one semiconductor material layer 110.

Referring to FIGS. 46A-46D, at least one isotropic etch process may be performed to isotropically recess (i.e., widen) the isolation openings 67. For example, if the insulating layers (132, 232, 332) comprise silicon oxide and if the sacrificial material layers (142, 242, 342) comprise silicon nitride, a first wet etch process employing dilute hydrofluoric acid can be performed to laterally recess the insulating layers (132, 232, 332) and a second wet etch process employing hot phosphoric acid can be performed to laterally recess the sacrificial material layers (142, 242, 342). Clusters of isolation openings 67 are laterally expanded until neighboring isolation openings 67 merge to form merged isolation openings 69. The merged isolation openings 69 comprise cavities within a respective set of isolation openings 67 and further includes an additional cavity formed by removal of proximal portions of the vertically alternating sequence {(132, 142), (232, 242), (332, 342)} around the respective set of isolation openings 67.

Each row of merged isolation openings 69 can be interlaced with a respective row of dielectric pillar structures (172, 272, 372) without any lateral gap therethrough. Contiguous combinations of dielectric pillar structures (172, 272, 372) and merged isolation openings 69 divide the vertically alternating sequence {(132, 142), (232, 242), (332, 342)} into multiple alternating stacks {(132, 142), (232, 242), (332, 342)} of patterned portions of the insulating layers (132, 232, 332) and patterned portions of the sacrificial material layers (142, 242, 342). In other words, each divided portion of the vertically alternating sequence of insulating layers (132, 232, 332) and sacrificial material layers (142, 242, 342) as provided at the processing steps of FIGS. 45A-45D and laterally extending through multiple rows of merged isolation openings 69 along the second horizontal direction hd2 constitutes an alternating stack of insulating layers (132, 232, 332) and sacrificial material layers (142, 242, 342) having a limited lateral extent along the second horizontal direction hd2. The limited lateral extent may be between a neighboring pair of contiguous combinations of dielectric pillar structures (172, 272, 372) and merged isolation openings 69.

The vertically alternating sequence of insulating layers (132, 232, 332) and sacrificial material layers (142, 242, 342) is divided into multiple alternating stacks {(132, 142), (232, 242), (332, 342)} of insulating layers (132, 232, 332) and sacrificial material layers (142, 242, 342), which are disjoined (i.e., laterally separated) from each other. The dielectric pillar structures (172, 272, 372) function as support bridge structures between adjacent merged isolation openings 69 to prevent or reduce tilting or collapse of the alternating stacks into the isolation openings 69. Each row of interlaced dielectric pillar structures (172, 272, 372) and merged isolation openings 69 laterally isolate and separate adjacent memory block areas located in the alternating stacks.

The support pillar structures (120, 220, 320) vertically extend through and are laterally surrounded by a respective one of the alternating stacks {(132, 142), (232, 242), (332, 342)}. In one embodiment, each of the dielectric pillar structures (172, 272, 372) comprises a pair of laterally-concave and vertically-straight sidewalls that are exposed to a respective merged isolation opening 69. As used herein, a “laterally-concave” surface refers to a surface having a concave horizontal cross-sectional profile in a horizontal cross-sectional view. As used herein, a “laterally-convex” surface refers to a surface having a convex horizontal cross-sectional profile in a horizontal cross-sectional view. As used herein, a “vertically straight” surface refers to a surface having a straight vertical cross-sectional profile in a vertical cross-sectional view. In one embodiment, the pair of laterally-concave and vertically-straight sidewalls has a uniform radius of curvature in a horizontal cross-sectional view. In one embodiment, each of the dielectric pillar structures (172, 272, 372) comprises a pair of laterally-convex and vertically-straight sidewalls in contact with a pair of the alternating stacks {(132, 142), (232, 242), (332, 342)}.

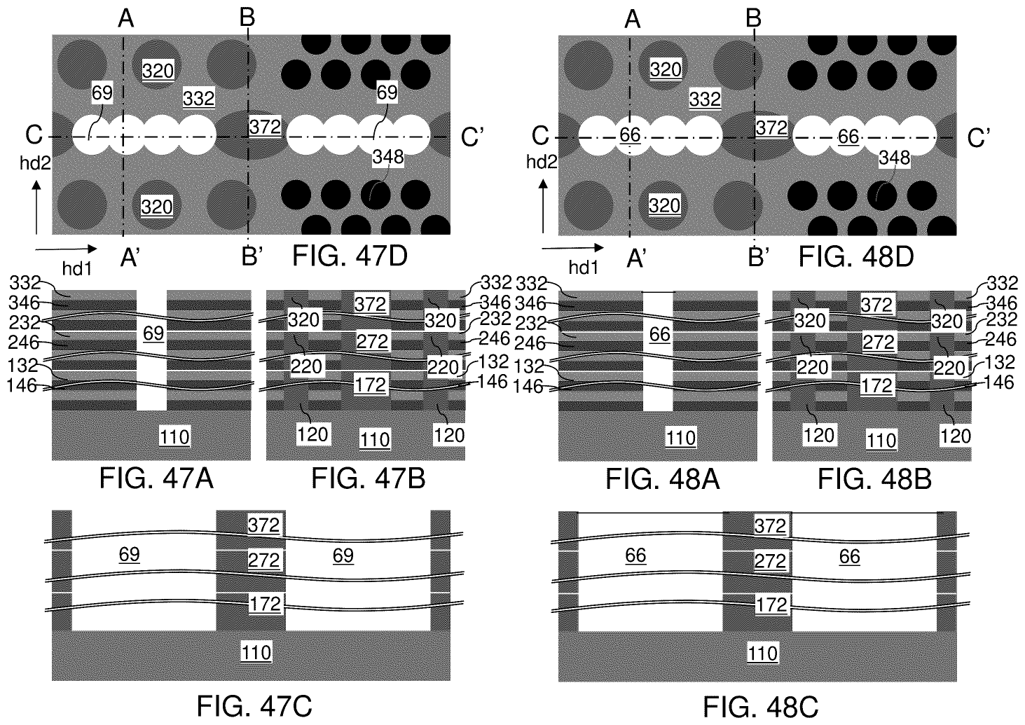

Referring to FIGS. 47A-47D, the processing steps described with reference to FIGS. 24A-24C can be performed to replace the sacrificial material layers (142, 242, 342) with electrically conductive layers (146, 246, 346). The first sacrificial material layers 142 are replaced with first electrically conductive layers 146; the second sacrificial material layers 242 are replaced with second electrically conductive layers 246; and the third sacrificial material layers 342 are replaced with third electrically conductive layers 346. The merged isolation openings 69 function as conduits for providing an isotropic etchant that etches the second material of the sacrificial material layers (142, 242, 342) selective to the first material of the insulating layers (132, 232, 332), and for providing a precursor material for depositing at least one conductive material of the electrically conductive layers (146, 246, 346). The sacrificial material layers (142, 242, 342) are replaced with electrically conductive layers (146, 246, 346) while the sacrificial memory opening fill structures (148, 248, 348) are present in the memory openings 49.

Referring to FIGS. 48A-48D, a dielectric material, which is herein referred to as a second dielectric material, can be conformally deposited in the merged isolation openings 69. Excess portions of the second dielectric material can be removed from above the horizontal plane including the topmost surface of the third-tier alternating stacks (332, 346). Each remaining portion of the second dielectric material filling a respective merged isolation opening 69 constitutes an isolation opening fill structures 66. In one embodiment, the dielectric pillar structures (172, 272, 372) and the support pillar structures (120, 220, 320) comprise a first dielectric fill material, and the isolation opening fill structures 66 comprise a fill material that is deposited separately from, and comprises the same or different composition from the first dielectric fill material. In one embodiment, the isolation opening fill structures 66 comprise silicon oxide.

In one embodiment, each of the isolation opening fill structures 66 continuously extends from a horizontal plane including bottommost surfaces of the first-tier alternating stacks (132, 146) at least to a horizontal plane including topmost surfaces of the second-tier alternating stacks (232, 246) as a single continuous material portion having a homogenous material composition throughout. In one embodiment, each of the isolation opening fill structures 66 continuously extends from the horizontal plane including bottommost surfaces of the first-tier alternating stacks (132, 146) to a horizontal plane including topmost surfaces of the third-tier alternating stacks (332, 346) as a single continuous material portion.

Each contiguous combination of a row of dielectric pillar structures (172, 272, 372) and a row of isolation opening fill structures 66 constitutes a composite lateral isolation trench fill structure {(172, 272, 372), 66}. Each volume occupied by a composite lateral isolation trench fill structure {(172, 272, 372), 66} constitutes a lateral isolation trench. Thus, the second exemplary structure includes composite lateral isolation trench fill structures {(172, 272, 372), 66} located in the lateral isolation trenches. Each of the composite lateral isolation trench fill structures {(172, 272, 372), 66} comprises a laterally alternating sequence of dielectric pillar structures (172, 272, 372) and isolation opening fill structures 66 arranged along the first horizontal direction hd1. A laterally alternating sequence refers to an alternating sequence of first elements and second elements that alternate along a lateral direction, i.e., along a horizontal direction such as the first horizontal direction hd1.

In one embodiment, each of the isolation opening fill structures 66 comprises a pair of first-type laterally-convex and vertically-straight sidewalls in contact with a respective pair of dielectric pillar structures (172, 272, 372) among the dielectric pillar structures (172, 272, 372). In one embodiment, each of the isolation opening fill structures 66 comprises at least two second-type laterally-convex and vertically-straight sidewalls in contact with a respective one of the alternating stacks {(132, 146), (232, 246), (332, 346)}. In one embodiment, the at least two second-type laterally-convex and vertically-straight sidewalls comprise two laterally-undulating lengthwise sidewalls, and each of the two laterally-undulating lengthwise sidewalls comprises a respective plurality of second-type laterally-convex and vertically-straight sidewalls that are adjoined among one another at vertically-extending edges. In one embodiment, at least one, such as each of the isolation opening fill structures 66 has a horizontal cross-sectional shape of a circle or an oval that is elongated along the first horizontal direction hd1.

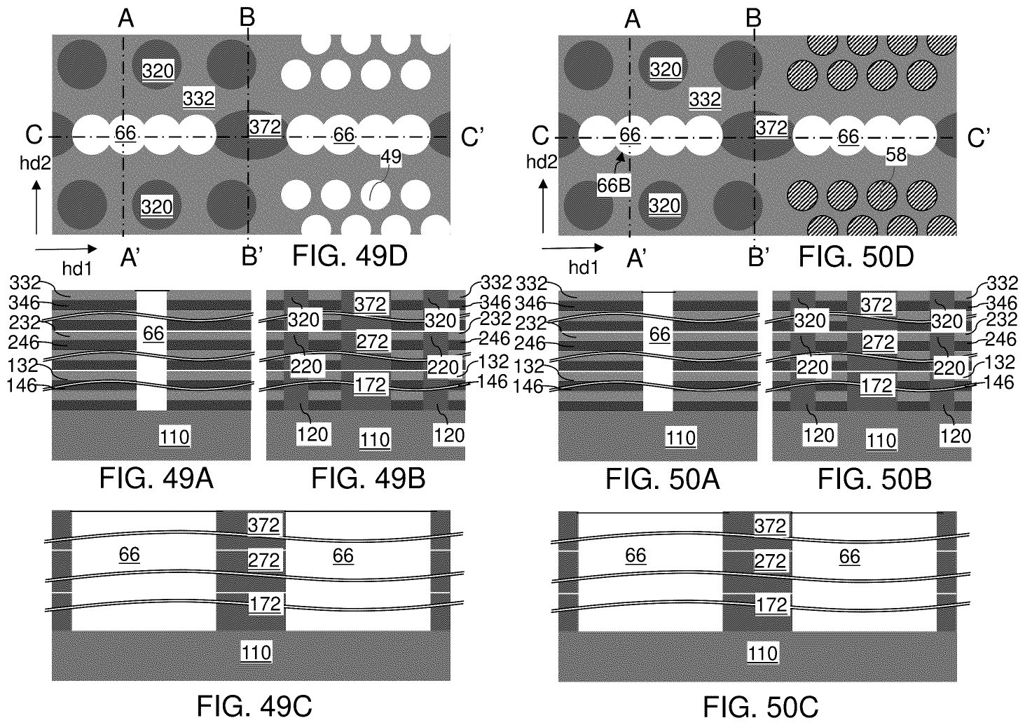

Referring to FIGS. 49A-49D, the sacrificial memory opening fill structures (148, 248, 348) are removed (e.g., by ashing) selective to the materials of the alternating stacks {(132, 146), (232, 246), (332, 346)}, the dielectric pillar structures (172, 272, 372), the support pillar structures (120, 220, 320), and the isolation opening fill structures 66. The volumes of the voids formed by removal of the sacrificial memory opening fill structures (148, 248, 348) comprise memory openings 49.

Referring to FIGS. 50A-50D, the processing steps described with reference to FIGS. 16A-16F can be performed to form memory opening fill structures 58 in the memory openings 49. Thus, the sacrificial memory opening fill structures (148, 248, 348) may be replaced with the memory opening fill structures 58 after formation of the isolation opening fill structures 66.

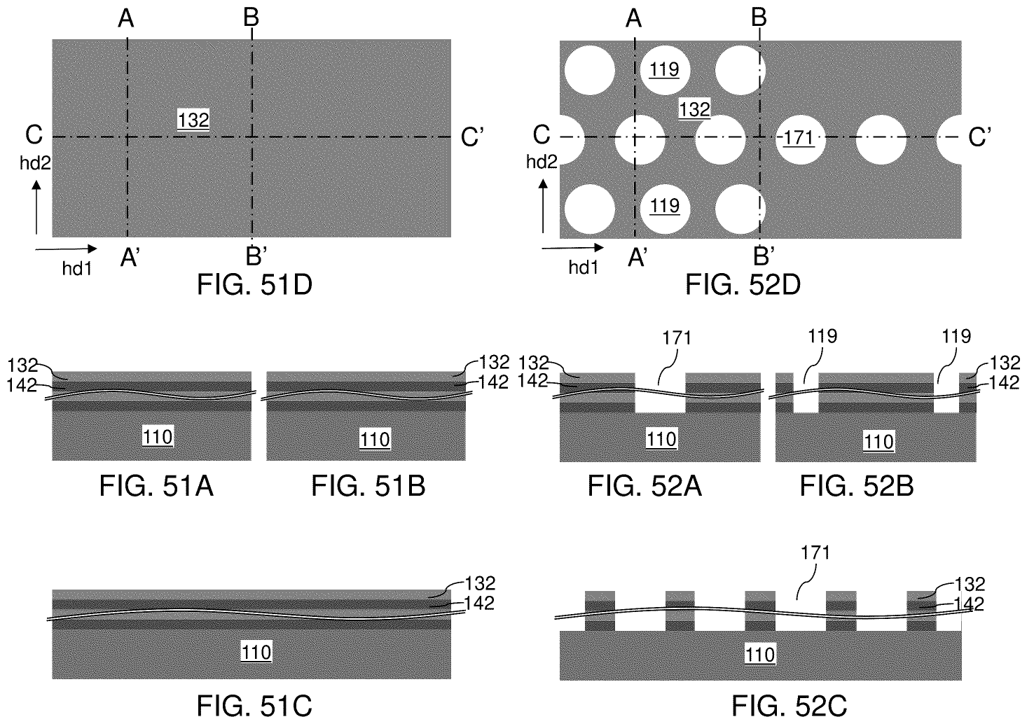

Referring to FIGS. 51A-51D, a third exemplary structure according to a third embodiment of the present disclosure is illustrated. The third exemplary structure may be the same as the second exemplary structure of FIGS. 27A-27D. The processing steps described with reference to FIGS. 3A-3C, 4A-4C, and 5A-5C can be subsequently performed to form a stepped dielectric material portion (not illustrated), which is herein referred to as a first-tier stepped dielectric material portion.

Referring to FIGS. 52A-52D, the processing steps described with reference to FIGS. 28A-28D may be performed, with changes in the spacing between the shapes of the openings in the patterned etch mask layer, to form first-tier support openings 119 and first-tier pillar openings 171. The first-tier support openings 119 may have the same pattern as in FIGS. 28A-28D. The first-tier pillar openings 171 may be arranged in rows of first-tier pillar openings 171, as in FIGS. 28A-28D, but with a decreased spacing along the first horizontal direction hd1 between adjacent first-tier pillar openings 171 in each row.

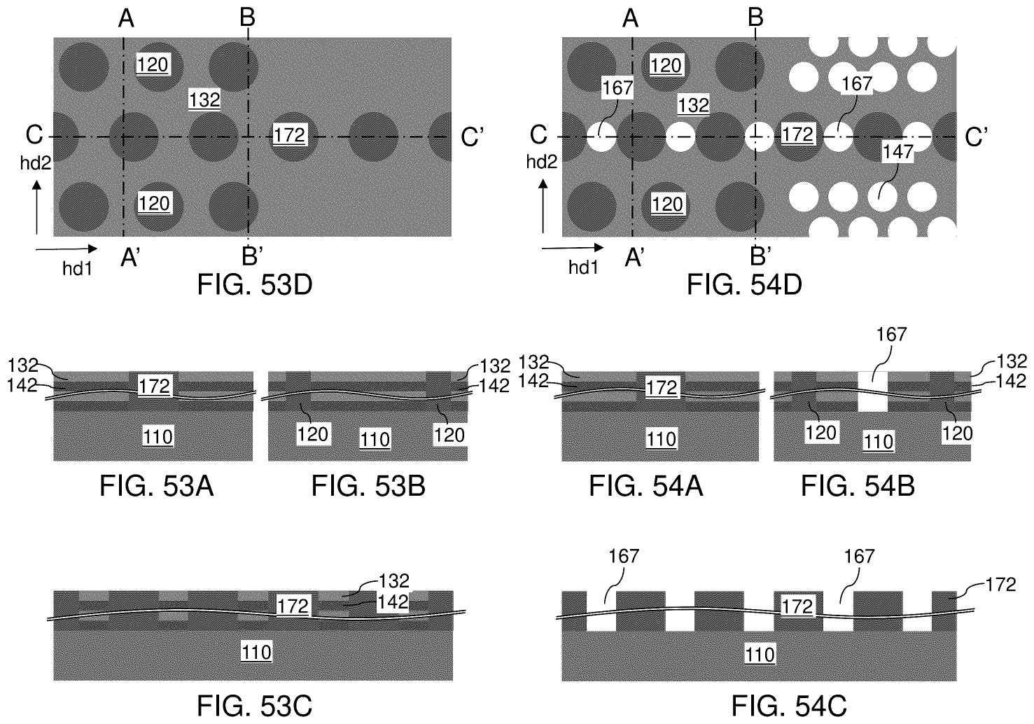

Referring to FIGS. 53A-53D, a first dielectric fill material may be deposited in the first-tier support openings 119 and in the first-tier pillar openings 171 to form the first-tier support pillars 120 and the first-tier dielectric pillars 172, as described above with respect to FIGS. 29A-29D. The first-tier dielectric pillars 172 may be arranged as rows of first-tier dielectric pillars 172, but with a decreased spacing along the first horizontal direction hd1 between adjacent first-tier dielectric pillars 172 in each row.

Referring to FIGS. 54A-54D, the processing steps described with respect to FIGS. 30A-30D can be performed to form the first-tier memory openings 147 and the first-tier isolation openings 167. The first-tier isolation openings 167 are formed in rows of first-tier isolation openings 167. The rows of first-tier isolation openings 167 can be laterally spaced apart from each other along the second horizontal direction hd2. Each row of first-tier isolation openings 167 can be aligned to a respective row of first-tier dielectric pillars 172, and can be interlaced along the first horizontal direction with the respective row of first-tier dielectric pillars 172. One first-tier isolation opening 167 can be provided between each neighboring pair of first-tier dielectric pillars 172. In one embodiment, the row of first-tier isolation openings 167 can be aligned to the row of first-tier dielectric pillars 172 within each laterally interlaced combination of a row of first-tier isolation openings 167 and a row of first-tier dielectric pillars 172 such that any lateral gap along the first horizontal direction within the laterally interlaced combination is less than a predetermined lateral dimension, which may be in a range from 20 nm to 200 nm, such as from 40 nm to 120 nm, although lesser and greater dimensions may also be employed.

In one embodiment, at least one, such as each of the first-tier isolation openings 167 may have a horizontal cross-sectional shape of a circle or an oval that is elongated along the first horizontal direction hd1. In the third embodiment, a single first-tier isolation opening 167 can be provided between each neighboring pair of first-tier dielectric pillars 172 within each laterally interlaced combination of a row of first-tier isolation openings 167 and a row of first-tier dielectric pillars 172.

In one embodiment, each of the first-tier dielectric pillars 172 may have a first lateral extent along the second horizontal direction hd2, and each of the first-tier isolation openings 167 may have a second lateral extent along the second horizontal direction hd2. The second lateral extent may be different from the first lateral extent, or may be the same as the first lateral extent. The first lateral extent may be in a range from 200 nm to 1,000 nm, such as from 300 nm to 600 nm, although lesser and greater first lateral extents may also be employed. In one embodiment, the second lateral extent may be in a range from 150 nm to 800 nm, such as from 200 nm to 500 nm, although lesser and greater second lateral extents may also be employed.

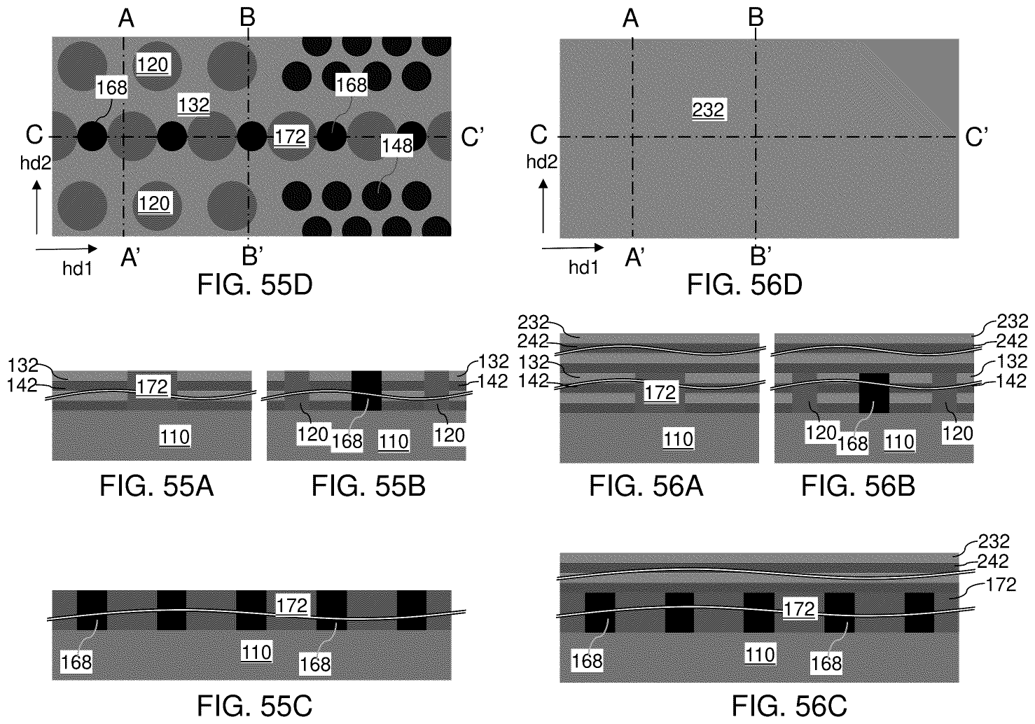

Referring to FIGS. 55A-55D, a first sacrificial fill material can be deposited in the first-tier memory openings 147 and first-tier isolation openings 167 to form the first-tier sacrificial memory opening fill material portions 148 and the first-tier sacrificial isolation opening fill material portions 168, as described above with respect to FIGS. 31A-31D.

Referring to FIGS. 56A-56D, a second-tier vertically alternating sequence of second insulating layers 232 and second sacrificial material layers 242 can be formed, as described with respect to FIGS. 32A-32D. The processing steps described with reference to FIGS. 3A-3C, 4A-4C, and 5A-5C can be subsequently performed with suitable modification in the pattern of the stepped surfaces to form a stepped dielectric material portion (not illustrated), which is herein referred to as a second-tier stepped dielectric material portion.

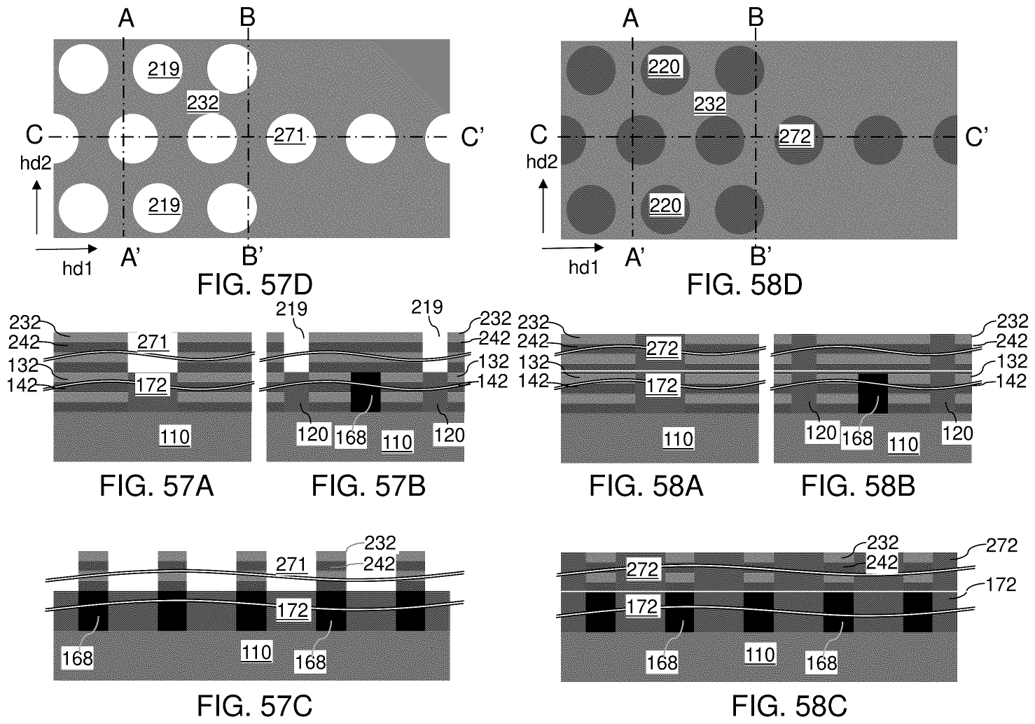

Referring to FIGS. 57A-57D, the processing steps described with reference to FIGS. 33A-33D may be performed to form second-tier support openings 219 and second-tier pillar openings 271. The second-tier support openings 219 may have the same pattern as the pattern of the first-tier support openings 119. The second-tier pillar openings 271 may have the same pattern as the pattern of the first-tier pillar openings 171.

Referring to FIGS. 58A-58D, a dielectric fill material may be deposited in the second-tier support openings 219 and in the second-tier pillar openings 271 to form the second-tier support pillars 220 and the second-tier dielectric pillar 27, as described above with respect to FIGS. 34A-34D. The second-tier support pillars 220 may have the same pattern as the pattern of the first-tier support pillars 120. The second-tier dielectric pillars 272 may have the same pattern as the pattern of the first-tier dielectric pillars 172.

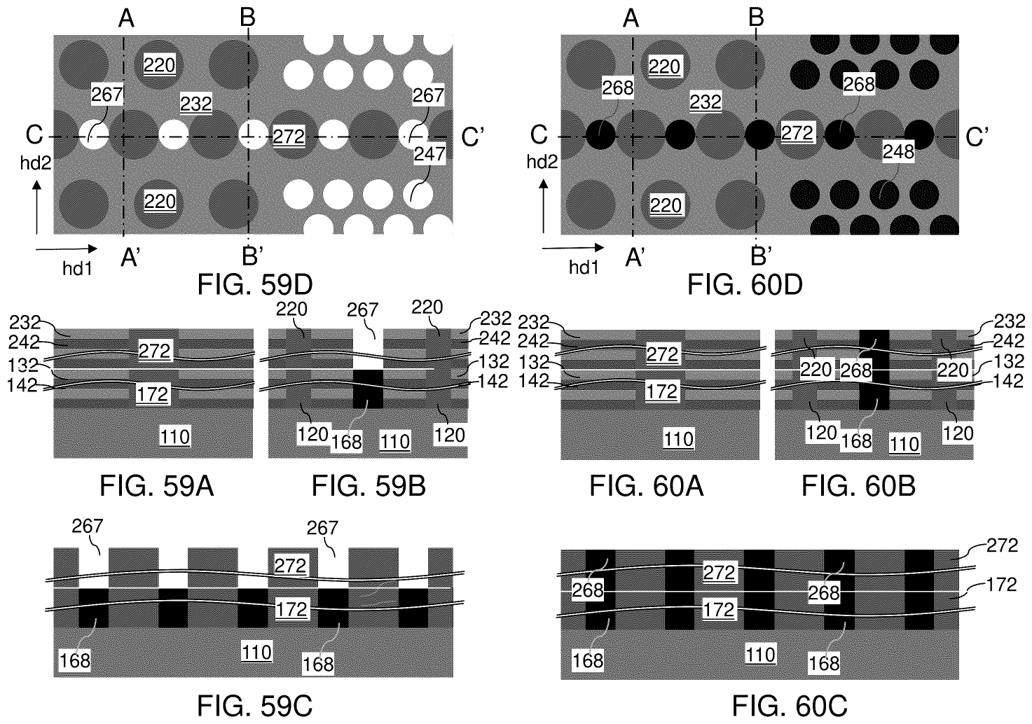

Referring to FIGS. 59A-59D, the processing steps described with respect to FIGS. 35A-35D can be performed with suitable modifications to form second-tier memory openings 247 and second-tier isolation openings 267 through the second-tier vertically alternating sequence (232, 242). The second-tier memory openings 247 may have the same pattern as the pattern of the first-tier memory openings 147. The second-tier isolation openings 267 may have the same pattern as the pattern of the first-tier isolation openings 167.

Referring to FIGS. 60A-60D, a second sacrificial fill material can be deposited in the second-tier memory openings 247 and second-tier isolation openings 267 to form the second-tier sacrificial memory opening fill material portions 248 and the second-tier sacrificial isolation opening fill material portions 268, as described above with respect to FIGS. 36A-36D.

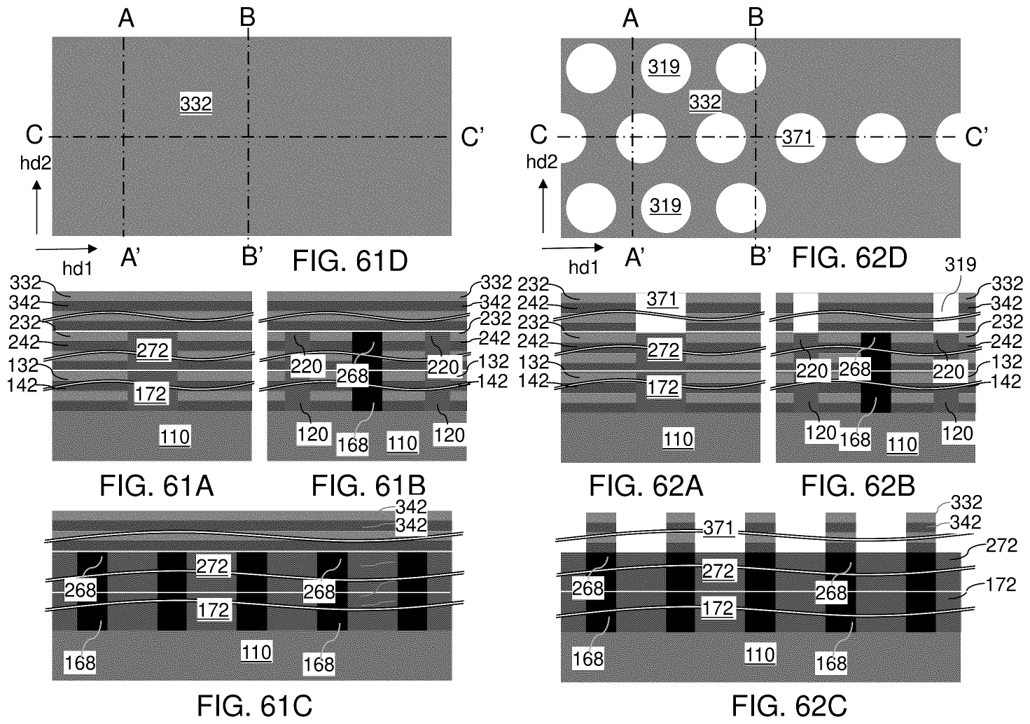

Referring to FIGS. 61A-61D, a third-tier vertically alternating sequence of third insulating layers 332 and third sacrificial material layers 342 can be formed, as described above with respect to FIGS. 37A-37D. The processing steps described with reference to FIGS. 3A-3C, 4A-4C, and 5A-5C can be subsequently performed with suitable modification in the pattern of the stepped surfaces to form a stepped dielectric material portion (not illustrated), which is herein referred to as a third-tier stepped dielectric material portion.

Referring to FIGS. 62A-62D, the processing steps described with reference to FIGS. 38A-38D may be performed, with optional changes in the shapes of the openings in the patterned etch mask layer, to form third-tier support openings 319 and third-tier pillar openings 371. The third-tier support openings 319 may have the same pattern as the pattern of the first-tier support openings 119. The third-tier pillar openings 371 may have the same pattern as the pattern of the first-tier pillar openings 171.

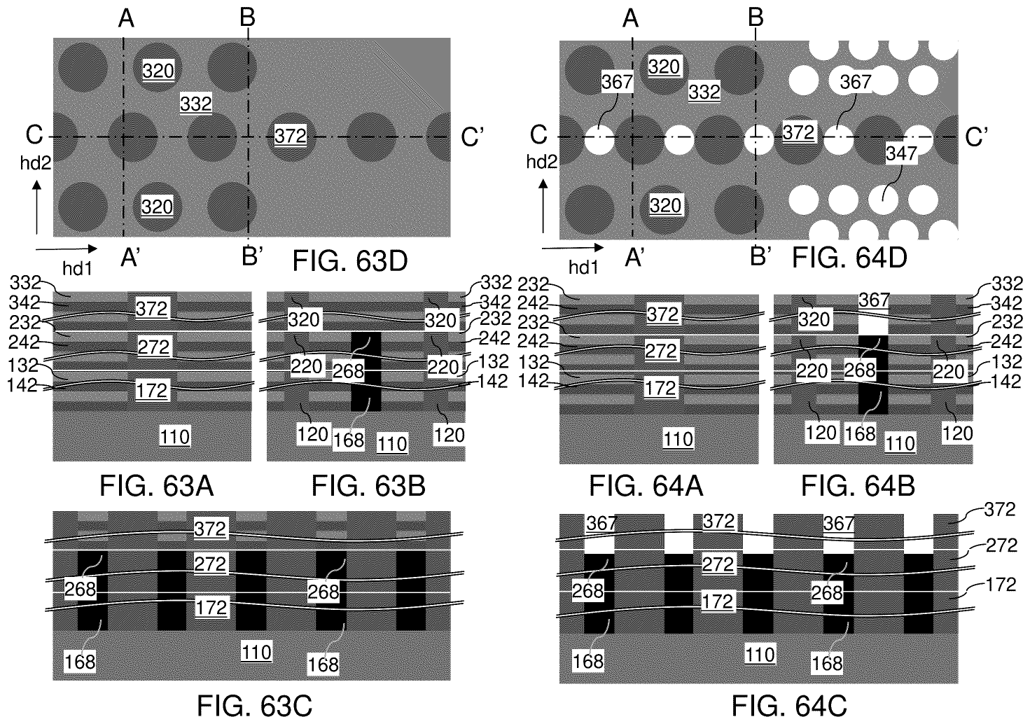

Referring to FIGS. 63A-63D, a dielectric fill material may be deposited in the third-tier support openings 319 and in the third-tier pillar openings 371 to form the third-tier support pillars 320 and the third-tier dielectric pillars 372, as described above with respect to FIGS. 39A-39D. The third-tier support pillars 320 may have the same pattern as the pattern of the first-tier support pillars 120. The third-tier dielectric pillars 372 may have the same pattern as the pattern of the first-tier dielectric pillars 172.

Each vertical stack of a first-tier dielectric pillar 172, a second-tier dielectric pillar 272, and a third-tier dielectric pillar 372 constitutes a dielectric pillar structure (172, 272, 372). Each vertical stack of a first-tier support pillar 120, a second-tier support pillar 220, and a third-tier support pillar 320 constitutes a support pillar structure (120, 220, 320). The dielectric pillar structures (172, 272, 372) and the support pillar structures (120, 220, 320) vertically extend from the at least one semiconductor material layer 110 to a horizontal plane including the topmost surface of the third-tier vertically alternating sequence (332, 342).

Referring to FIGS. 64A-64D, the processing steps described with respect to FIGS. 40A-40D can be performed with suitable modifications to form third-tier memory openings 347 and third-tier isolation openings 367 through the third-tier vertically alternating sequence (332, 342). The third-tier memory openings 347 may have the same pattern as the pattern of the first-tier memory openings 147. The third-tier isolation openings 367 may have the same pattern as the pattern of the first-tier isolation openings 167.

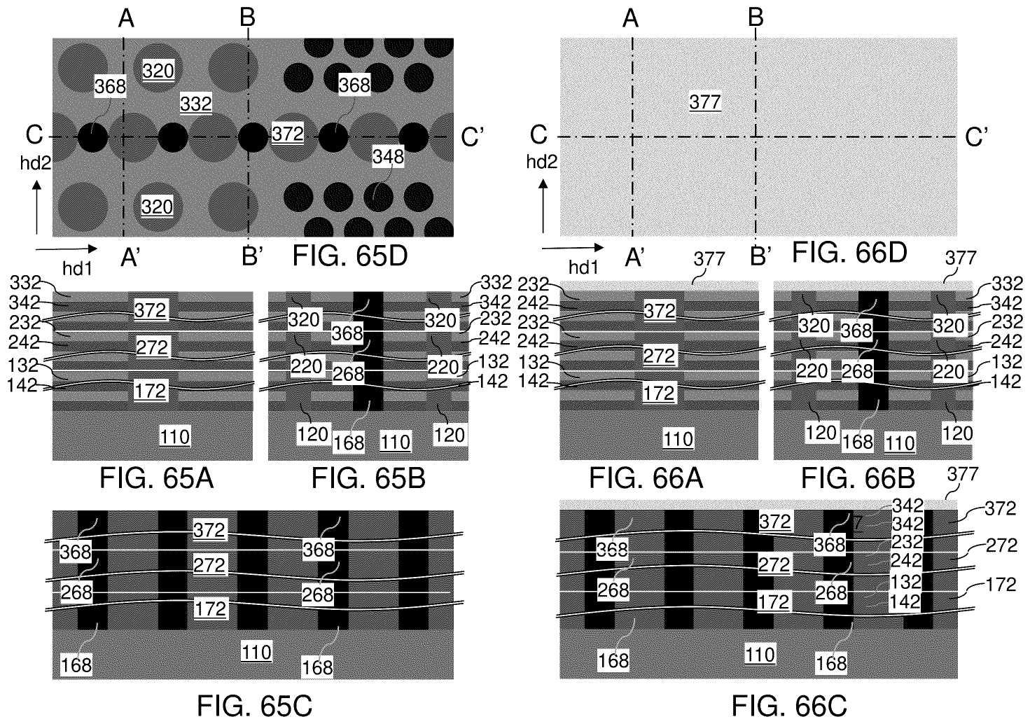

Referring to FIGS. 65A-65D, a third sacrificial fill material can be deposited in the third-tier memory openings 347 and third-tier isolation openings 367 to form the third-tier sacrificial memory opening fill material portions 348 and the third-tier sacrificial isolation opening fill material portions 368, as described above with respect to FIGS. 41A-42D.

Referring to FIGS. 66A-66D, the etch mask layer 377 is formed over the third-tier vertically alternating sequence (332, 342), as described above with respect to FIGS. 42A-42D.

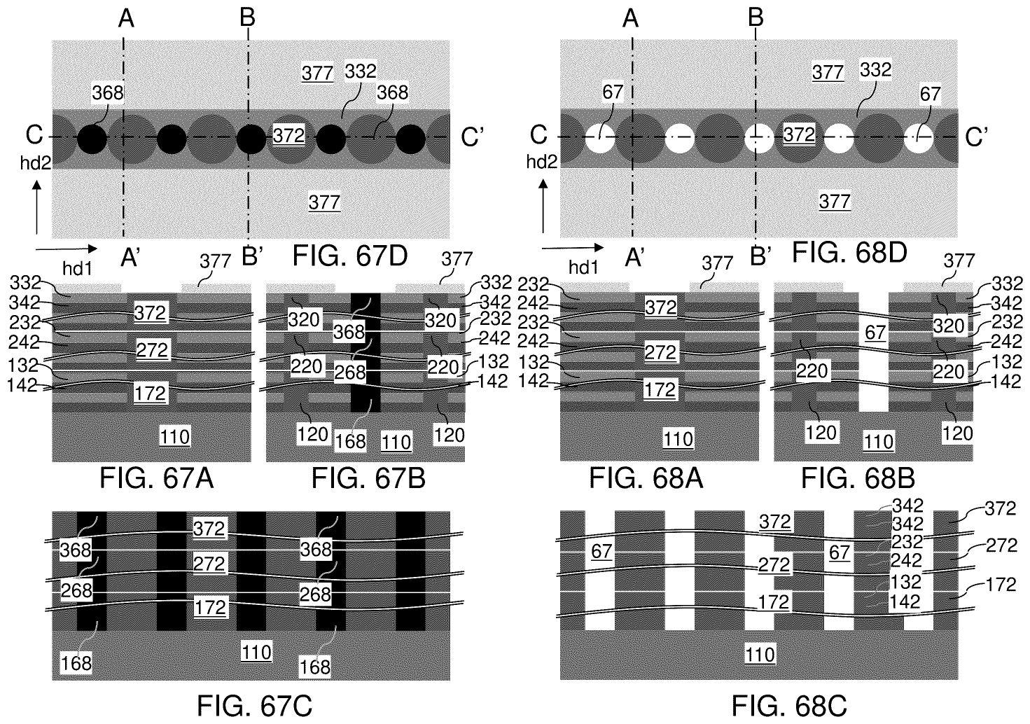

Referring to FIGS. 67A-67D, a photoresist layer (not shown) can be applied over the etch mask layer 377, and can be lithographically patterned to form elongated openings that overlie the dielectric pillar structures (172, 272, 372) and the various sacrificial isolation opening fill material portions (168, 268, 368), as described above with respect to FIGS. 43A-43D. The various sacrificial memory opening fill material portions (148, 248, 348) and the support pillar structures (120, 220, 320) can be masked by the etch mask layer 377.

Referring to FIGS. 68A-68D, the sacrificial isolation opening fill material portions (168, 268, 368) can be removed selective to the materials of the vertically alternating sequences {(132, 142), (232, 242), (332, 342)}, the dielectric pillar structures (172, 272, 372), and the etch mask layer 377 to form rows of isolation openings 67, as described above with respect to FIGS. 44A-44D. Each row of isolation openings 67 may be interlaced with a respective row of dielectric pillar structures (172, 272, 372). In the third exemplary structure, there is only one isolation opening 67 located between two adjacent dielectric pillar structures (172, 272, 372) along the first horizontal direction.

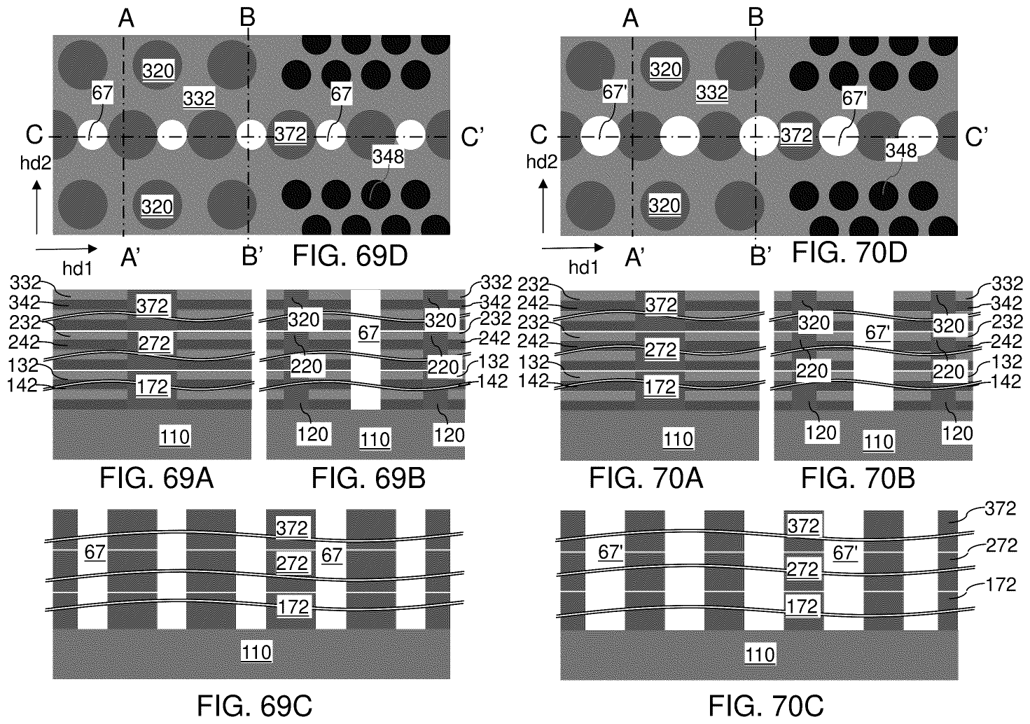

Referring to FIGS. 69A-69D, the etch mask layer 377 may be removed selective to the materials of the vertically alternating sequences {(132, 142), (232, 242), (332, 342)}, the dielectric pillar structures (172, 272, 372), and the at least one semiconductor material layer 110, as described above with respect to FIGS. 45A-45D.

Referring to FIGS. 70A-70D, at least one isotropic etch process may be performed to isotropically recess the isolation openings 67, as described above with respect to FIGS. 46A-46D. The isolation openings 67 are laterally expanded until each expanded isolation opening 67′ located between a pair of dielectric pillar structures (172, 272, 372) is bounded by laterally recessed surfaces of the pair of dielectric pillar structures (172, 272, 372). The expanded isolation openings 67′ comprise cavities within a respective isolation opening 67 and further includes an additional cavity formed by removal of proximal portions of the vertically alternating sequence {(132, 142), (232, 242), (332, 342)} around the respective isolation opening 67.

Each row of expanded isolation openings 67′ can be interlaced with a respective row of dielectric pillar structures (172, 272, 372) without any lateral gap therethrough. Contiguous combinations of dielectric pillar structures (172, 272, 372) and expanded isolation openings 67′ divide the vertically alternating sequence {(132, 142), (232, 242), (332, 342)} into multiple alternating stacks {(132, 142), (232, 242), (332, 342)} of patterned portions of the insulating layers (132, 232, 332) and patterned portions of the sacrificial material layers (142, 242, 342). In other words, each divided portion of the vertically alternating sequence of insulating layers (132, 232, 332) and sacrificial material layers (142, 242, 342) as provided at the processing steps of FIGS. 69A-69D and laterally extending through multiple rows of expanded isolation openings 67′ along the second horizontal direction hd2 constitutes an alternating stack of insulating layers (132, 232, 332) and sacrificial material layers (142, 242, 342) having a limited lateral extent along the second horizontal direction hd2. The limited lateral extent may be between a neighboring pair of contiguous combinations of dielectric pillar structures (172, 272, 372) and expanded isolation openings 67′.

The vertically alternating sequence of insulating layers (132, 232, 332) and sacrificial material layers (142, 242, 342) is divided into multiple alternating stacks {(132, 142), (232, 242), (332, 342)} of insulating layers (132, 232, 332) and sacrificial material layers (142, 242, 342), which are disjoined among one another. The support pillar structures (120, 220, 320) vertically extend through and are laterally surrounded by a respective one of the alternating stacks {(132, 142), (232, 242), (332, 342)}. In one embodiment, each of the dielectric pillar structures (172, 272, 372) comprises a pair of laterally-concave and vertically-straight sidewalls that are exposed to a respective expanded isolation opening 67′. In one embodiment, the pair of laterally-concave and vertically-straight sidewalls has a uniform radius of curvature in a horizontal cross-sectional view. In one embodiment, each of the dielectric pillar structures (172, 272, 372) comprises a pair of laterally-convex and vertically-straight sidewalls in contact with a pair of the alternating stacks {(132, 142), (232, 242), (332, 342)}.

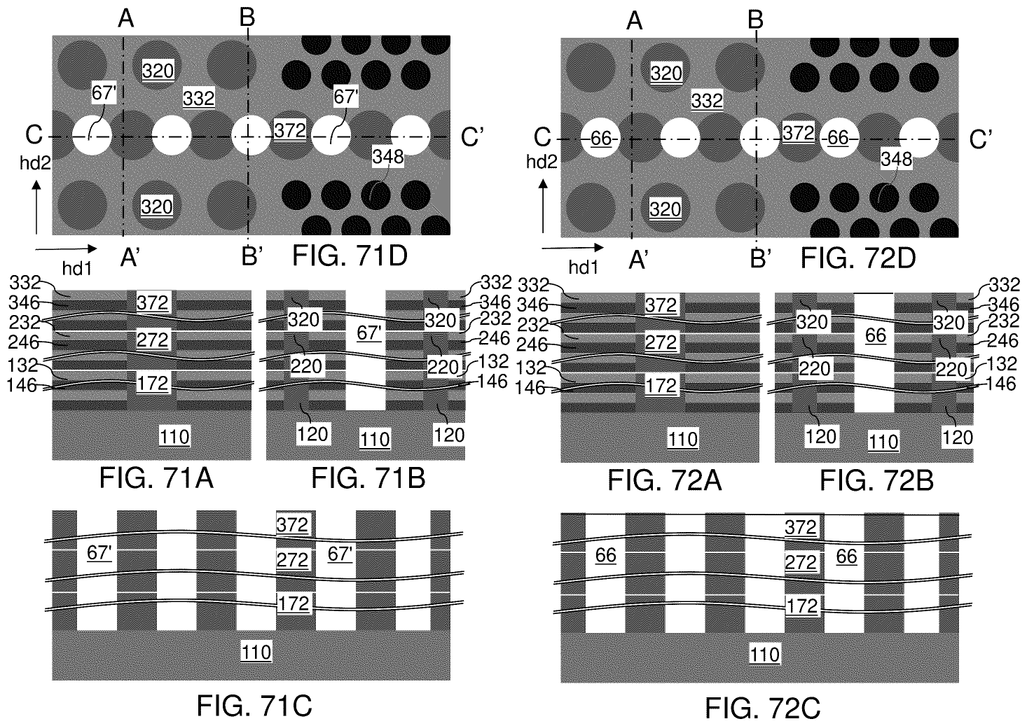

Referring to FIGS. 71A-71D, the processing steps described with reference to FIGS. 47A-47D can be performed to replace the sacrificial material layers (142, 242, 342) with electrically conductive layers (146, 246, 346). The expanded isolation openings 67′ function as conduits for providing an isotropic etchant that etches the second material of the sacrificial material layers (142, 242, 342) selective to the first material of the insulating layers (132, 232, 332), and for providing a precursor material for depositing at least one conductive material of the electrically conductive layers (146, 246, 346).

Referring to FIGS. 72A-72D, a dielectric material, which is herein referred to as a second dielectric material, can be conformally deposited in the expanded isolation openings 67′ to form the isolation opening fill structures 66, as described above with respect to FIGS. 48A-48D.

In one embodiment, each of the isolation opening fill structures 66 continuously extends from a horizontal plane including bottommost surfaces of the first-tier alternating stacks (132, 146) at least to a horizontal plane including topmost surfaces of the second-tier alternating stacks (232, 246) as a single continuous material portion having a homogenous material composition throughout. In one embodiment, each of the isolation opening fill structures 66 continuously extends from the horizontal plane including bottommost surfaces of the first-tier alternating stacks (132, 146) to a horizontal plane including topmost surfaces of the third-tier alternating stacks (332, 346) as a single continuous material portion.

Each contiguous combination of a row of dielectric pillar structures (172, 272, 372) and a row of isolation opening fill structures 66 constitutes a composite lateral isolation trench fill structure {(172, 272, 372), 66}. Each volume occupied by a composite lateral isolation trench fill structure {(172, 272, 372), 66} constitutes a lateral isolation trench. Thus, the third exemplary structure comprises composite lateral isolation trench fill structures {(172, 272, 372), 66} located in the lateral isolation trenches. Each of the composite lateral isolation trench fill structures {(172, 272, 372), 66} comprises a laterally alternating sequence of dielectric pillar structures (172, 272, 372) and isolation opening fill structures 66 arranged along the first horizontal direction hd1.

In one embodiment, each of the isolation opening fill structures 66 comprises a pair of first-type laterally-convex and vertically-straight sidewalls in contact with a respective pair of the dielectric pillar structures (172, 272, 372). In one embodiment, each of the isolation opening fill structures 66 comprises two second-type laterally-convex and vertically-straight sidewalls in contact with a respective one of the alternating stacks {(132, 146), (232, 246), (332, 346)}. In one embodiment, at least one, such as each of the isolation opening fill structures 66 has a horizontal cross-sectional shape of a circle or an oval that is elongated along the first horizontal direction hd1.

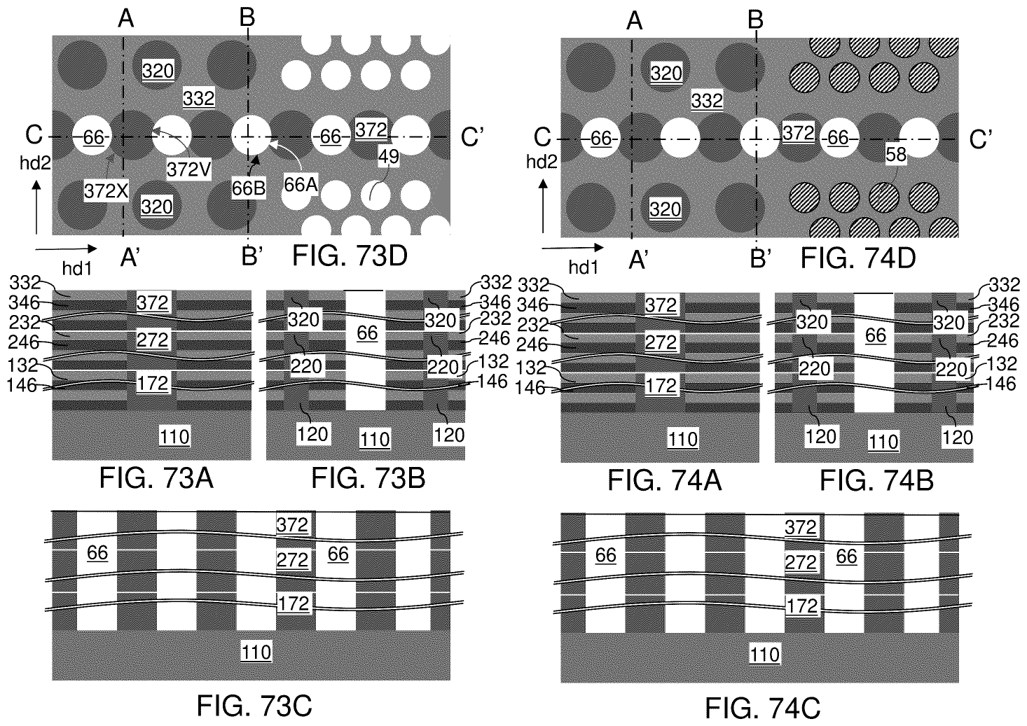

Referring to FIGS. 73A-73D, the sacrificial memory opening fill structures (148, 248, 348) are removed selective to the materials of the alternating stacks {(132, 146), (232, 246), (332, 346)}, the dielectric pillar structures (172, 272, 372), the support pillar structures (120, 220, 320), and the isolation opening fill structures 66 to form the memory openings 49, as described above with respect to FIGS. 49A-49D.

Referring to FIGS. 74A-74D, the processing steps described with reference to FIGS. 50A-50D can be performed to form memory opening fill structures 58 in the memory openings 49. Thus, the sacrificial memory opening fill structures (148, 248, 348) may be replaced with the memory opening fill structures 58 after formation of the isolation opening fill structures 66.

Referring to all drawings and according to various embodiments of the present disclosure, a three-dimensional memory device comprises: alternating stacks {(132, 146), (232, 246), (332, 346)} of insulating layers (132, 232, 332) and electrically conductive layers (146, 246, 346), wherein each of the alternating stacks {(132, 146), (232, 246), (332, 346)} laterally extends along a first horizontal direction hd1, and the alternating stacks {(132, 146), (232, 246), (332, 346)} are laterally spaced apart from each other along a second horizontal direction hd2 by lateral isolation trenches (which are volumes occupied by composite lateral isolation trench fill structures {(172, 272, 372), 66}); arrays of memory openings 49, wherein each array of memory openings 49 vertically extends through a respective one of the alternating stacks {(132, 146), (232, 246), (332, 346)}; arrays of memory opening fill structures 58 located within the arrays of memory openings 49, wherein each of the memory opening fill structures 58 comprises a respective vertical stack of memory elements (e.g., portions of the memory film 50) and a vertical semiconductor channel 60; and composite lateral isolation trench fill structures {(172, 272, 372), 66} located in the lateral isolation trenches. Each of the composite lateral isolation trench fill structures {(172, 272, 372), 66} comprises a laterally alternating sequence of dielectric pillar structures (172, 272, 372) and dielectric containing structures (such as insulating spacers 74 or isolation opening fill structures 66) arranged along the first horizontal direction hd1.

In one embodiment, each of the dielectric pillar structures (172, 272, 372) comprises a pair of laterally-concave and vertically-straight sidewalls (e.g., 372V shown in FIG. 74D) in contact with a respective pair of the isolation opening fill structures 66. In one embodiment, the pair of laterally-concave and vertically-straight sidewalls 372V has a uniform radius of curvature in a horizontal cross-sectional view. In one embodiment, each of the dielectric pillar structures (172, 272, 372) further comprises a pair of laterally-convex and vertically-straight sidewalls (e.g., 372X shown in FIG. 74D) in contact with a pair of the alternating stacks {(132, 146), (232, 246), (332, 346)}.

In one embodiment, the three-dimensional memory device comprises support pillar structures (120, 220, 320) vertically extending through and laterally surrounded by a respective one of the alternating stacks {(132, 146), (232, 246), (332, 346)}. In one embodiment, the dielectric pillar structures (172, 272, 372) and the support pillar structures (120, 220, 320) comprise a first dielectric fill material; and the isolation opening fill structures 66 comprise the same or different fill material that is formed separately from the first dielectric fill material.

In one embodiment, each of the isolation opening fill structures 66 comprises a pair of first-type laterally-convex and vertically-straight sidewalls (e.g., 66A in FIG. 74D) in contact with a respective pair of the laterally-concave and vertically-straight sidewalls 372V of the dielectric pillar structures (172, 272, 372). In one embodiment, each of the isolation opening fill structures 66 further comprises at least two second-type laterally-convex and vertically-straight sidewalls (e.g., 66B in FIGS. 50D and 74D) in contact with a respective one of the alternating stacks {(132, 146), (232, 246), (332, 346)}.

In the second embodiment, the at least two second-type laterally-convex and vertically-straight sidewalls 66B comprise two laterally-undulating lengthwise sidewalls; and each of the two laterally-undulating lengthwise sidewalls comprises a respective plurality of second-type laterally-convex and vertically-straight sidewalls that are adjoined to each other at vertically-extending edges.

In the third embodiment, at least one of the isolation opening fill structures 66 has a horizontal cross-sectional shape of a circle or an oval that is elongated along the first horizontal direction hd1. In one embodiment, each of the dielectric pillar structures (172, 272, 372) has a first lateral extent along the second horizontal direction hd2; and each of the isolation opening fill structures 66 has a second lateral extent along the second horizontal direction hd2 that is different from the first lateral extent. In one embodiment, each of the dielectric pillar structures (172, 272, 372) and the isolation opening fill structures 66 vertically extends at least from a first horizontal plane including bottommost surfaces of the alternating stacks {(132, 146), (232, 246), (332, 346)} to a second horizontal plane including topmost surfaces of the alternating stacks {(132, 146), (232, 246), (332, 346)}.

In one embodiment, each of the alternating stack {(132, 146), (232, 246), (332, 346)} comprises a first-tier alternating stack (132, 146) of first insulating layers 132 and first electrically conductive layers 146 and a second-tier alternating stack (232, 246) of second insulating layers 232 and second electrically conductive layers 246; and each of the dielectric pillar structures (172, 272, 372) comprises a vertical stack including a first-tier dielectric pillar 172 vertically extending through the first-tier alternating stack (132, 146) and a second-tier dielectric pillar 272 vertically extending through the second-tier alternating stack (232, 246) and contacting a top surface of the first-tier dielectric pillar 172. In one embodiment, each of the isolation opening fill structures 66 continuously extends from a horizontal plane including bottommost surfaces of the first-tier alternating stacks (132, 146) at least to a horizontal plane including topmost surfaces of the second-tier alternating stacks (232, 246) as a single continuous material portion having a homogenous material composition throughout.

In the second and third embodiments, the memory openings 49 and the isolation openings (147, 247, 347) are formed during the same photolithography and etching steps. Likewise, the pillar openings (171, 271, 371) and the support openings (119, 219, 319) are formed during the same photolithography and etching steps and then filled with the same insulating material to form the dielectric pillar structures (172, 272, 372) and the support pillar structures (120, 220, 320) during the same deposition steps. This eliminates several processing steps, simplifies the device manufacturing process, reduces the risk for misalignment during separate photolithography steps, and eliminates the need to etch electrically conductive layer portions inside the dielectric pillar structures.

Although the foregoing refers to particular embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment using a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A three-dimensional memory device, comprising:
alternating stacks of insulating layers and electrically conductive layers, wherein each of the alternating stacks laterally extends along a first horizontal direction, and the alternating stacks are laterally spaced apart from each other along a second horizontal direction by lateral isolation trenches;
arrays of memory openings, wherein each array of memory openings vertically extends through a respective one of the alternating stacks;
arrays of memory opening fill structures located within the arrays of memory openings, wherein each of the memory opening fill structures comprises a respective vertical stack of memory elements and a vertical semiconductor channel; and
composite lateral isolation trench fill structures located in the lateral isolation trenches, wherein each of the composite lateral isolation trench fill structures comprises a laterally alternating sequence of dielectric pillar structures and dielectric containing structures arranged along the first horizontal direction.

2. The three-dimensional memory device of claim 1, wherein the dielectric containing structures comprise isolation opening fill structures.

3. The three-dimensional memory device of claim 2, wherein each of the dielectric pillar structures comprises a pair of laterally-concave and vertically-straight sidewalls in contact with a respective pair of the isolation opening fill structures.

4. The three-dimensional memory device of claim 3, wherein:
the pair of laterally-concave and vertically-straight sidewalls have a uniform radius of curvature in a horizontal cross-sectional view; and
each of the dielectric pillar structures further comprises an additional pair of laterally-convex and vertically-straight sidewalls in contact with a pair of alternating stacks among the alternating stacks.

5. The three-dimensional memory device of claim 3, further comprising support pillar structures vertically extending through and laterally surrounded by a respective one of the alternating stacks.

6. The three-dimensional memory device of claim 5, wherein:
the dielectric pillar structures and the support pillar structures comprise a first dielectric fill material; and
the isolation opening fill structures comprise a fill material that is formed separately from the first dielectric fill material.

7. The three-dimensional memory device of claim 3, wherein each of the isolation opening fill structures comprises a pair of first-type laterally-convex and vertically-straight sidewalls in contact with the respective pair of laterally-concave and vertically-straight sidewalls of the dielectric pillar structures.

8. The three-dimensional memory device of claim 7, wherein each of the isolation opening fill structures further comprises at least two second-type laterally-convex and vertically-straight sidewalls in contact with a respective one of the alternating stacks.

9. The three-dimensional memory device of claim 8, wherein:
the at least two second-type laterally-convex and vertically-straight sidewalls comprise two laterally-undulating lengthwise sidewalls; and
each of the two laterally-undulating lengthwise sidewalls comprises a respective plurality of second-type laterally-convex and vertically-straight sidewalls that are adjoined to each other at vertically-extending edges.

10. The three-dimensional memory device of claim 2, wherein at least one of the isolation opening fill structures has a horizontal cross-sectional shape of a circle or an oval that is elongated along the first horizontal direction.

11. The three-dimensional memory device of claim 2, wherein:
each of the dielectric pillar structures has a first lateral extent along the second horizontal direction; and
each of the isolation opening fill structures has a second lateral extent along the second horizontal direction that is different from the first lateral extent.

12. The three-dimensional memory device of claim 2, wherein each of the dielectric pillar structures and the isolation opening fill structures vertically extends at least from a first horizontal plane including bottommost surfaces of the alternating stacks to a second horizontal plane including topmost surfaces of the alternating stacks.

13. The three-dimensional memory device of claim 2, wherein:
each of the alternating stacks comprises a first-tier alternating stack of first insulating layers and first electrically conductive layers and a second-tier alternating stack of second insulating layers and second electrically conductive layers; and
each of the dielectric pillar structures comprises a vertical stack including a first-tier dielectric pillar vertically extending through the first-tier alternating stack and a second-tier dielectric pillar vertically extending through the second-tier alternating stack and contacting a top surface of the first-tier dielectric pillar.

14. The three-dimensional memory device of claim 13, wherein each of the isolation opening fill structures continuously extends from a horizontal plane including bottommost surfaces of the first-tier alternating stacks at least to a horizontal plane including topmost surfaces of the second-tier alternating stacks as a single continuous material portion having a homogenous material composition throughout.

15. A method of forming device structure, comprising:
forming a vertically alternating sequence of continuous insulating layers comprising a first material and continuous sacrificial material layers comprising a second material;
forming dielectric pillar structures arranged in rows through the vertically alternating sequence, wherein each row of dielectric pillar structures comprises a respective subset of the dielectric pillar structures arranged along a first horizontal direction, and the rows of dielectric pillar structures are laterally spaced apart along a second horizontal direction that is perpendicular to the first horizontal direction;
forming memory openings through the vertically alternating sequence;
forming isolation openings arranged in rows through the vertically alternating sequence, wherein each row of isolation openings comprises a respective subset of the isolation openings arranged along the first horizontal direction, and the rows of isolation openings are laterally spaced apart along the second horizontal direction;
replacing the sacrificial material layers with electrically conductive layers employing cavities within the isolation openings as a conduit for providing an isotropic etchant that etches the second material selective to the first material, and for providing a precursor material for depositing at least one conductive material of the electrically conductive layers; and
forming memory opening fill structures in the memory openings, wherein each of the memory opening fill structures comprises a respective vertical stack of memory elements and a vertical semiconductor channel.

16. The method of claim 15, wherein a combination of the dielectric pillar structures and the isolation openings divides the vertically alternating sequence into multiple laterally separated alternating stacks of patterned portions of the insulating layers and patterned portions of the sacrificial material layers.

17. The method of claim 15, further comprising isotropically expanding the isolation openings by isotropically etching portions of vertically alternating sequence from around the isolation openings, wherein:
clusters of the isolation openings merge to form merged isolation openings; and
a combination of the dielectric pillar structures and the merged isolation openings divides the vertically alternating sequence into multiple laterally separated alternating stacks of patterned portions of the insulating layers and patterned portions of the sacrificial material layers.

18. The method of claim 15, further comprising:
forming support openings and pillar openings through the vertically alternating sequence during a same etching step; and
depositing a first dielectric fill material in the support openings and in the pillar openings, wherein support pillar structures are formed in the support openings and dielectric pillar structures are formed in the pillar openings, wherein a subset of the support pillar structures is laterally surrounded by a respective electrically conductive layer after formation of the electrically conductive layers.

19. The method of claim 15, wherein:
the memory openings and the isolation openings are concurrently formed by performing an anisotropic etch process employing an etch mask layer including arrays of openings therein;
the method further comprises concurrently forming sacrificial memory opening fill structures and sacrificial isolation opening fill structures in the memory openings and in the isolation openings, respectively; and
the sacrificial material layers are replaced with electrically conductive layers while the sacrificial memory opening fill structures are present in the memory openings.

20. The method of claim 19, further comprising filling volumes of the cavities with isolation opening fill structures, wherein the sacrificial memory opening fill structures are replaced with the memory opening fill structures after formation of the isolation opening fill structures.
